(19) United States
(12) Patent Application Publication
(10) Pub. No.: US 2025/0212681 A1
(43) Pub. Date: Jun. 26, 2025

(54) Light-Emitting Device

(71) Applicant: Semiconductor Energy Laboratory Co., Ltd., Kanagawa-ken (JP)

(72) Inventors: Nobuharu OHSAWA, Zama (JP); Toshiki SASAKI, Kawasaki (JP); Hiromi SEO, Sagamihara (JP); Shinya FUKUZAKI, Atsugi (JP)

(73) Assignee: Semiconductor Energy Laboratory Co., Ltd., Kanagawa-ken (JP)

(21) Appl. No.: 18/999,401

(22) Filed: Dec. 23, 2024

(30) Foreign Application Priority Data
Dec. 26, 2023 (JP) 2023-219947

(51) Int. Cl. H10K 85/60; H10K 50/17; H10K 101/40

(52) U.S. Cl. CPC H10K 85/654; H10K 85/6572; H10K 50/171; H10K 2101/40

(57) ABSTRACT

A light-emitting device driven at a low voltage is provided. The light-emitting device includes a first electrode, a second electrode, and an organic compound layer. The organic compound layer is positioned between the first electrode and the second electrode. The organic compound layer includes a light-emitting layer and an electron-injection layer. The electron-injection layer includes a metal or a metal oxide, a first organic compound, and a second organic compound. The first organic compound includes a π-electron deficient heteroaromatic ring. The second organic compound includes two or more heteroaromatic rings that are bonded or condensed to each other and include three or more heteroatoms in total. The second organic compound has a function of interacting with the metal or the metal oxide by two or more of the three or more heteroatoms as a multidentate ligand.

### BACKGROUND OF THE INVENTION

### 1. Field of the Invention

One embodiment of the present invention relates to a light-emitting device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), driving methods thereof, and manufacturing methods thereof.

### 2. Description of the Related Art

Display devices are being developed into a variety of applications these days. For example, a television device for home use (also referred to as TV or television receiver), digital signage, and a public information display (PID) are being developed as large-sized display devices, and a smartphone and a tablet terminal each provided with a touch panel are being developed as small-sized display devices.

At the same time, an increase in the resolution of display devices is also required. For example, devices for virtual reality (VR), augmented reality (AR), substitutional reality (SR), or mixed reality (MR) are given as devices requiring high-resolution display devices and are being developed actively.

Development is actively conducted on light-emitting devices (also referred to as light-emitting elements) as display elements used in display devices. Light-emitting devices utilizing electroluminescence (hereinafter referred to as EL; such devices are also referred to as EL devices or EL elements), particularly organic EL devices that mainly use organic compounds, are suitable for display devices because of having features such as ease of reduction in thickness and weight, high-speed response to input signals, and driving with a constant DC voltage power source.

In order to obtain a higher-resolution light-emitting apparatus using an organic EL device, patterning an organic layer by a photolithography method using a photoresist or the like, instead of an evaporation method using a metal mask, has been studied. By using the photolithography method, a high-resolution display device in which the distance between EL layers is several micrometers can be obtained (see Patent Document 1, for example).

### REFERENCE

### Patent Document

[Patent Document 1] Japanese Translation of PCT International Application No. 2018-521459

### SUMMARY OF THE INVENTION

It has been known that EL layers in an organic EL device (the organic EL device is also referred to as a light-emitting device in this specification) exposed to atmospheric components such as water and oxygen have affected initial characteristics and reliability, and thus it has been common knowledge that the EL layers are treated in a near-vacuum atmosphere. In particular, an electron-injection layer, which includes an alkali metal, an alkaline earth metal, or a compound thereof highly reactive with water or oxygen, rapidly deteriorates and loses the function as the electron-injection layer when the surface of the EL layer is exposed to the air.

However, processing steps by the aforementioned photolithography method inevitably expose the surface of the EL layer to the air.

An object of one embodiment of the present invention is to provide a novel light-emitting device. An object of another embodiment of the present invention is to provide a highly efficient light-emitting device. An object of another embodiment of the present invention is to provide a highly reliable light-emitting device. An object of another embodiment of the present invention is to provide a highly efficient and highly reliable light-emitting device.

An object of another embodiment of the present invention is to provide a novel light-emitting device manufactured through a photolithography process. An object of another embodiment of the present invention is to provide a highly efficient light-emitting device manufactured through a photolithography process. An object of another embodiment of the present invention is to provide a highly reliable light-emitting device manufactured through a photolithography process. An object of another embodiment of the present invention is to provide a high-emission-efficiency and highly reliable light-emitting device manufactured through a photolithography process.

An object of another embodiment of the present invention is to provide a novel light-emitting device capable of being used in a high-resolution display device. An object of another embodiment of the present invention is to provide a highly efficient light-emitting device capable of being used in a high-resolution display device. An object of another embodiment of the present invention is to provide a highly reliable light-emitting device capable of being used in a high-resolution display device. An object of another embodiment of the present invention is to provide a high-emission-efficiency and highly reliable light-emitting device capable of being used in a high-resolution display device.

An object of another embodiment of the present invention is to provide a highly reliable display device. An object of another embodiment of the present invention is to provide a high-resolution display device. An object of another embodiment of the present invention is to provide a highly reliable and high-resolution display device.

Note that the description of these objects does not preclude the presence of other objects. One embodiment of the present invention does not necessarily achieve all of these objects. Other objects can be derived from the description of the specification, the drawings, and the claims.

One embodiment of the present invention is a light-emitting device including a first electrode, a second electrode, and an organic compound layer. The organic compound layer is positioned between the first electrode and the second electrode. The organic compound layer includes a light-emitting layer and an electron-injection layer. The electron-injection layer includes a metal or a metal oxide, a first organic compound, and a second organic compound. The first organic compound includes a π-electron deficient heteroaromatic ring. The second organic compound includes two or more heteroaromatic rings that are bonded or condensed to each other and include three or more heteroatoms in total. The second organic compound has a function of interacting with the metal or the metal oxide by two or more of the three or more heteroatoms as a multidentate ligand.

Another embodiment of the present invention is a light-emitting device that is one of a plurality of light-emitting devices included in a light-emitting device group. The light-emitting device group includes a first electrode group formed over one insulating surface, a second electrode facing the first electrode group, and a first layer group positioned between the first electrode group and the second electrode. The light-emitting device includes a first electrode, a second electrode, and a first layer. The first electrode is one included in the first electrode group. The first electrode is independent for each of the plurality of light-emitting devices. The first layer is one included in the first layer group. The first layer is independent for each of the plurality of light-emitting devices. The second electrode is a continuous conductive layer shared by the plurality of light-emitting devices. The second electrode and the first layer overlap with the first electrode. The first layer includes a light-emitting layer and an electron-injection layer. The electron-injection layer includes a metal or a metal oxide, a first organic compound, and a second organic compound. The first organic compound includes a π-electron deficient heteroaromatic ring. The second organic compound includes two or more heteroaromatic rings that are bonded or condensed to each other and include three or more heteroatoms in total. The second organic compound has a function of interacting with the metal or the metal oxide by two or more of the three or more heteroatoms as a multidentate ligand. The distance between the first layer included in the light-emitting device and the first layer included in another light-emitting device adjacent to the light-emitting device is greater than or equal to 0.5 μm and less than or equal to 5 μm.

In the light-emitting device of the above embodiment of the invention, the second organic compound has a function of interacting with the metal or the metal oxide by the heteroatoms as a bidentate or tridentate ligand.

In the light-emitting device of the above embodiment of the invention, the heteroatoms are each a nitrogen atom.

Another embodiment of the present invention is a light-emitting device including a first electrode, a second electrode, and an organic compound layer. The organic compound layer is positioned between the first electrode and the second electrode. The organic compound layer includes a light-emitting layer and an electron-injection layer. The electron-injection layer includes a metal or a metal oxide, a first organic compound, and a second organic compound. The first organic compound includes a π-electron deficient heteroaromatic ring. The second organic compound is represented by General Formula (G1-1).

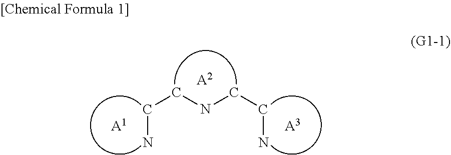

In General Formula (G1-1), A¹, A², and A³ independently represent a substituted or unsubstituted heteroaromatic ring having 1 to 30 carbon atoms, and A¹, A², and A³ may form a condensed ring with each other.

Another embodiment of the present invention is a light-emitting device including a first electrode, a second electrode, and an organic compound layer. The organic compound layer is positioned between the first electrode and the second electrode. The organic compound layer includes a light-emitting layer and an electron-injection layer. The electron-injection layer includes a metal or a metal oxide, a first organic compound, and a second organic compound. The first organic compound includes a π-electron deficient heteroaromatic ring. The second organic compound is represented by General Formula (G1-2).

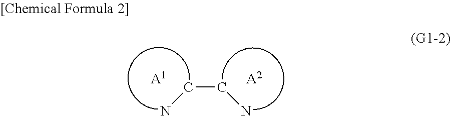

In General Formula (G1-2), A¹ and A² independently represent a substituted or unsubstituted heteroaromatic ring having 1 to 30 carbon atoms, A¹ and A² may form a condensed ring with each other, and A¹ includes two or more nitrogen atoms.

In the light-emitting device of any of the above embodiments, the heteroaromatic ring is a π-electron deficient heteroaromatic ring.

In the light-emitting device of any of the above embodiments, the heteroaromatic ring includes at least one of a pyridine ring, a diazine ring (a pyrazine ring, a pyrimidine ring, or a pyridazine ring), a triazine ring, an azole ring (an imidazole ring, a pyrazole ring, an oxazole ring, or a thiazole ring), and a triazole ring.

In the light-emitting device of any of the above embodiments, at least one of the two or more heteroaromatic rings includes a diazine ring (a pyrazine ring, a pyrimidine ring, or a pyridazine ring) or a triazine ring.

In the light-emitting device of any of the above embodiments, the two or more heteroaromatic rings include three or more pyridine rings in total.

In the light-emitting device of any of the above embodiments, the first organic compound includes an electron-donating group.

In the light-emitting device of any of the above embodiments, the electron-donating group includes at least one of an alkyl group, an alkoxy group, an aryloxy group, an alkylamino group, an arylamino group, and a heterocyclic amino group.

In the light-emitting device of any of the above embodiments, the first organic compound has an acid dissociation constant pKₐ of 8 or more.

In the light-emitting device of any of the above embodiments, the first organic compound includes a phenanthroline ring.

In the light-emitting device of any of the above embodiments, the second organic compound has a glass transition temperature T_{g} of 100° C. or higher.

In the light-emitting device of any of the above embodiments, the lowest unoccupied molecular orbital (LUMO) level of the second organic compound is lower than the LUMO level of the first organic compound.

In the light-emitting device of any of the above embodiments, the metal belongs to Group 1, 3, 11, or 13 of the periodic table.

In the light-emitting device of any of the above embodiments, the first layer is a mixture of the metal, the second organic compound, and the first organic compound.

In the light-emitting device of any of the above embodiments, the first layer has a stacked-layer structure of a layer containing the metal and a layer containing the second organic compound or the first organic compound.

Another embodiment of the present invention is a light-emitting apparatus including a plurality of light-emitting devices, each of which is any of the light-emitting devices described above. Each of the plurality of light-emitting devices includes an organic compound layer including a light-emitting layer and an electron-injection layer between the first electrode and the second electrode. The organic compound layer included in each of the plurality of light-emitting devices is independent between the plurality of light-emitting devices.

Another embodiment of the present invention is a display module including any of the above-described light-emitting devices and at least one of a connector and an integrated circuit.

Another embodiment of the present invention is an electronic device including any of the above-described light-emitting devices and at least one of a housing, a battery, a camera, a speaker, and a microphone.

With one embodiment of the present invention, a novel light-emitting device can be provided. With another embodiment of the present invention, a highly efficient light-emitting device can be provided. With another embodiment of the present invention, a highly reliable light-emitting device can be provided. With another embodiment of the present invention, a highly efficient and highly reliable light-emitting device can be provided.

With another embodiment of the present invention, a novel light-emitting device manufactured through a photolithography process can be provided. With another embodiment of the present invention, a highly efficient light-emitting device manufactured through a photolithography process can be provided. With another embodiment of the present invention, a highly reliable light-emitting device manufactured through a photolithography process can be provided. With another embodiment of the present invention, a high-emission-efficiency and highly reliable light-emitting device manufactured through a photolithography process can be provided.

With another embodiment of the present invention, a novel light-emitting device capable of being used in a high-resolution display device can be provided. With another embodiment of the present invention, a highly efficient light-emitting device capable of being used in a high-resolution display device can be provided. With another embodiment of the present invention, a highly reliable light-emitting device capable of being used in a high-resolution display device can be provided. With another embodiment of the present invention, a high-emission-efficiency and highly reliable light-emitting device capable of being used in a high-resolution display device can be provided.

With another embodiment of the present invention, a highly reliable display device can be provided. With another embodiment of the present invention, a high-resolution display device can be provided. With another embodiment of the present invention, a highly reliable and high-resolution display device can be provided.

With another embodiment of the present invention, a novel organic compound, a novel light-emitting device, a novel display device, a novel display module, and a novel electronic device can be provided.

Note that the description of these effects does not preclude the presence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIGS. 1A and 1B illustrate light-emitting devices;

FIG. 2 shows an analysis result of spin density distribution of a composite material in a ground state;

FIG. 3 shows a result of analyzing an electrostatic potential map of a composite material in a ground state;

FIGS. 4A and 4B illustrate light-emitting devices;

FIGS. 5A and 5B illustrate light-emitting devices;

FIGS. 6A and 6B are a top view and a cross-sectional view of a light-emitting apparatus;

FIGS. 7A to 7D illustrate light-emitting devices;

FIGS. 8A to 8E are cross-sectional views illustrating an example of a method for manufacturing a display device;

FIGS. 9A and 9B are cross-sectional views illustrating an example of a method for manufacturing a display device;

FIGS. 10A to 10D are cross-sectional views illustrating an example of a method for manufacturing a display device;

FIGS. 11A to 11C are cross-sectional views illustrating an example of a method for manufacturing a display device;

FIGS. 12A to 12C are cross-sectional views illustrating an example of a method for manufacturing a display device;

FIGS. 13A to 13C are cross-sectional views illustrating an example of a method for manufacturing a display device;

FIGS. 14A to 14G are top views each illustrating a structure example of a pixel;

FIGS. 15A to 15I are top views each illustrating a structure example of a pixel;

FIGS. 16A and 16B are perspective views illustrating a structure example of a display module;

FIGS. 17A and 17B are cross-sectional views each illustrating a structure example of a display device;

FIG. 18 is a perspective view illustrating a structure example of a display device;

FIG. 19 is a cross-sectional view illustrating a structure example of a display device;

FIG. 20 is a cross-sectional view illustrating a structure example of a display device;

FIGS. 21A to 21C are views illustrating a structure example of a display device;

FIG. 22 is a cross-sectional view illustrating a structure example of a display device;

FIGS. 23A to 23C are views illustrating a structure example of a display device;

FIGS. 24A to 24D illustrate examples of electronic devices;

FIGS. 25A to 25F illustrate examples of electronic devices;

FIGS. 26A to 26G illustrate examples of electronic devices;

FIG. 27 is a diagram illustrating a structure of a light-emitting device;

FIG. 28 shows luminance-current density characteristics of light-emitting devices;

FIG. 29 shows luminance-voltage characteristics of the light-emitting devices;

FIG. 30 shows current efficiency-luminance characteristics of the light-emitting devices;

FIG. 31 shows current density-voltage characteristics of the light-emitting devices;

FIG. 32 shows electroluminescence spectra of the light-emitting devices;

FIG. 33 shows voltages with respect to a constant current density of the light-emitting devices;

FIG. 34 shows an ESR measurement result of a sample in this example;

FIG. 35 shows a driving time-dependent change in luminance of the light-emitting devices;

FIG. 36 shows luminance-current density characteristics of light-emitting devices;

FIG. 37 shows luminance-voltage characteristics of the light-emitting devices;

FIG. 38 shows current efficiency-luminance characteristics of the light-emitting devices;

FIG. 39 shows current density-voltage characteristics of the light-emitting devices;

FIG. 40 shows electroluminescence spectra of the light-emitting devices; and

FIG. 41 shows a driving time-dependent change in luminance of the light-emitting devices.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

In this specification and the like, a device formed using a metal mask or a fine metal mask (FMM, a high-resolution metal mask) is sometimes referred to as a device having a metal mask (MM) structure. In this specification and the like, a device formed without using a metal mask or an FMM is sometimes referred to as a device having a metal maskless (MML) structure.

### Embodiment 1

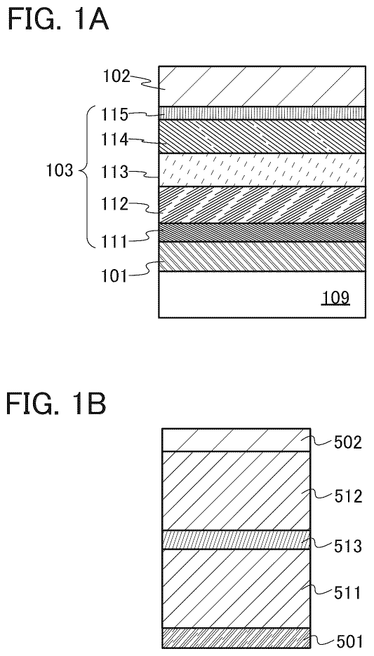

FIG. 1A is a schematic diagram of a light-emitting device of one embodiment of the present invention. The light-emitting device includes a first electrode 101 over an insulator 109, and an organic compound layer (also referred to as EL layer) 103 between the first electrode 101 and a second electrode 102. The organic compound layer 103 includes at least a light-emitting layer 113 and an electron-injection layer 115. The light-emitting layer 113 contains a light-emitting substance and emits light when voltage is applied between the first electrode 101 and the second electrode 102.

The organic compound layer 103 preferably includes, besides the light-emitting layer 113 and the electron-injection layer 115, functional layers such as a hole-injection layer 111, a hole-transport layer 112, and an electron-transport layer 114, as illustrated in FIG. 1A. The organic compound layer 103 may include functional layers other than the above functional layers, such as a hole-blocking layer, an exciton-blocking layer, and an intermediate layer. Alternatively, any of the above-described layers may be omitted.

As a method for forming an organic film in a predetermined shape, a vacuum evaporation method with a metal mask (mask vapor deposition) is widely used. However, in these days of higher density and higher resolution, mask vapor deposition has come close to the limit of increasing the resolution for various reasons such as the alignment accuracy and the distance between the mask and the substrate. An organic semiconductor device having a finer pattern is expected to be achieved by shape processing of an organic film by a photolithography method. Moreover, since a photolithography method achieves large-area processing more easily than mask vapor deposition, processing of an organic film by the photolithography method is being researched.

It has been known that EL layers in an organic EL device exposed to atmospheric components such as water and oxygen have affected initial characteristics or reliability, and thus it has been common knowledge that the EL layers are treated in a near-vacuum atmosphere.

In particular, an electron-injection layer in a light-emitting device, which includes an alkali metal, an alkaline earth metal, or a compound thereof (hereinafter also referred to as a Li compound or the like) highly reactive with water or oxygen, rapidly deteriorates and loses the function as the electron-injection layer when being exposed to the air.

However, processing steps by the aforementioned photolithography method inevitably expose the surface of the EL layer to the air. The processing by the photolithography method therefore causes a significant deterioration of the electron-injection properties of an electron-injection layer using an alkali metal compound or the like. Thus, an organic EL device that includes an electron-injection layer using an alkali metal compound or the like and is processed by a photolithography method has increased driving voltage and is hard to obtain favorable characteristics.

In view of the above, the electron-injection layer 115 of one embodiment of the present invention includes a metal or metal oxide, a first organic compound having a π-electron deficient heteroaromatic ring, and a second organic compound having two or more heteroaromatic rings that are bonded or condensed to each other and include three or more heteroatoms in total. Accordingly, an organic EL device with favorable characteristics can be provided even through a photolithography process involving exposure of the organic compound layer to the air.

In the electron-injection layer 115 with this structure, the first organic compound functions as an electron donor (donating electrons) to the second organic compound, and the first organic compound, the metal or metal oxide, and the second organic compound interact with each other to form a donor level (a singly occupied molecular orbital (SOMO) level or a highest occupied molecular orbital (HOMO) level). When the first organic compound, the metal or metal oxide, and the second organic compound interact with each other, the donor level (SOMO level or HOMO level) becomes high and a barrier against electron injection from the electron-injection layer to the electron-transport layer can be lowered. The interaction enables electrons to be injected and transported smoothly from the electron-injection layer 115 to the electron-transport layer 114. Accordingly, a light-emitting device with a low driving voltage can be manufactured.

Note that the LUMO level and the HOMO level of an organic compound are generally estimated by cyclic voltammetry (CV), photoelectron spectroscopy, optical absorption spectroscopy, inverse photoelectron spectroscopy, or the like. When values of different compounds are compared with each other, it is preferable that values estimated by the same measurement be used.

The SOMO level is an orbital derived from an unpaired electron of a metal, and when the metal or metal oxide, the first organic compound, and the second organic compound interact with each other, the SOMO level can also be distributed on the orbitals of the first organic compound and the second organic compound. In other words, the electron orbital of the metal or metal oxide and the electron orbitals of the organic compounds interact with each other.

Note that an organic compound containing a large number of atoms that enable an interaction can interact more stably with a metal or metal oxide. Thus, the second organic compound used in one embodiment of the present invention is preferably a material that interacts with a metal or metal oxide as a multidentate ligand of a bi-, tri- or higher dentate ligand. An organic compound interacting with a metal or metal oxide as a multidentate ligand is stabilized when interacting with the metal or metal oxide; thus, an electron-injection layer having resistance to oxygen and water in the air and water and a chemical solution used in the process by a lithography method can be formed.

Examples of the atom that enables an interaction include a heteroatom having an unshared electron pair in an organic compound. For example, oxygen (O), nitrogen (N), sulfur (S), and phosphorus (P) are given, and nitrogen is preferable. Nitrogen has high electronegativity and thus easily interacts with a metal or metal oxide. Here, since nitrogen can form a conjugated bond in an organic compound, nitrogen enables the organic compound to have a high carrier-transport property when used in the molecule, particularly in a heteroaromatic ring. It is further preferable that the heteroaromatic ring be an even-numbered ring such as a six-membered ring or an eight-membered ring. Since the unshared electron pair of nitrogen does not contribute to the conjugation in this structure, nitrogen is likely to interact with a metal or metal oxide.

By the interaction between the metal or metal oxide, the first organic compound, and the second organic compound, a donor level (SOMO level or HOMO level) can be formed, a barrier against electron injection to the electron-transport layer can be lowered, and electrons can be injected and transported smoothly from the electron-injection layer to the electron-transport layer. The heteroaromatic ring included in the second organic compound is preferably a π-electron deficient heteroaromatic ring. With this structure, the second organic compound can have an electron-transport property, and electrons can be injected and transported smoothly from the electron-injection layer to the electron-transport layer. When the second organic compound includes two or more heteroaromatic rings that are bonded or condensed to each other and include three or more nitrogen atoms in total, the LUMO level of the second organic compound can be lower than that of the first organic compound. When a material whose LUMO level is lower than that of the first organic compound is used for the second organic compound, interaction between the metal or metal oxide, the first organic compound, and the second organic compound brings about stabilization.

The first organic compound preferably includes a π-electron deficient heteroaromatic ring having an unshared electron pair. This structure enables a stable interaction with the metal or metal oxide. The first organic compound is preferably a material that includes two or more π-electron deficient heteroaromatic rings each having an unshared electron pair and interacts with a metal or metal oxide as a multidentate ligand such as a bi- or higher dentate ligand. An organic compound that interacts with a metal or metal oxide as a multidentate ligand such as a bi- or higher dentate ligand is stabilized when interacting with the metal or metal oxide.

The first organic compound preferably includes an electron-donating substituent. With this structure, the first organic compound can have a high HOMO level and a high LUMO level; thus, the difference between the LUMO level of the first organic compound and the LUMO level of the second organic compound can be increased. Thus, further stabilization is achieved when the metal or metal oxide, the first organic compound, and the second organic compound interact with each other.

As described above, the first organic compound and the second organic compound can be stabilized when interacting with each other; thus, electrons can be injected and transported smoothly from the electron-injection layer to the adjacent electron-transport layer even through a photolithography process involving exposure of the EL layer to the air. Accordingly, the light-emitting device with a suppressed increase in driving voltage, high emission efficiency, and high reliability can be manufactured by a photolithography process.

Since a metal with a low work function typified by an alkali metal and an alkaline earth metal and a compound of such a metal have high reactivity with oxygen or water, using the metal or the compound for a light-emitting device manufactured through processing by a lithography method may cause a reduction in emission efficiency, an increase in driving voltage, a reduction in driving lifetime, generation of shrinkage (a non-emission region at an end portion of a light-emitting portion), or the like, leading to deterioration in the characteristics or a reduction in the reliability of the light-emitting device.

Meanwhile, in one embodiment of the present invention, even when an alkali metal, an alkaline earth metal, or a compound thereof is used, the alkali metal, the alkaline earth metal, or the compound thereof interacts with the first organic compound having a π-electron deficient heteroaromatic ring and the second organic compound having two or more heteroaromatic rings that are bonded or condensed to each other and include three or more heteroatoms in total, resulting in stabilization; thus, an electron-injection layer having resistance to oxygen and water in the air and water and a chemical solution used in a lithography process can be formed.

When an alkali metal, an alkaline earth metal, or a compound thereof is used as the metal in one embodiment of the present invention, the donor level (SOMO level or HOMO level) that is formed by interaction between the metal, the first organic compound having a π-electron deficient heteroaromatic ring, and the second organic compound having two or more heteroaromatic rings that are bonded or condensed to each other and include three or more heteroatoms in total can be a high energy level. This structure is preferable because it lowers a barrier against electron injection from the electron-injection layer to the electron-transport layer and enables electrons to be injected and transported smoothly from the electron-injection layer to the electron-transport layer.

Furthermore, since transition metals (metal elements belonging to Group 3 to Group 11) and metal elements belonging to Group 12 to Group 14 of the typical metal elements have low reactivity with oxygen and water in the air and water and a chemical solution used in a lithography process, the use of such a metal in a light-emitting device hardly causes deterioration due to water and oxygen, which might occur when a metal having a low work function is used. By contrast, such metals are stable and have a low electron-injection property, which may cause a reduction in emission efficiency, an increase in driving voltage, a reduction in driving lifetime, and the like of the light-emitting device.

In the electron-injection layer of one embodiment of the present invention, even when any of transition metals (metal elements belonging to Group 3 to Group 11) and metal elements belonging to Group 12 to Group 14 of the typical metals is used, the first organic compound having a π-electron deficient heteroaromatic ring interacts with the second organic compound having two or more heteroaromatic rings that are bonded or condensed to each other and include three or more heteroatoms in total, so that a donor level (SOMO level or HOMO level) is formed. That is, this structure lowers a barrier against electron injection from the electron-injection layer to the electron-transport layer and enables electrons to be injected and transported smoothly from the electron-injection layer to the electron-transport layer. In addition, the structure is resistant to oxygen and water in the air and water and a chemical solution used in a lithography process; as a result, one embodiment of the present invention can provide a light-emitting device that has high moisture resistance, high water resistance, high oxygen resistance, high chemical resistance, a low driving voltage, and high emission efficiency.

### <Quantum Chemical Calculation Analysis of Interaction Between Metal or Metal Oxide and Organic Compound>

Here, quantum chemical calculation analysis is performed on the case where the metal or metal oxide, the first organic compound having an electron-donating property and an unshared electron pair, and the second organic compound having an electron-transport property interact with each other.

### [Estimation of Interaction Between Metal or Metal Oxide and Organic Compound]

Here, quantum chemical calculation analysis is performed on the spin density and electrostatic potential (ESP) obtained at the time when the metal or metal oxide, the first organic compound having a π-electron deficient heteroaromatic ring, and the second organic compound having two or more heteroaromatic rings that are bonded or condensed to each other and include three or more heteroatoms in total interact with each other. Note that in the calculation, 4,7-di-1-pyrrolidinyl-1,10-phenanthroline (abbreviation: Pyrrd-Phen) is used as the first organic compound, 2,2′-(2,2′-bipyridine-6,6′-diyl)bis(4-phenylbenzo[h]quinazoline (abbreviation: 6,6′(P-Bqn)2BPy) is used as the second organic compound, and lithium (Li) is used as the metal.

As the quantum chemistry computational program, Gaussian 09 is used. The calculation is performed using SGI 8600 (manufactured by Hewlett Packard Enterprise (HPE)). The most stable structures of the first organic compound alone in a ground state, the second organic compound alone in a ground state, and a composite material in a ground state of the first organic compound, the second organic compound, and the metal or metal oxide are calculated by the density functional theory (DFT). As a basis function, 6-311G(d,p) is used, and as a functional, B3LYP is used. In the DFT, the total energy is represented as the sum of potential energy, electrostatic energy between electrons, electronic kinetic energy, and exchange-correlation energy including all the complicated interactions between electrons. Also in the DFT, exchange-correlation interaction is approximated by a functional (a function of another function) of one electron potential represented in terms of electron density to enable highly accurate calculations.

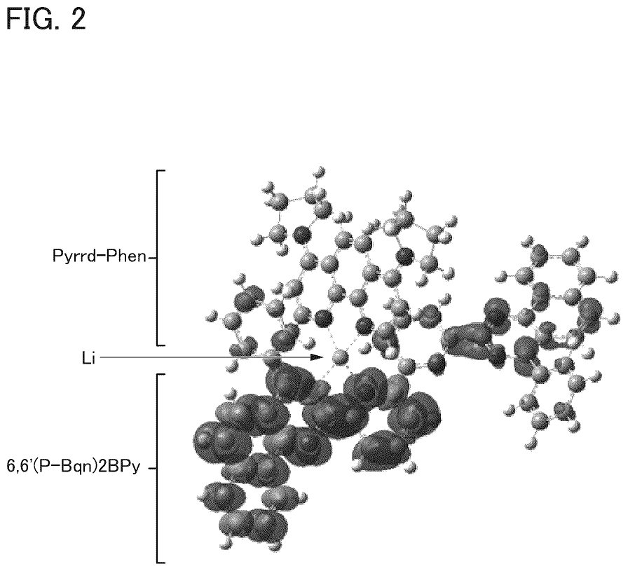

FIG. 2 shows an analysis result of the spin density distribution of the composite material in the ground state of the first organic compound (Pyrrd-Phen), the second organic compound (6,6′(P-Bqn)2BPy), and the metal (Li). In the diagrams, spheres represent atoms included in the compounds, and clouds around some of the atoms represent spin density distribution at the time when the density value in atomic units is 0.0004 e/a₀³ (where e represents elementary charge (1 e=1.60218×10⁻¹⁹ C) and a₀ represents a Bohr radius (1 a₀=5.29177×10⁻¹¹ m)). The clouds represent localization of the doublet ground state of the compounds. Note that no spin density distribution is observed in the first organic compound (Pyrrd-Phen) in a ground state and the second organic compound (6,6′(P-Bqn)2BPy) in a ground state because the ground states of the first organic compound and the second organic compound are singlet ground states.

Meanwhile, in the composite material of the first organic compound (Pyrrd-Phen), the second organic compound (6,6′(P-Bqn)2BPy), and the metal (Li), which is one embodiment of the present invention, in the doublet ground state, the first organic compound (Pyrrd-Phen), the second organic compound (6,6′(P-Bqn)2BPy), and the metal (Li) interact with one another, and the metal (Li) is coordinated to nitrogen atoms (N atoms at 1- and 10-positions) having unshared electron pairs in the 1,10-phenanthroline ring of the first organic compound (Pyrrd-Phen) and nitrogen atoms having unshared electron pairs in the pyridine ring and benzo[h]quinazoline ring of the second organic compound (6,6′(P-Bqn)2BPy), which leads to stabilization of the formed composite material. Thus, as shown in FIG. 2, spins derived from unpaired electrons included in the metal (Li) are localized in the second organic compound (6,6′(P-Bqn)2BPy). Furthermore, a spin density distribution is not observed in the metal (Li). This indicates that the second organic compound (6,6′(P-Bqn)2BPy) is in a radical anion state owing to the interaction between the first organic compound (Pyrrd-Phen), the second organic compound (6,6′(P-Bqn)2BPy), and the metal (Li).

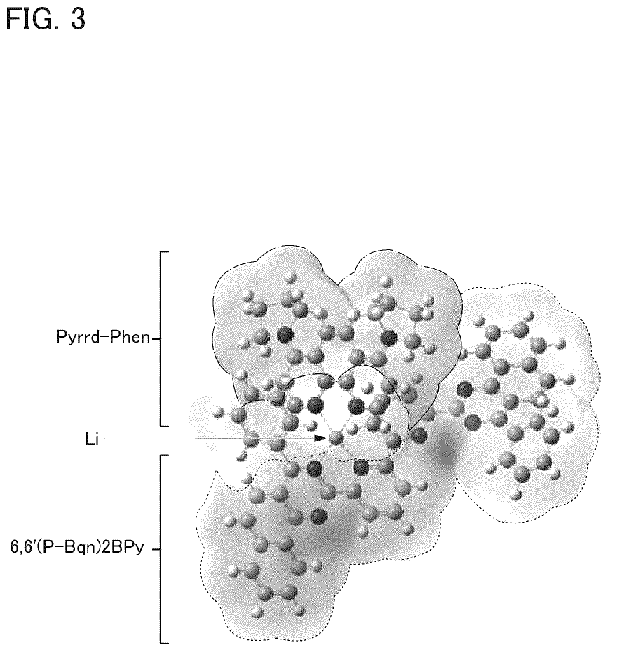

Next, FIG. 3 shows an analysis result of the electrostatic potential map of the composite material in the ground state of the first organic compound (Pyrrd-Phen), the second organic compound (6,6′(P-Bqn)2BPy), and the metal (Li). In the diagram, spheres represent atoms included in the compounds, and clouds around some of the atoms represent electrostatic potentials in electron density distribution at the time when the density value in atomic units is 0.0004 e/a₀³. An electrostatic potential is the energy of interaction between positive point charge with unit quantity of electricity and electron distribution of a molecule. An electrostatic potential map denotes an electrostatic potential on an electron density isosurface in colors; in the map, a region with a negative electrostatic potential is denoted in red, a region with a positive electrostatic potential is denoted in blue, an atom in the region with a negative electrostatic potential has negative charge, and an atom in the region with a positive electrostatic potential has positive charge. FIG. 3 is a grayscale diagram converted from a colored image, and the region with a negative electrostatic potential corresponds to a region surrounded by a dotted line, and the region with a positive electrostatic potential corresponds to a region surrounded by a dashed-dotted line.

Meanwhile, in the composite material of the first organic compound (Pyrrd-Phen), the second organic compound (6,6′(P-Bqn)2BPy), and the metal (Li), which is one embodiment of the present invention, in the doublet ground state, the first organic compound (Pyrrd-Phen), the second organic compound (6,6′(P-Bqn)2BPy), and the metal (Li) interact with one another, and the metal (Li) is coordinated to nitrogen atoms (N atoms at 1- and 10-positions) having unshared electron pairs in the 1,10-phenanthroline ring of the first organic compound (Pyrrd-Phen) and nitrogen atoms having unshared electron pairs in the pyridine ring and benzo[h]quinazoline ring of the second organic compound (6,6′(P-Bqn)2BPy), which leads to stabilization of the formed composite material. Accordingly, as shown in FIG. 3, a positive electrostatic potential is mainly distributed in the metal (Li) and the first organic compound (Pyrrd-Phen), and a negative electrostatic potential is mainly distributed in the second organic compound (6,6′(P-Bqn)2BPy). It is also shown that the electrostatic potential of the nitrogen atoms having unshared electron pairs in the pyridine ring and the benzo[h]quinazoline ring of the second organic compound (6,6′(P-Bqn)2BPy) is negative whereas the electrostatic potential of the metal (Li) is positive. The Li atom has a Mulliken partial charge of +0.691 e in atomic units.

### [Estimation of SOMO Level or Stabilization Energy]

Next, a quantum chemical calculation is performed for estimation of the stabilization energy when the metal or metal oxide, the first organic compound having a π-electron deficient heteroaromatic ring, and the second organic compound having two or more heteroaromatic rings that are bonded or condensed to each other and include three or more heteroatoms in total interact with each other, and the SOMO level formed at this time.

As the quantum chemistry computational program, Gaussian 09 is used. The calculation is performed using HPE SGI 8600. First, the most stable structures of the first organic compound in a ground state, the second organic compound in a ground state, the metal or metal oxide in a ground state, the composite material in a ground state of the first organic compound and the metal or metal oxide, the composite material in a ground state of the second organic compound and the metal or metal oxide, and the composite material in a ground state of the first organic compound, the second organic compound, and the metal or metal oxide are calculated by DFT. As basis functions, 6-311G(d,p) and LanL2DZ are used, and as a functional, B3LYP is used. Next, the stabilization energy is calculated by subtracting the sum of the total energy of the organic compound(s) alone and the total energy of the metal or metal oxide alone from the total energy of the composite material of the organic compound(s) and the metal or metal oxide. That is, (stabilization energy)=(the total energy of the composite material of the organic compound(s) and the metal or metal oxide)−(the total energy of the organic compound(s) alone)−(the total energy of the metal or metal oxide alone).

The calculation result of a composite material including lithium (Li) as the metal or metal oxide, 4,7-di-1-pyrrolidinyl-1,10-phenanthroline (abbreviation: Pyrrd-Phen) as the first organic compound, and 2,2′-(2,2′-bipyridine-6,6′-diyl)bis(4-phenylbenzo[h]quinazoline) (abbreviation: 6,6′(P-Bqn)2BPy) as the second organic compound is shown in Table 1 below. For comparison, the following also shows the calculation result of a composite material including lithium (Li) as the metal or metal oxide, Pyrrd-Phen as the first organic compound, and 2,9-di(naphthalen-2-yl)-4,7-diphenyl-1,10-phenanthroline (abbreviation: NBPhen) in place of 6,6′(P-Bqn)2BPy as the second organic compound; the calculation result of a composite material including lithium (Li) and Pyrrd-Phen; the calculation result of a composite material including lithium (Li) and 6,6′(P-Bqn)2Bpy; and the calculation result of a composite material including lithium (Li) and NBPhen. Note that 6,6′(P-Bqn)2BPy is the second organic compound having two or more heteroaromatic rings that are bonded or condensed to each other and include three or more heteroatoms in total. NBPhen is an organic compound having two or more heteroaromatic rings that are bonded or condensed to each other and include less than three heteroatoms in total.

TABLE 1

| | Stabilization | |
|---|---|---|
| | energy (eV) | SOMO (eV) |
| Pyrrd-Phen + 6,6′(P-Bqn)2BPy + Li | −3.79 | −2.32 |
| Pyrrd-Phen + NBPhen + Li | −3.67 | −2.35 |
| Pyrrd-Phen + Li | −2.17 | −2.46 |
| 6,6′(P-Bqn)2BPy + Li | −3.07 | −2.88 |
| NBPhen + Li | −2.31 | −2.96 |

TABLE 2

| | LUMO (eV) | HOMO (eV) |
|---|---|---|
| Pyrrd-Phen | −1.35 | −5.65 |
| 6,6′(P-Bqn)2BPy | −2.07 | −5.99 |
| tPy2P | −1.65 | −6.37 |
| 2Py3Tzn | −2.20 | −6.89 |
| NBPhen | −2.04 | −5.74 |

As shown in Table 1, the stabilization energy of the composite material of lithium (Li), the first organic compound (Pyrrd-Phen), and the second organic compound (6,6′(P-Bqn)2BPy) of one embodiment of the present invention has a negative value having a larger absolute value. This indicates that energy is more stable in the case where the organic compounds and the metal interact with each other than in the case where the organic compounds and the metal do not interact with each other. The SOMO level formed at this time is preferable because it is higher than the HOMO level of each of the first organic compound (Pyrrd-Phen) and the second organic compound (6,6′(P-Bqn)2BPy) shown in Table 2 and has a small difference from the LUMO level of each of the first organic compound (Pyrrd-Phen) and the second organic compound (6,6′(P-Bqn)2BPy), offering a high electron-injection property. Note that the values of the energy levels of the SOMO, HOMO, and LUMO levels in Tables 1 and 2 are calculated values and might have absolute values different from those of the measured values.

Although not as much as the composite material of lithium (Li), the first organic compound (Pyrrd-Phen), and the second organic compound (6,6′(P-Bqn)2BPy), the composite material of lithium (Li), the first organic compound (Pyrrd-Phen), and NBPhen has a negative value of the stabilization energy, and the energy is more stable in the case where the organic compounds and the metal interact with each other than in the case where the organic compounds and the metal do not interact with each other.

The composite material of lithium (Li) and the first organic compound (Pyrrd-Phen) has a negative value of the stabilization energy, and will be further stabilized when further including the second organic compound.

The composite material of lithium (Li) and the second organic compound (6,6′(P-Bqn)2BPy) has a slightly low SOMO level, and will excel in electron-injection properties when further including the first organic compound. The composite material of lithium (Li) and NBPhen has a negative value of the stabilization energy, and will be further stabilized when further including the first organic compound. In addition, the composite material of lithium (Li) and NBPhen has a low SOMO level, and will excel in electron-injection properties when further including the first organic compound. That is to say, the composite material of one embodiment of the present invention, which includes the metal or metal oxide, the first organic compound having a π-electron deficient heteroaromatic ring, and the second organic compound having two or more heteroaromatic rings that are bonded or condensed to each other and include three or more heteroatoms in total, is stable and has a high electron-injection property, and thus is suitable for an electron-injection layer.

Next, the following tables show calculation results of composite materials including a metal belonging to Group 11 or Group 13, specifically silver (Ag) or indium (In), as the metal or metal oxide; Pyrrd-Phen as the first organic compound; and 4′,4′″-(1,4-phenylene)bis(2,2′:6′,2″-terpyridine) (abbreviation: tPy2P) or 2,4,6-tris(2-pyridyl)-1,3,5-triazine (abbreviation: 2Py3Tzn) as the second organic compound. For comparison, the tables also show calculation results of composite materials including silver (Ag) or indium (In) as the metal or metal oxide, Pyrrd-Phen as the first organic compound, and NBPhen in place of the second organic compound. Note that tPy2P and 2Py3Tzn are each the second organic compound having two or more heteroaromatic rings that are bonded or condensed to each other and include three or more heteroatoms in total. NBPhen is the organic compound having two or more heteroaromatic rings that are bonded or condensed to each other and include less than three heteroatoms in total.

TABLE 3

| | Stabilization | |
|---|---|---|
| | energy (eV) | SOMO (eV) |
| Pyrrd-Phen + tPy2P + In | −2.15 | −3.03 |
| Pyrrd-Phen + NBPhen + In | −1.25 | −3.02 |

TABLE 4

| | Stabilization | |
|---|---|---|
| | energy (eV) | SOMO (eV) |
| Pyrrd-Phen + 2Py3Tzn + Ag | −1.79 | −2.56 |
| Pyrrd-Phen + NBPhen + Ag | −1.26 | −2.50 |

As shown in the above tables, the composite materials of one embodiment of the present invention, each of which includes the metal belonging to Group 11 or Group 13, the first organic compound, and the second organic compound, are preferable because of having a high stabilization energy and having a stable structure. The SOMO level formed at this time is high to offer a high electron-injection property, which is preferable.

In a general fabrication process of a light-emitting device, an EL layer, particularly an electron-injection layer, of the light-emitting device is mostly formed by a vacuum evaporation method. Thus, it is preferable to use a material that can be easily deposited by vacuum evaporation, i.e., a material with a low melting point. The metal elements belonging to Group 11 and Group 13 have low melting points and thus, they can be suitably used for vacuum evaporation. The metal elements belonging to Group 11 and Group 13 are preferable because they are stable with respect to oxygen and water in the air. A vacuum evaporation method is preferably used, in which case a metal atom and an organic compound can be easily mixed.

Furthermore, Ag and In can be used also as a cathode material. Using the same material for an electron-injection layer and a cathode is preferable, in which case the fabrication of the light-emitting device can become easier. Moreover, the fabrication cost of the light-emitting device can be reduced.

The above indicates that owing to the interaction between the first organic compound having a π-electron deficient heteroaromatic ring, the metal or metal oxide, and the second organic compound having two or more heteroaromatic rings that are bonded or condensed to each other and include three or more heteroatoms in total, the combination of the first organic compound and the metal or metal oxide functions as an electron donor to the second organic compound. In one embodiment of the present invention, the electron-injection layer formed using this combined materials can have a high electron-injection property and resistance to oxygen and water in the air and water and a chemical solution used in a lithography process; thus, the light-emitting device can have a reduced driving voltage and high emission efficiency.

### <<Electron-Injection Layer>>

The electron-injection layer 115 is provided between the second electrode 102 as a cathode and the light-emitting layer 113 as illustrated in FIG. 1A, and includes the metal or metal oxide, the first organic compound having a π-electron deficient heteroaromatic ring, and the second organic compound having two or more heteroaromatic rings that are bonded or condensed to each other and include three or more heteroatoms in total.

### <Metal>

As the metal, a typical metal or a transition metal can be used.

As the typical metal, an alkali metal (Group 1 element) such as Li, Na, K, or Cs, an alkaline earth metal (Group 2 element) such as Mg, Ca, or Ba, a Group 12 element such as Zn, an earth metal (Group 13 element) such as Al or In, a Group 14 element such as Sn, or a compound of a Group 1, 2, 13, or 14 element can be used.

An alkali metal, an alkaline earth metal, or a compound thereof is preferably used as the metal, in which case the donor level formed by interaction with the first organic compound and the second organic compound can be a high energy level, electrons can be injected and transported smoothly from the electron-injection layer to the electron-transport layer, and a light-emitting device having a low driving voltage and high emission efficiency can be provided.

As the transition metal, any of Group 3 elements, including Y and lanthanoids such as Eu and Yb, Group 7 elements such as Mn, Group 8 elements such as Fe, Group 9 elements such as Co, Group 10 elements such as Ni and Pt, Group 11 elements such as Cu, Ag, and Au, and a compound of a Group 3, 7, 8, 9, 10, or 11 element can be used. The transition metal is preferable because it has low reactivity with components of the air such as water and oxygen.

Among the above-described examples, it is further preferable to use a metal belonging to an odd-numbered group (Group 1, Group 3, Group 5, Group 7, Group 9, Group 11, or Group 13). It is particularly preferable to use a metal having one electron (an unpaired electron) in the orbital of the outermost shell among transition metals belonging to the odd-numbered groups, in which case the metal is likely to form SOMO with the first organic compound.

A metal that has a low melting point and that can be deposited by a vacuum evaporation method is preferably used because a mixed layer of this metal and an organic compound is easy to form. Specifically, for example, the metals belonging to Group 11 and Group 13 have low melting points and thus, they can be suitably used for vacuum evaporation. The metals belonging to Group 11 and Group 13 are preferable because they are stable with respect to oxygen and water in the air.

### <First Organic Compound>

As the first organic compound, an organic compound having a π-electron deficient heteroaromatic ring can be used. In order that the first organic compound and the metal or metal oxide interact with each other to function as an electron donor (donating electrons) to the second organic compound, the π-electron deficient heteroaromatic ring preferably includes an unshared electron pair, and the unshared electron pair preferably has an electron-donating property. In other words, the first organic compound preferably includes a basic π-electron deficient heteroaromatic ring. Moreover, nitrogen has high electronegativity and thus easily interacts with a metal or metal oxide. In addition, since nitrogen can form a conjugated bond in an organic compound, nitrogen enables the organic compound to have a high carrier-transport property when used in the molecule, particularly in a heteroaromatic ring. Accordingly, the first organic compound preferably includes a heteroaromatic ring containing nitrogen. It is further preferable that the heteroaromatic ring be an even-numbered ring such as a six-membered ring or an eight-membered ring. Since the unshared electron pair of nitrogen does not contribute to the conjugation in this structure, nitrogen is likely to interact with the metal or metal oxide. To inject and transport electrons smoothly from the electron-injection layer to the electron-transport layer, the first organic compound preferably has an electron-transport property. Specifically, for example, the first organic compound preferably includes a pyridine ring.

It is preferable that the first organic compound include two or more π-electron deficient heteroaromatic rings each having an unshared electron pair, and the two or more π-electron deficient heteroaromatic rings be bonded or condensed to each other. Thus, the electron-injection layer is stabilized when the metal or metal oxide interacts with the first organic compound and the second organic compound each serving as a bidentate or multidentate ligand such as a bi- or higher dentate ligand; thus, the electron-injection layer that is less likely to deteriorate even through a photolithography process involving exposure to the air can be formed. Specifically, for example, the first organic compound preferably includes a heteroaromatic ring having two or more pyridine rings. In particular, an organic compound having a bipyridine skeleton is preferable because its nitrogen atoms are likely to coordinate with a metal and thus the organic compound easily interacts with the metal or metal oxide.

Furthermore, a phenanthroline ring is preferable because of its rigidity and high stability. Among organic compounds having a phenanthroline ring, an organic compound having a 1,10-phenanthroline ring, the two nitrogen atoms of which can be coordinated to a metal, is particularly preferably used to facilitate interaction with the metal or metal oxide.

The first organic compound may have a structure in which a plurality of phenanthroline rings are bonded to each other via a single bond or a divalent group. Specific examples of the divalent group include an alkylene group and an arylene group.

An alkylene group refers to a divalent group obtained by eliminating two hydrogen atoms from an alkane. Specific examples of an alkylene group include a divalent group having a structure obtained by eliminating one hydrogen atom from any of the below specific examples of an alkyl group.

An arylene group refers to a divalent group obtained by eliminating two hydrogen atoms from an aromatic hydrocarbon. Specific examples of an arylene group include a divalent group having a structure obtained by eliminating one hydrogen atom from any of the below specific examples of an aryl group. Note that the arylene group may further have a substituent, and specific examples of the substituent include an alkyl group, an alkoxy group, and a phenyl group.

The first organic compound preferably has an electron-donating group. Accordingly, the first organic compound can have a high HOMO level and a high LUMO level; thus, the difference between the LUMO level of the first organic compound and the LUMO level of the second organic compound can be increased, in which case the electron-injection layer can be stabilized by interaction between the metal or metal oxide, the first organic compound, and the second organic compound and is less likely to deteriorate even through a photolithography process involving exposure to the air.

As the first organic compound, an organic compound having a phenanthroline ring with an electron-donating group is further preferably used. Specifically, introducing an electron-donating group to a 1,10-phenanthroline ring can increase the electron density of the phenanthroline ring and the efficiency of the interaction with the metal or metal oxide. Furthermore, an electron-donating group is preferably bonded to at least one of the 4- and 7-positions of the 1,10-phenanthroline ring. Introducing electron-donating groups to the 4- and 7-positions can increase the electron density of the nitrogen atoms at the 1- and 10-positions, which are the para-positions with respect to the 4- and 7-positions. In addition, steric congestion around the nitrogen atoms at the 1- and 10-positions can be inhibited, and the electron density around the nitrogen atoms can be increased. This structure facilitates the interaction with the metal or metal oxide and is thus preferable.

Specific examples of the electron-donating group include an alkyl group, an alkoxy group, an aryloxy group, an alkylamino group, an arylamino group, and a heterocyclic amino group. Note that the electron-donating group that is preferably introduced to the π-electron deficient heteroaromatic ring such as a phenanthroline ring is not limited to the above examples. As long as a group that is introduced to a π-electron deficient heteroaromatic ring such as a phenanthroline ring can increase the electron density of the π-electron deficient heteroaromatic ring, the group can be used as the electron-donating group. The electron-donating group may be introduced to a π-electron deficient heteroaromatic ring such as a phenanthroline ring via an arylene group such as a phenylene group, and the arylene group is preferably a p-phenylene group.

An alkyl group refers to a monovalent group obtained by eliminating one hydrogen atom from an alkane (CₙH₂ₙ₊₂). Specific examples of an alkyl group include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, and a 2,3-dimethylbutyl group.

An alkoxy group refers to a monovalent group with a structure in which an alkyl group is bonded to an oxygen atom. Specific examples of an alkoxyl group include a methoxy group, an ethoxy group, an n-propoxy group, an isopropoxy group, an n-butoxy group, a sec-butoxy group, an isobutoxy group, a tert-butoxy group, an n-pentyloxy group, an isopentyloxy group, a sec-pentyloxy group, a tert-pentyloxy group, a neopentyloxy group, an n-hexyloxy group, an isohexyloxy group, a sec-hexyloxy group, a tert-hexyloxy group, and a neohexyloxy group.

An aryloxy group refers to a monovalent group with a structure in which an aryl group is bonded to an oxygen atom. An aryl group refers to a monovalent group obtained by eliminating one hydrogen atom from one of carbon atoms forming the ring(s) of a monocyclic or polycyclic aromatic compound. Specific examples of an aryloxy group include a phenoxy group, an o-tolyloxy group, a m-tolyloxy group, a p-tolyloxy group, a mesityloxy group, an o-biphenyloxy group, a m-biphenyloxy group, a p-biphenyoxyl group, a 1-naphthyloxy group, a 2-naphthyloxy group, and a 2-fluorenyloxy group. Note that the aryloxy group may further have a substituent, and specific examples of the substituent include an alkyl group, an alkoxy group, and a phenyl group.

An alkylamino group refers to a monovalent group obtained by eliminating one hydrogen atom from the nitrogen atom of a primary amine in which one alkyl group is bonded to the nitrogen atom, or from the nitrogen atom of a secondary amine in which two alkyl groups are bonded to the nitrogen atom. Specific examples of an alkylamino group include a dimethylamino group and a diethylamino group.

An arylamino group refers to a monovalent group obtained by eliminating one hydrogen atom from the nitrogen atom of a primary amine in which one aryl group is bonded to the nitrogen atom, or from the nitrogen atom of a secondary amine in which two aryl groups are bonded to the nitrogen atom. Specific examples of an arylamino group include a diphenylamino group, a bis(α-naphthyl)amino group, and a bis(m-tolyl)amino group. Note that the arylamino group may further have a substituent, and specific examples of the substituent include an alkyl group, an alkoxy group, and a phenyl group.

Note that an amino group having a structure in which both an alkyl group and an aryl group are bonded to the nitrogen atom can be regarded as an alkylamino group or an arylamino group. Specific examples of such an amino group include an N-methyl-N-phenylamino group.

A heterocyclic amino group refers to a monovalent group obtained by eliminating one hydrogen atom from one of the nitrogen atoms forming a ring of a heterocyclic amine. Here, the heterocyclic amine refers to a monocyclic or polycyclic heterocyclic compound in which at least one of the atoms forming the ring(s) is a nitrogen atom bonded to a hydrogen atom. Specific examples of a heterocyclic amino group include groups represented by Structural Formulae (R-1) to (R-26) below. Note that the heterocyclic amino group may further have a substituent, and specific examples of the substituent include an alkyl group, an alkoxy group, and a phenyl group.

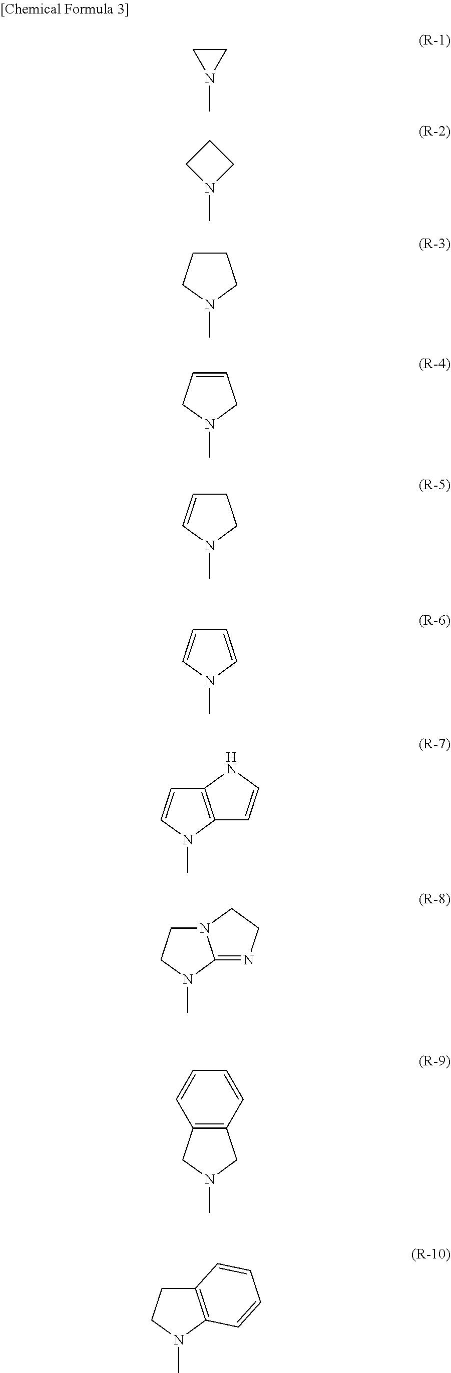

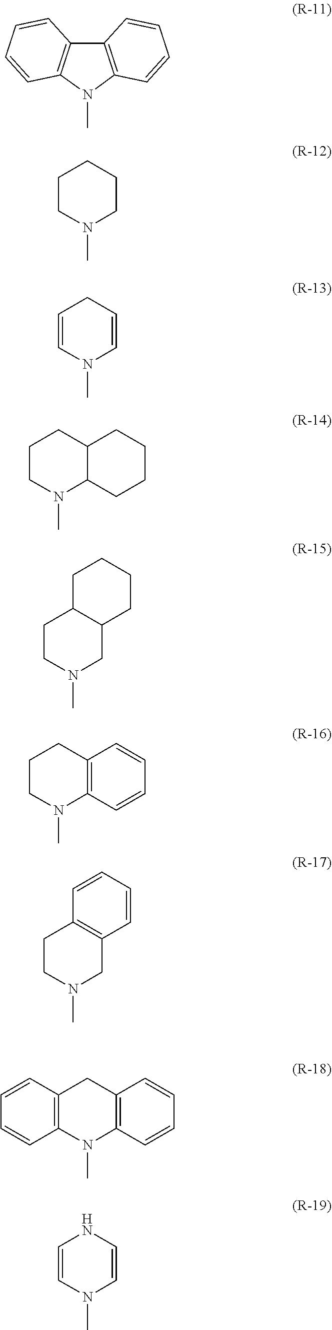

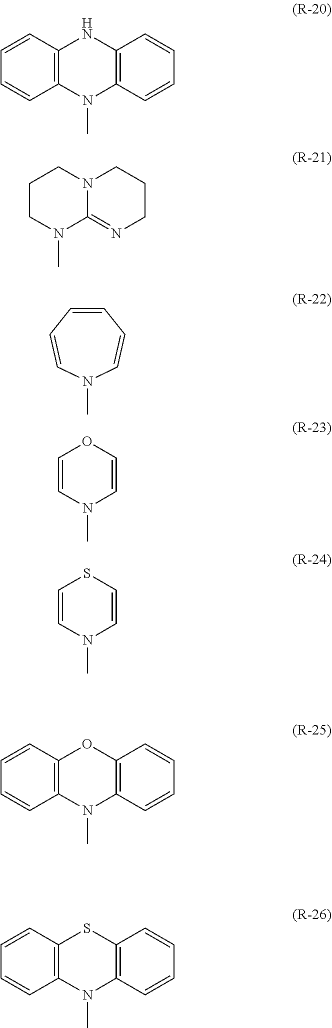

In some cases, the property of donating electrons to the phenanthroline ring is lower in a heterocyclic amino group which has aromaticity and in which an unshared electron pair of the nitrogen atom contributes to the aromaticity than in a heterocyclic amino group which has aromaticity and in which an unshared electron pair of the nitrogen atom does not contribute to the aromaticity. Therefore, among the above heterocyclic amino groups, a heterocyclic amino group which has aromaticity and in which an unshared electron pair of the nitrogen atom does not contribute to the aromaticity is further preferable. Specifically, the group represented by Structural Formula (R-1), (R-2), (R-3), (R-4), (R-5), (R-8), (R-9), (R-10), (R-12), (R-14), (R-15), (R-16), (R-17), or (R-21) is further preferably used as the electron-donating group. Among these groups, the group represented by Structural Formula (R-3), (R-4), (R-8), or (R-21) is preferably used because the group has a high electron-donating property and can further increase the electron density of the phenanthroline ring.

Specific examples of the electron-donating group include groups represented by Structural Formulae (R-27) and (R-28) below.

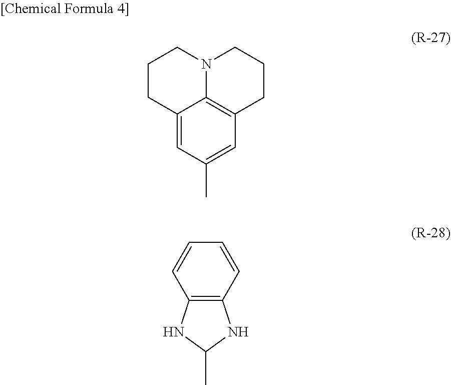

Note that an organic compound with a π-electron deficient heteroaromatic ring that can be used as the first organic compound may have both the above-described electron-donating group and another substituent. Specific examples of the substituent that can be introduced to the π-electron deficient heteroaromatic ring together with the above electron-donating group include an aryl group. Specific examples of the aryl group include a phenyl group, an o-tolyl group, a m-tolyl group, a p-tolyl group, a mesityl group, an o-biphenyl group, a m-biphenyl group, a p-biphenyl group, a 1-naphthyl group, a 2-naphthyl group, and a 2-fluorenyl group. Note that the aryl group may further have a substituent, and specific examples of the substituent include an alkyl group, an alkoxy group, and a phenyl group.

Specific examples of an organic compound with a π-electron deficient heteroaromatic ring that can be used as the first organic compound are represented by Structural Formulae (100) to (110). Note that the organic compound that can be used as the first organic compound is not limited to those examples.

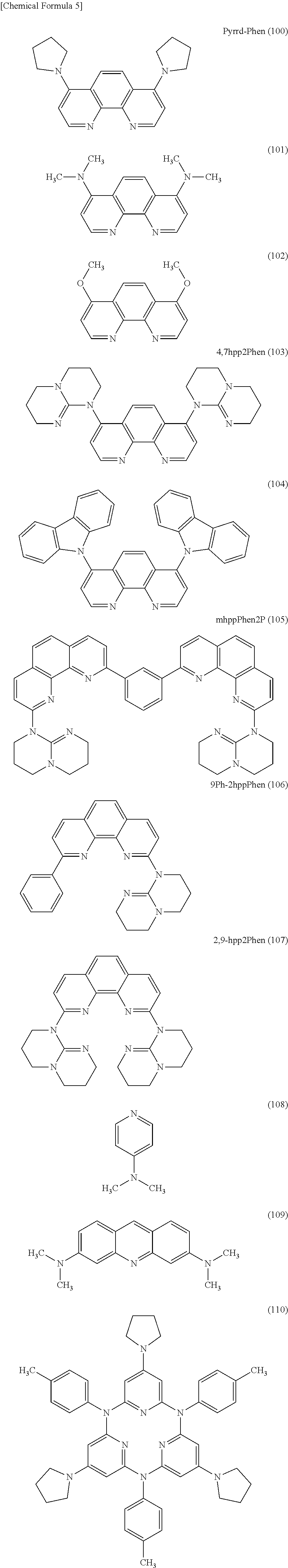

The negative minimum value of the electrostatic potential (ESP) of the first organic compound is preferably small (i.e., the negative minimum value preferably has a large absolute value), in which case the stability of the interaction with the metal or metal oxide is high. In an organic compound including a π-electron deficient heteroaromatic ring, the electrostatic potential around nitrogen atoms of the π-electron deficient heteroaromatic ring, which is likely to be negative, can be further lowered (i.e., the absolute value of the negative value can be increased) by introduction of an electron-donating group to the π-electron deficient heteroaromatic ring. Note that an electrostatic potential is the energy of interaction between positive point charge with unit quantity of electricity and electron distribution of a molecule. An electrostatic potential value also depends on the threshold value of electron density distribution. To increase the efficiency of the interaction with the metal or metal oxide, the minimum value of the electrostatic potential of the first organic compound is preferably smaller (has a larger absolute value) than the minimum value of the electrostatic potential of a phenanthroline ring having no substituent. Specifically, when the threshold value of electron density distribution in atomic units is 0.0004 e/a₀³, the minimum value of the electrostatic potential is preferably smaller than or equal to −0.085 Eₕ (Eₕ is the Hartree energy (1 Eₕ=27.211 eV)), further preferably smaller than or equal to −0.090 Eₕ. When the threshold value of electron density distribution is 0.003 e/a₀, the minimum value of the electrostatic potential is preferably smaller than or equal to −0.12 Eₕ, further preferably smaller than or equal to −0.13 Eₕ.

### <<Characteristic Estimation of First Organic Compound by Quantum Chemical Calculation>>

The minimum values of the electrostatic potentials (ESP) of the above organic compounds that can be used as the first organic compound are estimated by quantum chemical calculation.

As the quantum chemistry computational program, Gaussian 09 is used. The calculation is performed using HPE SGI 8600. The most stable structure of the first organic compound in a ground state is calculated by DFT. As a basis function, 6-311G(d,p) is used, and as a functional, B3LYP is used.

The following table shows the analysis results of the electrostatic potentials of the first organic compound in a ground state. Note that an electrostatic potential is the energy of interaction between positive point charge with unit quantity of electricity and electron distribution of a molecule. An electrostatic potential value also depends on the threshold value of electron density distribution. The following table shows electrostatic potentials in electron density distribution at the time when the threshold value of electron density distribution in atomic units is 0.0004 e/a₀³ or 0.003 e/a₀³.

TABLE 5

| | Minimum value of ESP (threshold value of | Minimum value of ESP (threshold value of |
|---|---|---|
| | electron density distribution = 0.0004) | electron density distribution = 0.003) |
| Pyrrd-Phen (100) | −0.091 | −0.12 |
| DMeAPhen (101) | −0.089 | −0.12 |
| p-MeO-Phen (102) | −0.089 | −0.12 |
| 4,7hpp2Phen (103) | −0.096 | −0.13 |
| CzPhen (104) | −0.072 | −0.10 |
| mhppPhen2P (105) | −0.057 | −0.096 |
| 9Ph2hppPhen (106) | −0.057 | −0.096 |
| 2,9hpp2Phen (107) | −0.061 | −0.097 |
| BPhen | −0.083 | −0.11 |
| mPPhen2P | −0.057 | −0.094 |
| NBPhen | −0.053 | −0.093 |
| Phen | −0.081 | −0.11 |

Note that the organic compounds represented by Structural Formulae (100) to (107) shown as the organic compounds that can be used as the first organic compound, BPhen, mPPhen2P, NBPhen, and Phen in Table 5 are shown below.

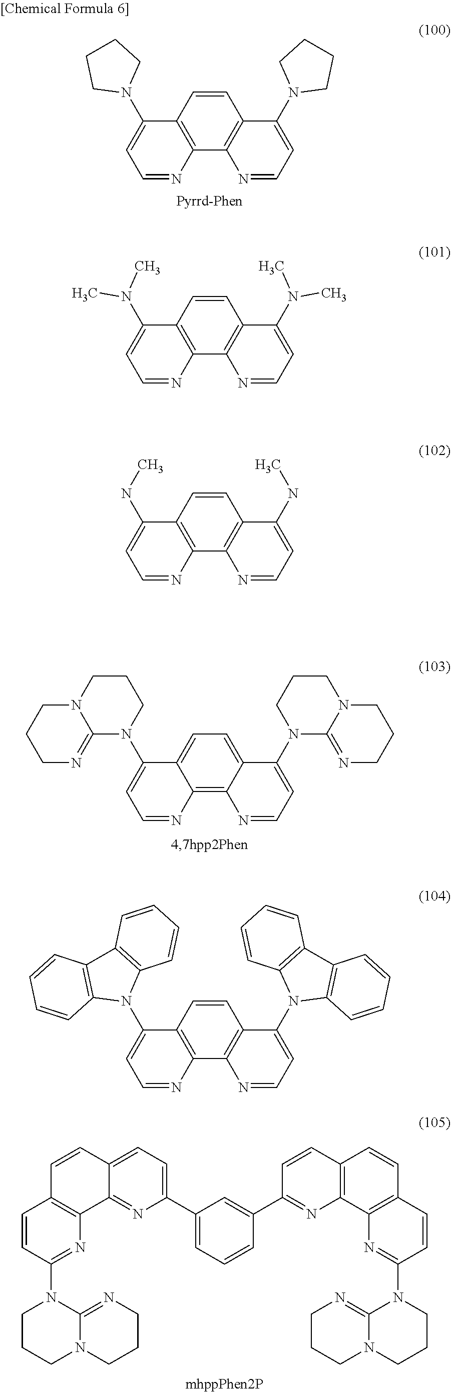

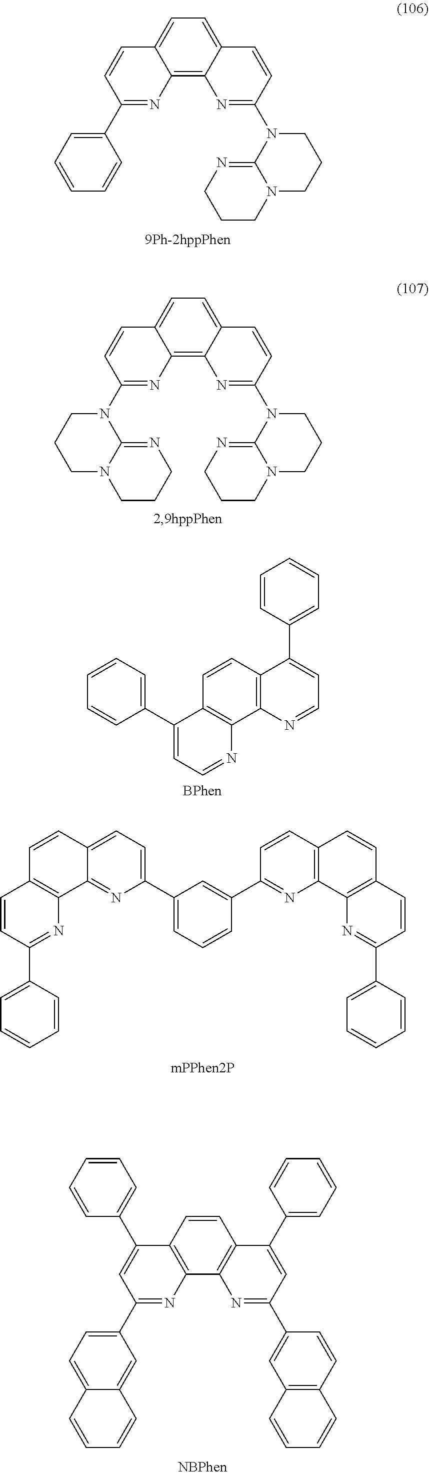 [SMILES: c1ccc(-c2ccc3ccc4ccc(N5CCCN6CCCN=C65)nc4c3n2)cc1 ; c1cc2ccc3ccc(N4CCCN5CCCN=C54)nc3c2nc1N1CCCN2CCCN=C21 ; c1ccc(-c2ccnc3c2ccc2c(-c4ccccc4)ccnc23)cc1 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc4ccccc4c3)nc3c2ccc2c(-c4ccccc4)cc(-c4ccc5ccccc5c4)nc23)cc1]

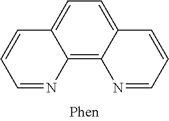 [SMILES: c1cnc2c(c1)ccc1cccnc12]

The above table indicates that the minimum values of ESP of the organic compounds represented by Structural Formulae (100) to (103) are each smaller than or equal to −0.085 Eₕ when the threshold value of electron density distribution in atomic units is 0.0004 e/a₀³ and that using any of these organic compounds as the first organic compound is the most preferable. On the other hand, the minimum values of ESP of the organic compounds represented by Structural Formulae (104) to (107) are each larger than −0.085 Eₕ.

It is shown that the organic compounds represented by Structural Formulae (100) to (103) have the most favorable values because of having an electron-donating group at each of the 4- and 7-positions of the 1,10-phenanthroline ring.

The organic compound represented by Structural Formula (104) has N-carbazolyl groups as electron-donating groups at the 4- and 7-positions of the 1,10-phenanthroline ring. In the N-carbazolyl group, in which an unshared electron pair of the nitrogen atom contributes to aromaticity, the property of donating electrons to the phenanthroline ring is lower than that in a group in which an unshared electron pair of a nitrogen atom does not contribute to aromaticity, inhibiting a reduction in the minimum value of ESP of the organic compound represented by Structural Formula (104).

The organic compounds represented by Structural Formulae (105) to (107) each have electron-donating groups at the 2- and 9-positions of the 1,10-phenanthroline ring. The electron-donating groups introduced to the 2- and 9-positions have a low property of donating electrons to the nitrogen atoms at the 1- and 10-positions of the phenanthroline ring. It is thus preferable that electron-donating groups be at the 4- and 7-positions of a 1,10-phenanthroline ring.

Note that the LUMO level of the second organic compound is further preferably lower than that of the first organic compound. In that case, electrons can be easily donated from the donor level formed by the first organic compound and the metal or metal oxide to the second organic compound. The LUMO level of the second organic compound is preferably lower than that of the first organic compound so that the second organic compound can have an electron-transport property.

For example, the LUMO level of the first organic compound is preferably higher than or equal to −3.0 eV and lower than or equal to −2.0 eV, further preferably higher than or equal to −2.7 eV and lower than or equal to −2.0 eV. The LUMO level of the second organic compound is preferably higher than or equal to −3.0 eV and lower than or equal to −2.0 eV, further preferably higher than or equal to −3.0 eV and lower than or equal to −2.5 eV. In the above case, electrons can be easily donated from the donor level formed by the first organic compound and the metal or metal oxide to the second organic compound. This facilitates electron transport in the second organic compound.

Note that the HOMO level and the LUMO level of an organic compound are generally estimated by cyclic voltammetry (CV), photoelectron spectroscopy, optical absorption spectroscopy, inverse photoemission spectroscopy, or the like. When values of different compounds are compared with each other, it is preferable that values estimated by the same measurement be used.

The first organic compound is preferably strongly basic, in which case the first organic compound interacts with holes to significantly reduce the hole-transport property in the electron-injection layer and prevent hole transport from the electron-injection layer to the electron-transport layer, enabling high efficiency of the light-emitting device. Specifically, the acid dissociation constant pKₐ of the first organic compound is preferably higher than or equal to 8, further preferably higher than or equal to 10, still further preferably higher than or equal to 12.

In the case where the acid dissociation constant pKₐ of an organic compound is unknown, the acid dissociation constants pKₐ of skeletons in the organic compound are calculated and the largest acid dissociation constant pKₐ can be regarded as the acid dissociation constant pKₐ of the organic compound.

The acid dissociation constant may be obtained by calculation. For example, the acid dissociation constant pKₐ can be obtained by the following calculation method.

The initial structure of a molecule serving as a calculation model is the most stable structure (the singlet ground state) obtained by first-principles calculation.

For the first-principles calculation, Jaguar, which is the quantum chemical computational software (Schradinger, Inc.) is used, and the most stable structure in the singlet ground state is calculated by DFT. As abasis function, 6-31G** is used, and as a functional, B3LYP-D3 is used. The structure subjected to quantum chemical calculation is sampled by conformational analysis in mixed torsional/low-mode sampling with Maestro GUI (Schrödinger, Inc.)

In the calculation of pKₐ, one or more atoms in each molecule are designated as basic sites, MacroModel is used to search for the stable structure of the protonated molecule in water, conformational search is performed with OPLS2005 force field, and a conformational isomer having the lowest energy is used. Jaguar's pKₐ calculation module is used. After structure optimization is performed by B3LYP/6-31G*, single point calculation is performed by cc-pVTZ(+) and the pKₐ value is calculated using empirical correction for functional group(s). In the case where one or more atoms are designated as basic sites in a molecule, the largest of obtained values is used as a pKₐ value. The obtained pKₐ values are shown below.

The acid dissociation constant pKₐ of 2,9hpp2Phen is 13.35, pKₐ of 4,7hpp2Phen is 13.42, pKₐ of Pyrrd-Phen is 11.23, pKₐ of mPPhen2P is 5.16, pKₐ of NBPhen is 5.59, and pKₐ of BPhen is 5.62.

### <Second Organic Compound>

The electron-injection layer includes the second organic compound having two or more heteroaromatic rings that are bonded or condensed to each other and include three or more heteroatoms in total, in addition to the metal or metal oxide and the first organic compound. The second organic compound has a function of interacting with the metal or metal oxide by two or more of the three or more heteroatoms as a multidentate ligand.

The second organic compound can improve heat resistance, electron-transport properties, and the like. In the case where the π-electron deficient heteroaromatic ring of the first organic compound is referred to as a first π-electron deficient heteroaromatic ring and the π-electron deficient heteroaromatic ring of the second organic compound is referred to as a second π-electron deficient heteroaromatic ring in one embodiment of the present invention, the first π-electron deficient heteroaromatic ring and the second π-electron deficient heteroaromatic ring preferably include different rings.

As the second π-electron deficient heteroaromatic ring, a heteroaromatic ring having an azole skeleton (an imidazole ring, a pyrazole ring, an oxazole ring, a thiazole ring, a triazole ring, an oxadiazole ring, or a thiadiazole ring), a heteroaromatic ring having a pyridine skeleton, a heteroaromatic ring having a diazine skeleton, a heteroaromatic ring having a triazine skeleton, or the like is preferable, and a diazine ring (a pyrazine ring, a pyrimidine ring, or a pyridazine ring) and a triazine ring are particularly preferable because they are electrochemically stable and have a high electron-transport property.

For example, an organic compound represented by General Formula (G1-1) below can be used as the organic compound used for the second organic compound.

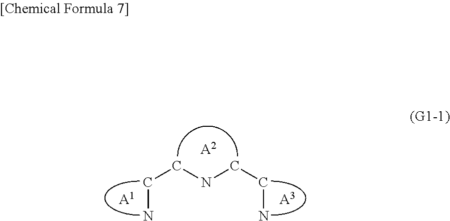

In General Formula (G1-1) above, A¹, A², and A³ each independently represent a substituted or unsubstituted heteroaromatic ring having 1 to 30 carbon atoms, and A¹, A², and A³ may form a condensed ring with each other.

The organic compound represented by General Formula (G1-1) includes a conjugated double bond in which N in the heteroaromatic ring are arranged in the order of N—C—C—N, and have a function of interacting with a metal or metal oxide as a tri- or higher dentate ligand. An organic compound having such a structure is likely to interact with a metal or metal oxide and thus can be suitably used for an electron-injection layer.

In General Formula (G1-1), examples of the substituted or unsubstituted heteroaromatic rings having 1 to 30 carbon atoms, which are represented by A¹, A², and A³, include a heteroaromatic ring having a pyridine skeleton (a pyridine ring, a quinoline ring, an isoquinoline ring, a naphthyridine ring, a bipyridine ring, a phenanthridine ring, a phenanthroline ring, an anthyridine ring, or an azafluoranthene ring), a heteroaromatic ring having a diazine skeleton (a pyrazine ring, a pyrimidine ring, a pyridazine ring, a quinoxaline ring, a benzoquinoxaline ring, a dibenzoquinoxaline ring, a quinazoline ring, a benzoquinazoline ring, a phthalazine ring, a cinnoline ring, a pteridine ring, or a phenazine ring), a heteroaromatic ring having a triazine skeleton, and a heteroaromatic ring having an azole skeleton (an imidazole ring, a benzimidazole ring, a pyrazole ring, an oxazole ring, a thiazole ring, a triazole ring, an oxadiazole ring, or a thiadiazole ring). Note that the substituted or unsubstituted heteroaromatic rings having 1 to 30 carbon atoms represented by A¹, A², and A³ are not limited to these. A¹, A², and A³ may form a condensed ring with each other. For example, A¹ and A² may be bonded to each other to form a phenanthroline ring.

As the second organic compound, an organic compound represented by General Formula (G2-1) can be used.

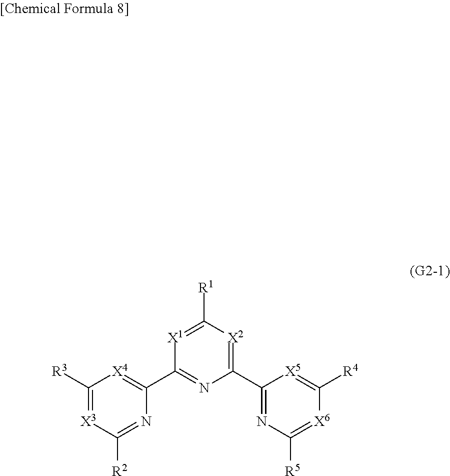

In General Formula (G2-1), X¹ to X⁶ each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁴ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms. Alternatively, in General Formula (G2-1), X¹ to X⁶ may be directly bonded to each other or bonded to each other via carbon to form a condensed ring.

As in the organic compound represented by General Formula (G2-1), it is further preferable that the organic compound having a function of interacting with the metal or metal oxide as a tri- or higher dentate ligand include at least one of a heteroaromatic ring having a pyridine skeleton, a heteroaromatic ring having a diazine skeleton, and a heteroaromatic ring having a triazine skeleton. A light-emitting device including any of these rings can have high reliability because these rings have high electrochemical stability. Moreover, the driving voltage of the light-emitting device can be reduced because these rings have high electron-transport properties.

As the second organic compound, an organic compound represented by General Formula (G3-1) can be used.

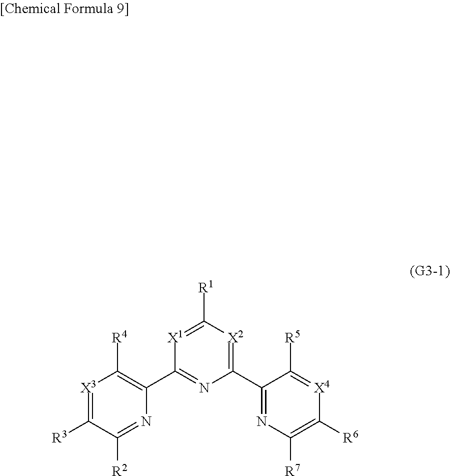

In General Formula (G3-1), X¹ to X⁴ each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁶ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

As the second organic compound, an organic compound represented by General Formula (G4-1) below can also be used.

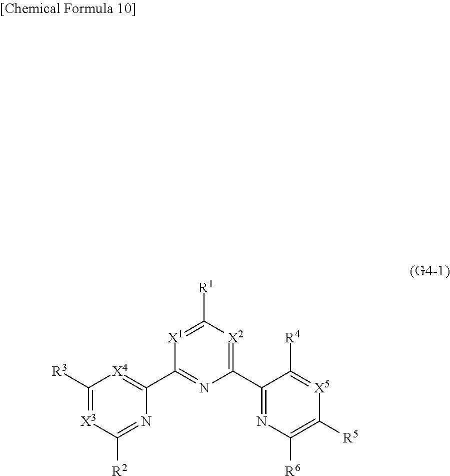

In General Formula (G4-1), X¹ to X⁵ each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁵ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

An organic compound having a pyridine skeleton has a high LUMO level, which is preferable. Thus, when X¹ and X² in each of General Formulae (G2-1) to (G4-1) represent carbon, the organic compound represented by each of General Formulae (G2-1) to (G4-1), which has a pyridine skeleton, can form a composite material with a high SOMO level when interacting with a metal or metal oxide. That is, when such an organic compound having a pyridine ring and a function of interacting with a metal or metal oxide as a tri- or higher dentate ligand interacts with a metal or metal oxide, an electron-injection layer having a high electron-injection property can be formed.

An organic compound having a diazine skeleton or a triazine skeleton is preferable because it is electrochemically stable and has a high electron-transport property. Thus, when at least one of X¹ and X² in each of General Formulae (G2-1) to (G4-1) represents nitrogen, the organic compound represented by each of General Formulae (G2-1) to (G4-1), which has a diazine skeleton or a triazine skeleton, can form a stable composite material with a high electron-transport property when interacting with a metal or metal oxide. That is, when such an organic compound having a diazine ring or a triazine ring and a function of interacting with a metal or metal oxide as a tri- or higher dentate ligand interacts with a metal or metal oxide, an electron-injection layer having high reliability can be formed.

As the second organic compound, an organic compound represented by General Formula (G1-2) below can also be used, for example.

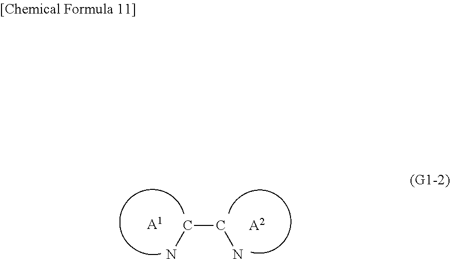

In General Formula (G1-2) above, Aland A² independently represent a substituted or unsubstituted heteroaromatic ring having 1 to 30 carbon atoms, Aland A² may form a condensed ring with each other, and A¹ contains two or more nitrogen atoms.

The organic compound represented by General Formula (G1-2) includes a conjugated double bond in which N in the heteroaromatic ring are arranged in the order of N—C—C—N and has a function of interacting with a metal or metal oxide as a bi- or higher dentate ligand. An organic compound having such a structure is likely to interact with a metal or metal oxide and thus can be suitably used for an electron-injection layer.

In General Formula (G1-2), examples of the substituted or unsubstituted heteroaromatic ring having 1 to 30 carbon atoms, which is represented by A¹, include a heteroaromatic ring having a diazine skeleton (a pyrazine ring, a pyrimidine ring, a pyridazine ring, a quinoxaline ring, a benzoquinoxaline ring, a dibenzoquinoxaline ring, a quinazoline ring, a benzoquinazoline ring, a phthalazine ring, a cinnoline ring, a pteridine ring, or a phenazine ring), a heteroaromatic ring having a triazine skeleton, and a heteroaromatic ring having an azole skeleton (an imidazole ring, a benzimidazole ring, a pyrazole ring, an oxazole ring, a thiazole ring, a triazole ring, an oxadiazole ring, or a thiadiazole ring). Examples of the substituted or unsubstituted heteroaromatic ring having 1 to 30 carbon atoms, which is represented by A², include a heteroaromatic ring having a pyridine skeleton (a pyridine ring, a quinoline ring, an isoquinoline ring, a naphthridine ring, a bipyridine ring, a phenanthridine ring, a phenanthroline ring, an anthyridine ring, or an azafluoranthene ring), a heteroaromatic ring having a diazine skeleton (a pyrazine ring, a pyrimidine ring, a pyridazine ring, a quinoxaline ring, a benzoquinoxaline ring, a dibenzoquinoxaline ring, a quinazoline ring, a benzoquinazoline ring, a phthalazine ring, a cinnoline ring, a pteridine ring, or a phenazine ring), a heteroaromatic ring having a triazine skeleton, and a heteroaromatic ring having an azole skeleton (an imidazole ring, a benzimidazole ring, a pyrazole ring, an oxazole ring, a thiazole ring, a triazole ring, an oxadiazole ring, or a thiadiazole ring). Note that the substituted or unsubstituted heteroaromatic rings having 1 to 30 carbon atoms represented by A¹ and A² are not limited to these. A¹ and A² may form a condensed ring with each other. For example, A¹ and A² may be bonded to each other to form a pyrazinoquinoxaline ring.

As the second organic compound, an organic compound represented by General Formula (G2-2) below can also be used.

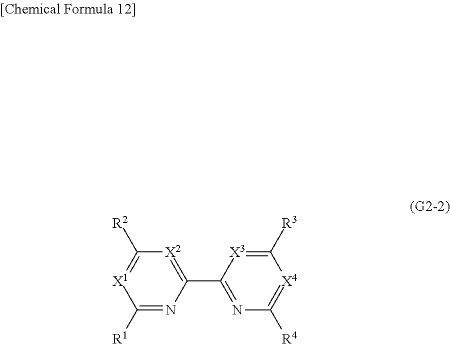

In General Formula (G2-2), at least one of X¹ to X⁴ represents nitrogen (N); the others each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁴ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms. Alternatively, in General Formula (G2-2), X¹ to X⁴ may be directly bonded to each other or bonded via carbon to form a condensed ring.

As in the organic compound represented by General Formula (G2-2), it is further preferable that the organic compound having a function of interacting with the metal or metal oxide as a bi- or higher dentate ligand include a heteroaromatic ring having a diazine skeleton or a heteroaromatic ring having a triazine skeleton. A light-emitting device including any of these rings can have high reliability because these rings have high electrochemical stability. Moreover, the driving voltage of the light-emitting device can be reduced because these rings have high electron-transport properties.

As the second organic compound, an organic compound represented by General Formula (G3-2) below can also be used.

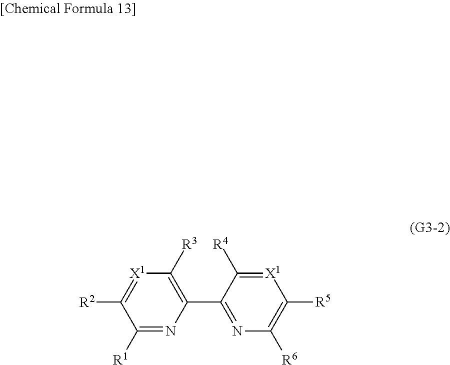

In General Formula (G3-2), one of X¹ and X² represents nitrogen (N); the other represents carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁶ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

As the second organic compound, an organic compound represented by General Formula (G4-2) below can also be used.

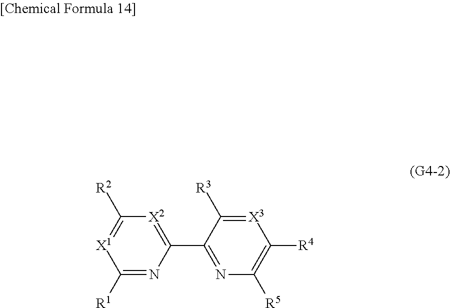

In General Formula (G4-2), at least one of X¹ to X³ represents nitrogen (N); the others each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁵ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

An organic compound having a pyridine skeleton is preferable because it has a high LUMO level. Thus, when X¹ and X² represented in General Formulae (G2-2) and (G4-2) and X¹ represented in General Formula (G3-2) represent carbon, each of the organic compounds represented by General Formulae (G2-2), (G3-2), and (G4-2), which has a pyridine skeleton, can form a composite material having a high SOMO level when interacting with a metal or metal oxide. That is, such an organic compound having a pyridine ring and a function of interacting with a metal or metal oxide as a bi- or higher dentate ligand interacts with a metal or metal oxide, whereby an electron-injection layer having a high electron-injection property can be formed.

An organic compound having a diazine skeleton or a triazine skeleton is preferable because it is electrochemically stable and has a high electron-transport property. Thus, when at least one of X¹ and X² represented in General Formulae (G2-2) and (G4-2) and X¹ represented in General Formula (G3-2) represent nitrogen, each of the organic compounds represented by General Formulae (G2-2), (G3-2), and (G4-2), which has a diazine skeleton or a triazine skeleton, can form a stable composite material with a high electron-transport property when interacting with a metal or metal oxide. That is, such an organic compound having a diazine ring or a triazine ring and a function of interacting with a metal or metal oxide as a bi- or higher dentate ligand interacts with a metal or metal oxide, whereby a highly reliable electron-injection layer can be formed.

Specific examples of the organic compounds used for the second organic compound and the organic compounds represented by General Formulae (G1-1) to (G4-2) above are shown below.

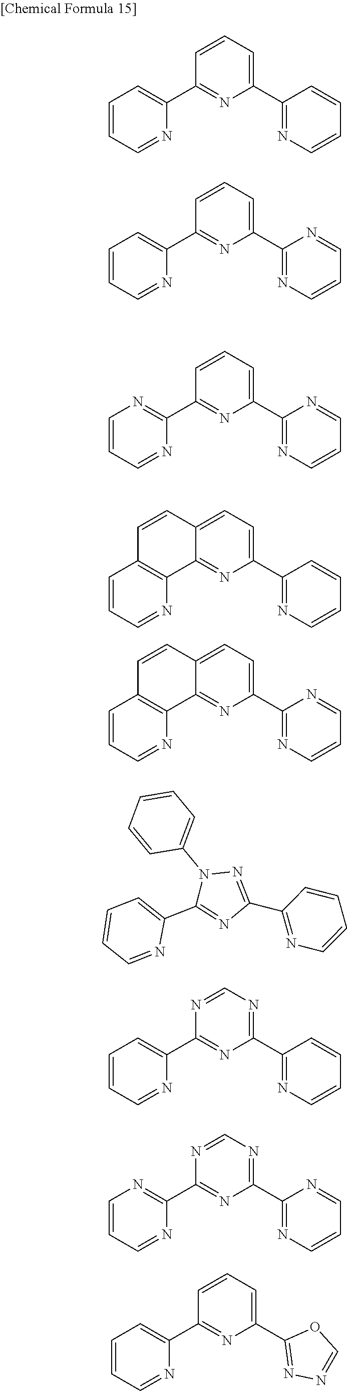

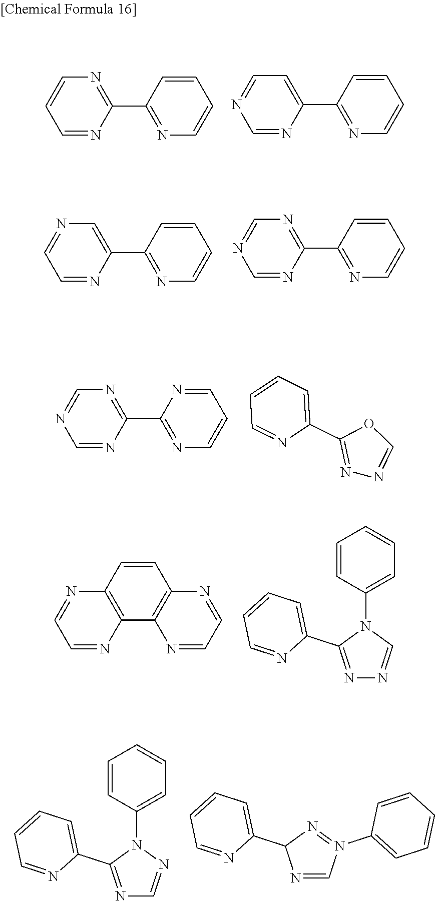

Examples of substituents that can be used in General Formulae (G1-1) to (G4-2) above include an alkyl group having 1 to 10 carbon atoms, a cycloalkyl group having 3 to 10 carbon atoms, an aryl group having 6 to 30 carbon atoms, an arylene group having 6 to 30 carbon atoms, and a heteroaryl group having 1 to 30 carbon atoms. Note that some or all of hydrogen atoms may be deuterium atoms. The groups that can be used in the above general formulae are not limited to the following specific examples.

Specific examples of the alkyl group having 1 to 10 carbon atoms include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, a 2,3-dimethylbutyl group, and a 1-ethylhexyl group.

Specific examples of a cycloalkyl group having 3 to 10 carbon atoms include a cyclopropyl group, a cyclobutyl group, a methylcyclobutyl group, a cyclopentyl group, a methylcyclopentyl group, an isopropylcyclopentyl group, a tert-butylcyclopropyl group, a cyclohexyl group, a methylcyclohexyl group, an isopropylcyclohexyl group, a tert-butylcyclohexyl group, a cycloheptyl group, a methylcycloheptyl group, an isopropylcycloheptyl group, a cyclooctyl group, a methylcyclooctyl group, an isopropylcyclohexyl group, a cyclononyl group, a methylcyclononyl group, a cyclodecyl group, and an adamantyl group.

Specific examples of the aryl group having 6 to 30 carbon atoms include a phenyl group, an o-tolyl group, an m-tolyl group, a p-tolyl group, a mesityl group, an o-biphenyl group, an m-biphenyl group, a p-biphenyl group, a 1-naphthyl group, a 2-naphthyl group, a fluorenyl group, a 9,9-dimethylfluorenyl group, a spirobifluorenyl group, a phenanthrenyl group, an anthracenyl group, and a fluoranthenyl group. In the case where the aryl group having 6 to 30 carbon atoms includes a substituent, examples of the substituent include an alkyl group having 1 to 10 carbon atoms, a cycloalkyl group having 3 to 10 carbon atoms, and a phenyl group.

Specific examples of the arylene group having 6 to 30 carbon atoms include a phenylene group, a biphenyl-diyl group, a naphthalene-diyl group, a fluorene-diyl group, an acenaphthene-diyl group, an anthracene-diyl group, a phenanthrene-diyl group, a terphenyl-diyl group, a triphenylene-diyl group, a tetracene-diyl group, a benzanthracene-diyl group, a pyrene-diyl group, and a spirobi[9H-fluorene]-diyl group. In the case where the arylene group having 6 to 30 carbon atoms includes a substituent, examples of the substituent include an alkyl group having 1 to 10 carbon atoms, a cycloalkyl group having 3 to 10 carbon atoms, and a phenyl group.

The heteroaryl group having 1 to 30 carbon atoms refers to a monovalent group obtained by eliminating one hydrogen atom from one of carbon atoms forming the ring(s) of a monocyclic or polycyclic heteroaromatic compound having 1 to 30 carbon atoms. Specific examples of the heteroaryl group having 1 to 30 carbon atoms include a 1,3,5-triazin-2-yl group, a 1,2,4-triazin-3-yl group, a pyrimidin-4-yl group, a pyrazin-2-yl group, a 2-pyridyl group, a 3-pyridyl group, a 4-pyridyl group, a carbazolyl group, a dibenzofuranyl group, a dibenzothiophenyl group, a benzonaphthofuranyl group, a benzonaphthothiophenyl group, an indolocarbazolyl group, a benzofurocarbazolyl group, a benzothienocarbazolyl group, an indenocarbazolyl group, and a dibenzocarbazolyl group. In the case where the heteroaryl group has a substituent, examples of the substituent include an alkyl group having 1 to 10 carbon atoms, a cycloalkyl group having 3 to 10 carbon atoms, and a phenyl group.

Specific examples of the organic compounds used for the second organic compound and the organic compounds represented by General Formulae (G1-1) to (G4-2) above are shown below.

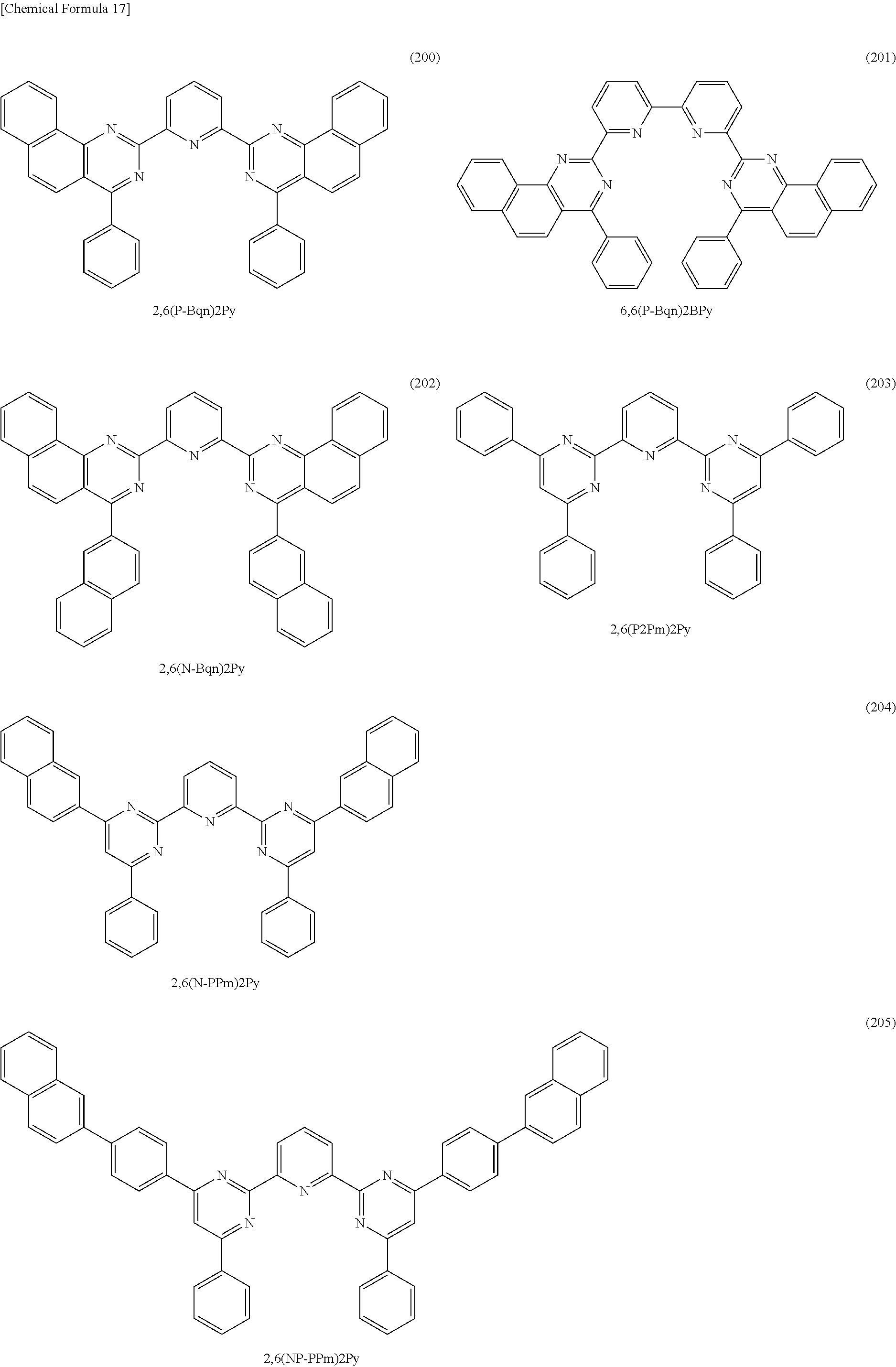

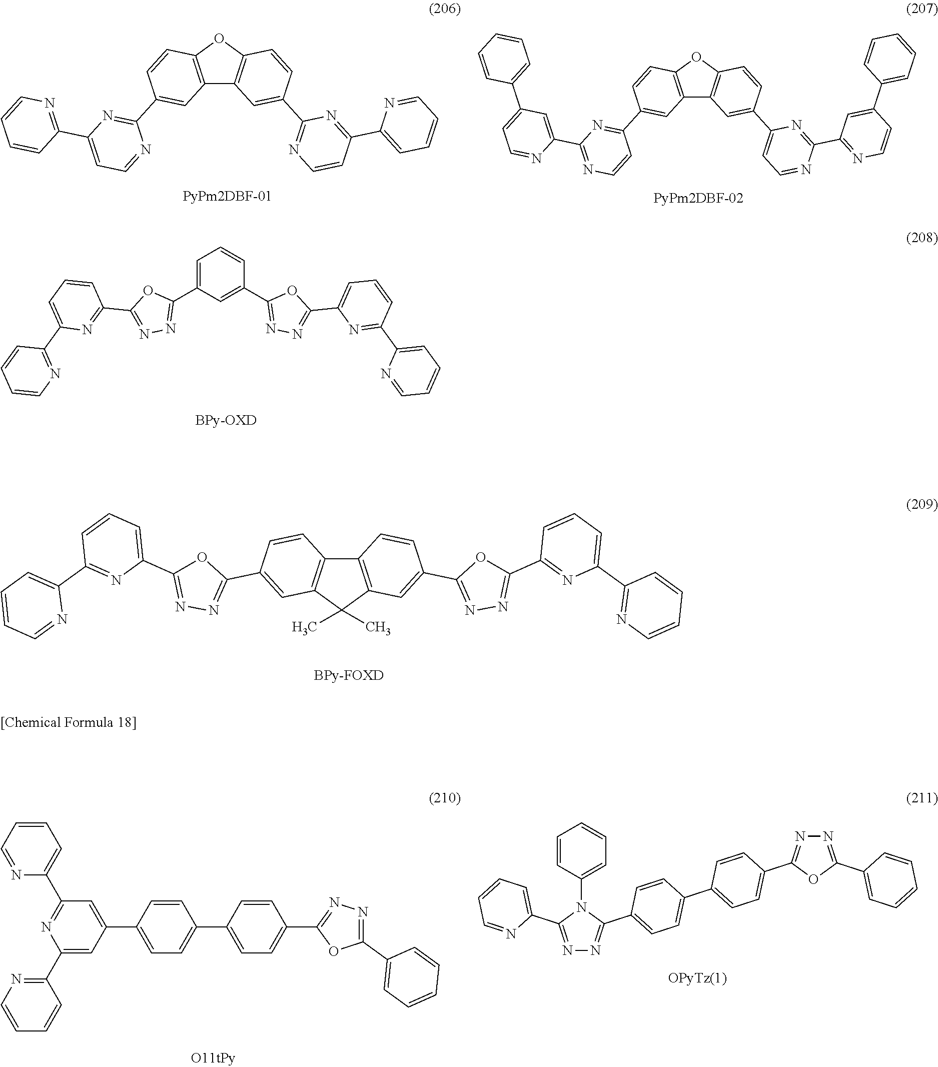

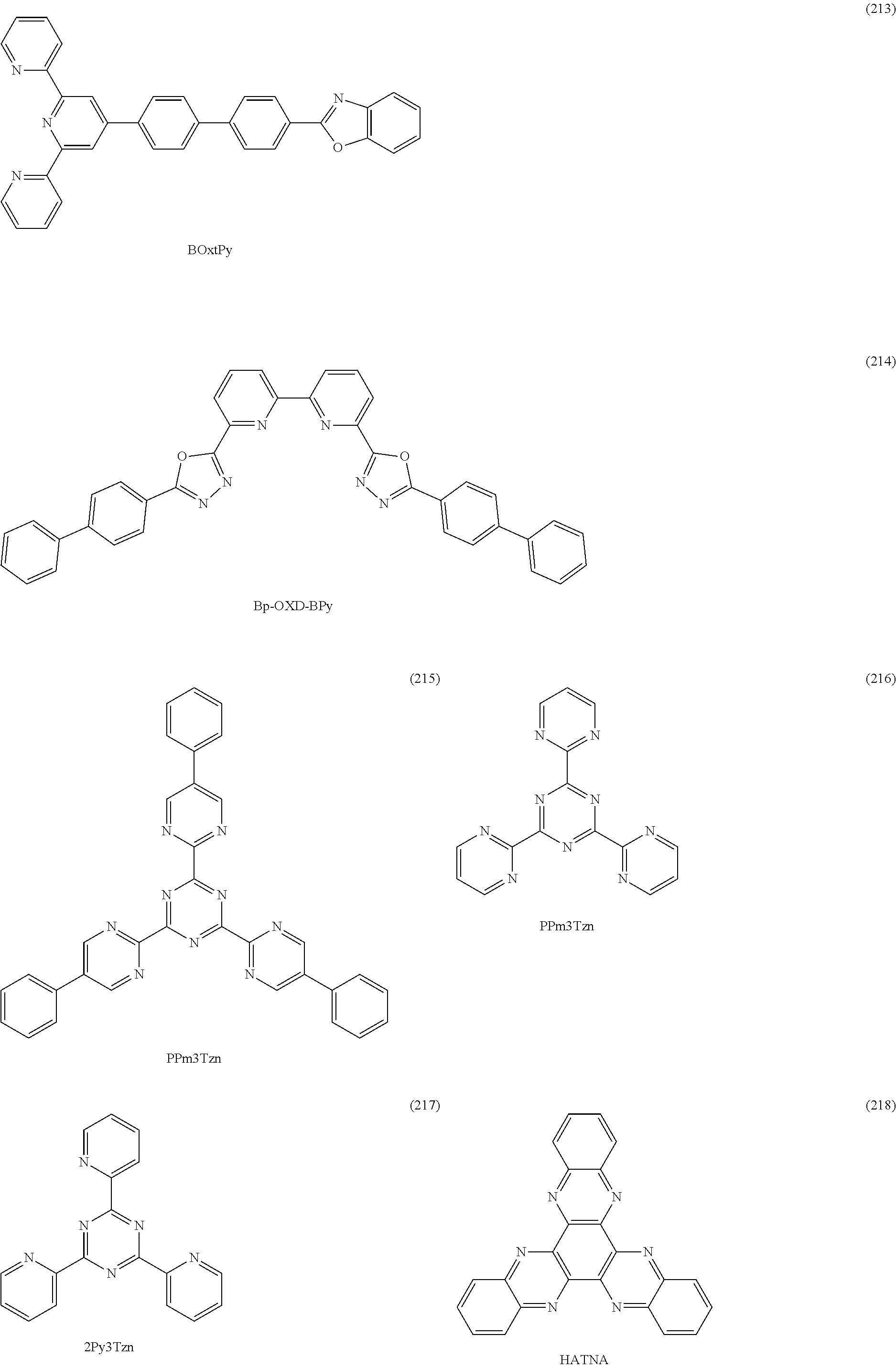

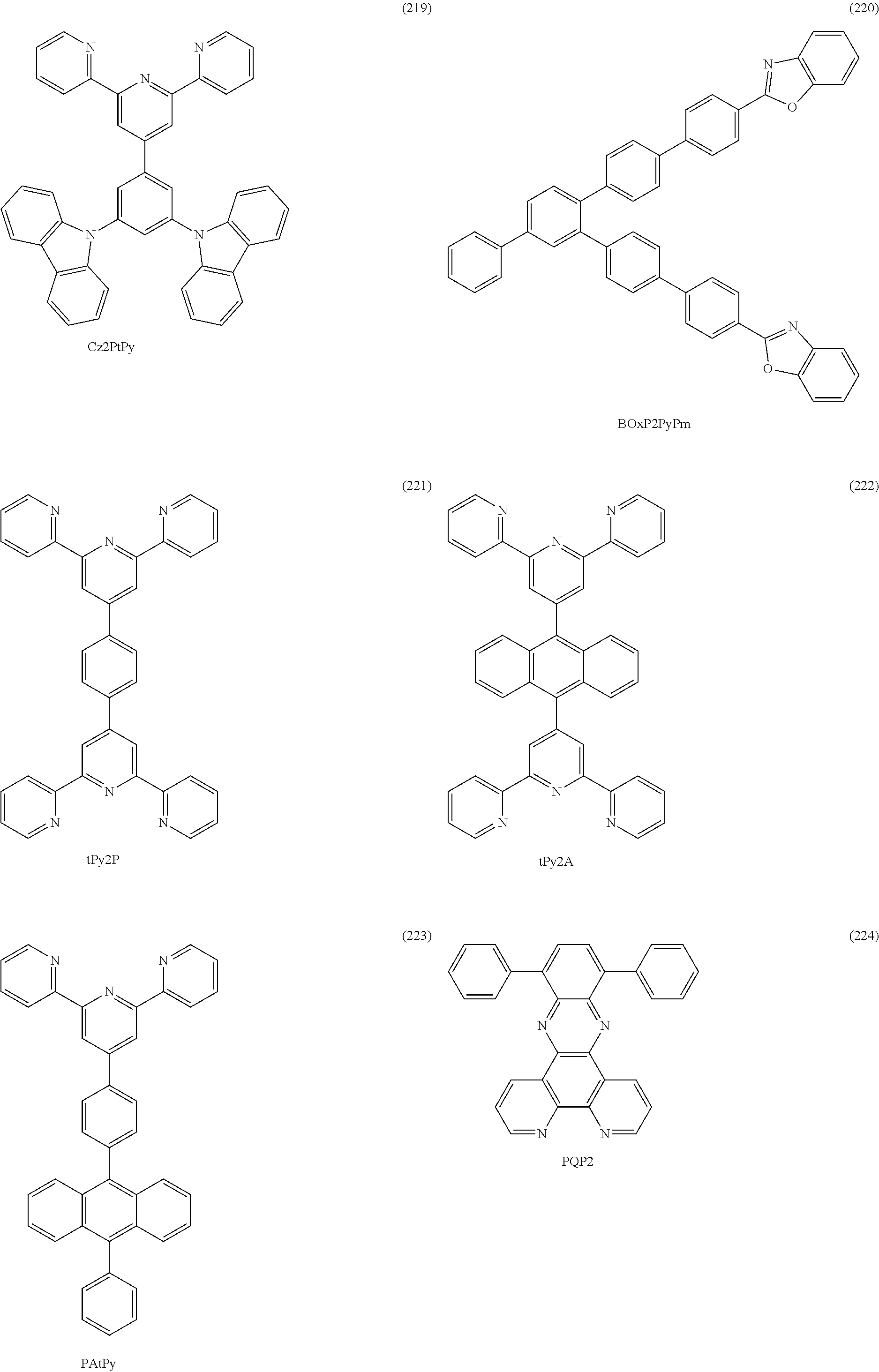

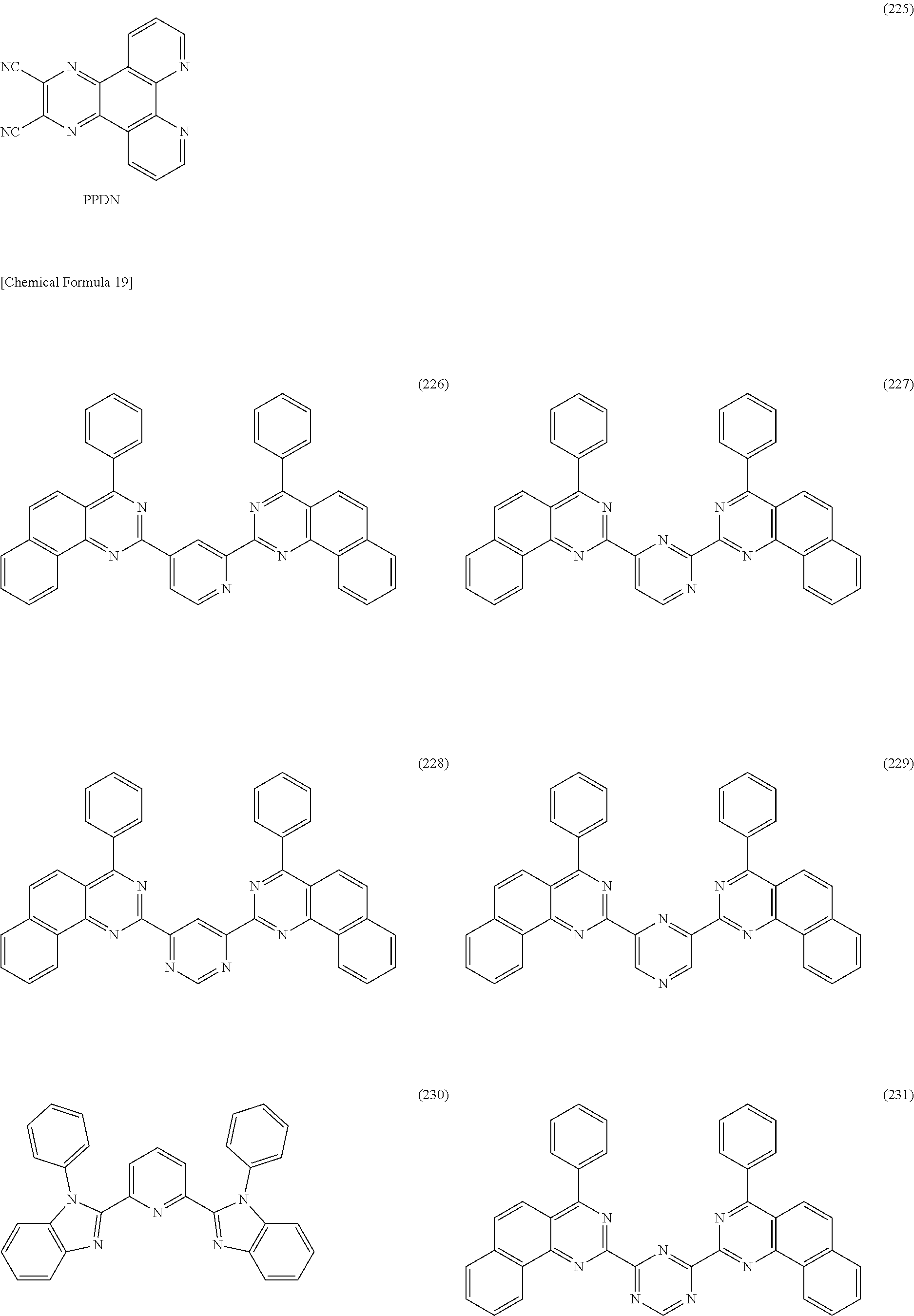

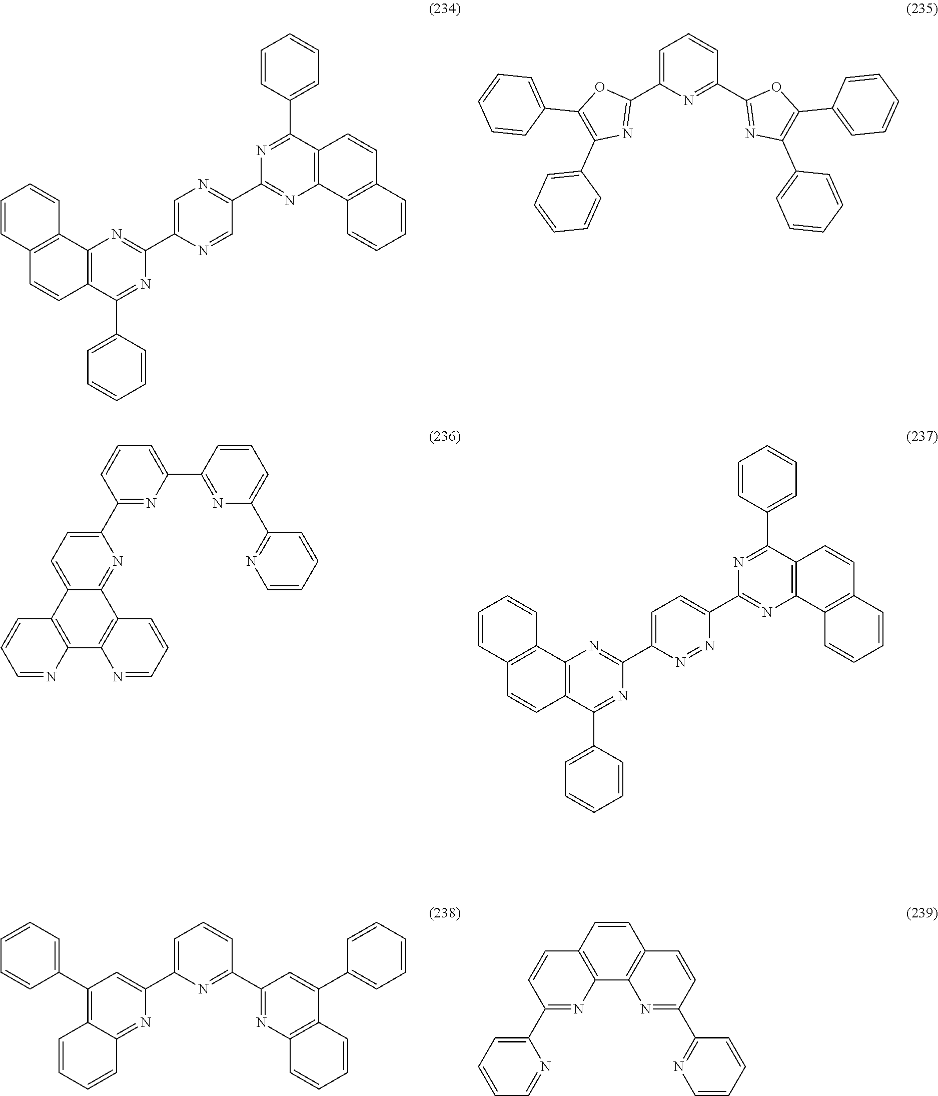

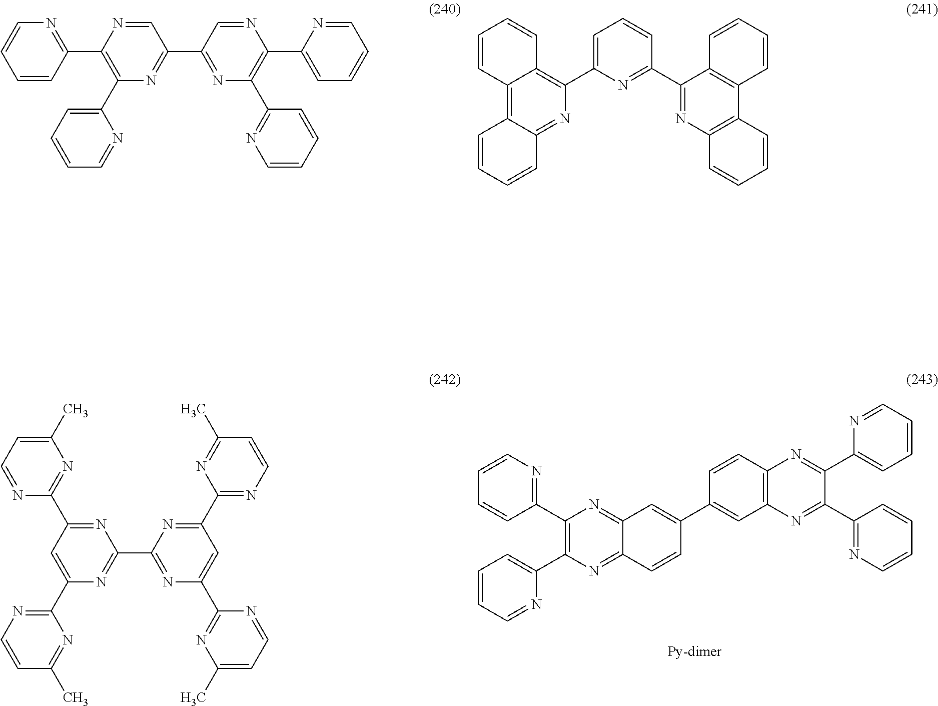

Note that the LUMO level of the second organic compound is further preferably lower than that of the first organic compound. In that case, electrons can be easily donated from the donor level formed by the first organic compound and the metal or metal oxide to the second organic compound. The LUMO level of the second organic compound is preferably lower than that of the first organic compound so that the second organic compound can have an electron-transport property.

The LUMO level of the second organic compound is preferably higher than or equal to −3.2 eV and lower than or equal to −2.0 eV, further preferably higher than or equal to −3.1 eV and lower than or equal to −2.0 eV, and still further preferably higher than or equal to −3.0 eV and lower than or equal to −2.5 eV. The LUMO level of the first organic compound is preferably higher than or equal to −3.0 eV and lower than or equal to −2.0 eV, further preferably higher than or equal to −2.7 eV and lower than or equal to −2.0 eV.

In the above case, electrons can be easily donated from the donor level formed by the first organic compound and the metal or metal oxide to the second organic compound. This facilitates electron transport in the second organic compound.

In one embodiment of the present invention, the LUMO level of the second organic compound is preferably lower than that of the first organic compound by greater than or equal to 0.20 eV and less than or equal to 0.60 eV, preferably 0.50 eV, further preferably by greater than or equal to 0.25 eV and less than or equal to 0.50 eV, still further preferably by greater than or equal to 0.30 eV and less than or equal to 0.50 eV, yet further preferably by greater than or equal to 0.35 eV and less than or equal to 0.50 eV, and yet still further preferably by greater than or equal to 0.40 eV and less than or equal to 0.50 eV.

In other words, when the LUMO level of the first organic compound is “LUMO1 (eV)” and the LUMO level of the second organic compound is “LUMO2 (eV)”, LUMO2 preferably satisfies the following formula.

$$LUMO 1 - 0.5 \leq LUMO 2 \leq LUMO 1 - 0.2$$

Further preferably, LUMO2 satisfies the following formula.

$$LUMO 1 - 0.5 \leq LUMO 2 \leq LUMO 1 - 0.25$$

Still further preferably, LUMO2 satisfies the following formula.

$$LUMO 1 - 0.5 \leq LUMO 2 \leq LUMO 1 - 0.3$$

Yet still further preferably, LUMO2 satisfies the following formula.

$$LUMO 1 - 0.5 \leq LUMO 2 \leq LUMO 1 - 0.35$$

Yet still further preferably, LUMO2 satisfies the following formula.

$$LUMO 1 - 0.5 \leq LUMO 2 \leq LUMO 1 - 0.4$$

When the LUMO2 is in the above range, the light-emitting device of one embodiment of the present invention can have favorable characteristics with low driving voltage, with or without undergoing a photolithography process involving exposure of the EL layer to the air. In addition, the light-emitting device can have high reliability.

As the second organic compound, an organic compound with an electron-transport property can be used. The organic compound with an electron-transport property is preferably a substance having an electron mobility higher than or equal to 1×10⁻⁷ cm²/Vs, further preferably higher than or equal to 1×10⁻⁶ cm²/Vs, when the square root of electric field strength [V/cm] is 600. Note that any other substance can also be used as long as the substance has an electron-transport property higher than a hole-transport property.

The second organic compound preferably has 25 to 100 carbon atoms. When having 25 to 100 carbon atoms, the second organic compound can have excellent sublimability, and thus, thermal decomposition of the organic compound during vacuum evaporation can be inhibited and the efficiency of use of the material can be high.

An organic compound having a glass transition temperature T_{g} higher than or equal to 100° C. is preferably used as the second organic compound. In that case, the electron-injection layer can be a layer that has high heat resistance and is not easily crystallized. Thus, the electron-injection layer is not easily crystallized even when part of the organic compound layer is processed by a lithography process.

As the second organic compound, an organic compound with an acid dissociation constant pKₐ lower than 4 can be used. Accordingly, the second organic compound can have low solubility in water and thus can be highly resistant to water and a chemical solution used in a lithography process.

An organic compound having an acid dissociation constant pKₐ smaller than 4 has lower solubility in water than an organic compound having an acid dissociation constant pKₐ larger than or equal to 4. The water resistance of the electron-injection layer including an organic compound having an acid dissociation constant pKₐ smaller than 4 as the second organic compound can be higher than that of the electro-injection layer including an organic compound having an acid dissociation constant pKₐ larger than or equal to 4 as the second organic compound. Moreover, occurrence of a problem such as peeling of the electron-injection layer from another layer in the fabrication process can be inhibited. Accordingly, occurrence of a problem that causes a defect in a light-emitting device can be inhibited.

In the case where the acid dissociation constant pKₐ of an organic compound is unknown, the acid dissociation constants pKₐ of skeletons in the organic compound are calculated and the largest acid dissociation constant pKₐ can be regarded as the acid dissociation constant pKₐ of the organic compound.

When the first layer includes the second organic compound in addition to the metal or metal oxide and the first organic compound, interaction between materials occurs efficiently. This can be confirmed by measurement of spin density by electron spin resonance (ESR).

For example, the spin density measured by ESR of a film that includes the metal or metal oxide and the first organic compound is preferably higher than that of a film that includes the metal or metal oxide and the second organic compound. The spin density measured by ESR of a film that includes the metal or metal oxide, the first organic compound, and the second organic compound is preferably higher than that of a film that includes any two of the metal or metal oxide, the first organic compound, and the second organic compound. In that case, interaction between the materials can be confirmed to occur efficiently.

Specifically, for example, by an electron spin resonance method, the density of spins attributed to a signal observed at a g-factor of approximately 2.00 in the film including the metal or metal oxide and the first organic compound is higher than or equal to 5×10¹⁶ spins/cm³, preferably higher than or equal to 1×10¹⁷ spins/cm³, further preferably higher than or equal to 1×10¹⁸ spins/cm³, still further preferably higher than or equal to 1×10¹⁹ spins/cm³, and yet still further preferably higher than or equal to 1×10²⁰ spins/cm³. In such a case, in the layer that includes a combination of the metal or metal oxide and the first organic compound, it can be confirmed that the interaction between the materials occurs efficiently. In addition, for example, in an electron spin resonance method, the density of spins attributed to a signal observed at a g-factor of approximately 2.00 in the film including the metal or metal oxide, the first organic compound, and the second organic compound is higher than or equal to 5×10¹⁶ spins/cm³, preferably higher than or equal to 1×10¹⁷ spins/cm³, further preferably higher than or equal to 1×10¹⁸ spins/cm³, still further preferably higher than or equal to 1×10¹⁹ spins/cm³, and yet still further preferably higher than or equal to 1×10²⁰ spins/cm³. In such a case, in the layer that includes the combination of the metal or metal oxide, the first organic compound, and the second organic compound, it can be confirmed that the interaction between the materials occurs more efficiently than in the layer that includes only two of the metal or metal oxide, the first organic compound, and the second organic compound. The density of spins attributed to a signal observed at a g-factor of approximately 2.00 is measured by an electron spin resonance method to be, for example, lower than or equal to 2×10¹⁶ spins/cm³ in a mixed film that includes the metal or metal oxide and the second organic compound. The density of spins attributed to a signal observed at a g-factor of approximately 2.00 is measured by an electron spin resonance method to be, for example, lower than or equal to 2×10¹⁶ spins/cm³ in a mixed film that includes the first organic compound and the second organic compound.

In the first layer, the molar ratio of the metal or metal oxide to the first organic compound (or the sum of the first organic compound and the second organic compound) is preferably greater than or equal to 0.1 and less than or equal to 10, further preferably greater than or equal to 0.2 and less than or equal to 5, still further preferably greater than or equal to 0.5 and less than or equal to 2. Alternatively, the volume ratio of the metal or metal oxide to the first organic compound (or the sum of the first organic compound and the second organic compound) is preferably greater than or equal to 0.01 and less than or equal to 0.3, further preferably greater than or equal to 0.02 and less than or equal to 0.2, still further preferably greater than or equal to 0.05 and less than or equal to 0.1. The first layer including the metal or metal oxide and the first organic compound (or the first organic compound and the second organic compound) in such a ratio enables providing the electron-injection layer having a high electron-injection property. Although the second organic compound is not necessarily used, the volume ratio of the first organic compound to the second organic compound is preferably greater than or equal to 0.1 and less than or equal to 10, further preferably greater than or equal to 0.2 and less than or equal to 5, still further preferably greater than or equal to 0.5 and less than or equal to 2. Mixing the first organic compound and the second organic compound in such a ratio enables providing the electron-injection layer having a high electron-transport property. When an organic compound with favorable thermophysical properties with high T_{g} is used as the second organic compound, highly reliable organic EL device can be provided.

The thickness of the first layer is preferably greater than or equal to 2 nm and less than or equal to 20 nm, further preferably greater than or equal to 5 nm and less than or equal to 10 nm. In the case where the first layer has a stacked-layer structure of a metal or metal oxide layer and a layer containing the first organic compound, the thickness of the metal or metal oxide layer is preferably greater than or equal to 0.1 nm and less than or equal to 5 nm, further preferably greater than or equal to 0.2 nm and less than or equal to 2 nm. In the case where the first layer has a stacked-layer structure of a metal or metal oxide layer and a layer containing the first organic compound, the thickness of the layer containing the first organic compound is preferably greater than or equal to 2 nm and less than or equal to 20 nm, further preferably greater than or equal to 5 nm and less than or equal to 10 nm.

The use of the second organic compound enables the composite material in which the metal or metal oxide, the first organic compound, and the second organic compound are mixed to favorably function, resulting in high emission efficiency of the light-emitting device.

### Embodiment 2

In this embodiment, light-emitting devices of one embodiment of the present invention will be described in detail.

FIG. 1A is a schematic diagram of the light-emitting device of one embodiment of the present invention. The light-emitting device includes the first electrode 101 over the insulator 109, and the organic compound layer 103 between the first electrode 101 and the second electrode 102. The organic compound layer 103 includes at least the light-emitting layer 113 and the electron-injection layer 115. The light-emitting layer 113 includes alight-emitting substance and emits light when voltage is applied between the first electrode 101 and the second electrode 102.

The organic compound layer 103 preferably includes, besides the light-emitting layer 113 and the electron-injection layer 115, functional layers such as the hole-injection layer 111, the hole-transport layer 112, and the electron-transport layer 114, as illustrated in FIG. 1A. The organic compound layer 103 may include functional layers other than the above functional layers, such as a hole-blocking layer, an exciton-blocking layer, and an intermediate layer. Alternatively, any of the above-described layers may be omitted.

The electron-injection layer 115 includes, as described in Embodiment 1, a metal or a metal oxide, an organic compound (a first organic compound) including a first π-electron deficient heteroaromatic ring with an electron-donating group, and an organic compound (a second organic compound) including a second π-electron deficient heteroaromatic ring. The electron-injection layer 115 may further include another organic compound (a third organic compound).

The specific structure of the electron-injection layer 115 is described in detail in Embodiment 1; thus, repeated description thereof is omitted.

This embodiment shows an example in which the first electrode 101 includes an anode, the second electrode 102 includes a cathode, and the first electrode 101 is formed on the insulator 109 side; however, a structure in which the second electrode 102 is formed on the insulator 109 side, what is called an inversely stacked structure, may be employed. In this case, the light-emitting device has a stacked-layer structure in which the second electrode 102, the electron-injection layer 115, (the electron-transport layer 114), the light-emitting layer 113, (the hole-transport layer 112, the hole-injection layer 111), and the first electrode 101 are stacked in this order from the insulator 109 side. In the case of such a light-emitting device having an inversely stacked structure, the relatively stable hole-injection layer 111 serves as a surface; thus, the light-emitting device can have higher reliability.

The first electrode 101 and the second electrode 102 may each have a single-layer structure or a stacked-layer structure. In the case of the stacked-layer structure, a layer in contact with the organic compound layer 103 serves as an anode or a cathode. In the case where the electrodes each have the stacked-layer structure, there is no limitation on work functions of materials for layers other than the layer in contact with the organic compound layer 103, and the materials can be selected in accordance with required properties such as a resistance value, processing easiness, reflectivity, light-transmitting property, and stability.

The anode is preferably formed using any of metals, alloys, and conductive compounds with a high work function (specifically, higher than or equal to 4.0 eV), mixtures thereof, and the like. Specific examples include indium oxide-tin oxide (ITO: indium tin oxide), indium oxide-tin oxide containing silicon or silicon oxide (ITSO: indium tin silicon oxide), indium oxide-zinc oxide, and indium oxide containing tungsten oxide and zinc oxide (IWZO). Such conductive metal oxide films are usually formed by a sputtering method, but may be formed by application of a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), titanium, (Ti), aluminum (Al), nitride of a metal material (e.g., titanium nitride), or the like can be used for the anode. The anode may be a stack of layers formed of any of these materials. For example, a film in which Al, Ti, and ITSO are stacked in this order over Ti is preferable because the film has high efficiency owing to high reflectivity and enables high resolution of several thousand ppi. Graphene can also be used for the anode. When a composite material that can be included in the hole-injection layer 111, which is described later, is used for a layer (typically, the hole-injection layer) in contact with the anode, an electrode material can be selected regardless of its work function.

The hole-injection layer 111 is provided in contact with the anode and has a function of facilitating injection of holes to the organic compound layer 103. The hole-injection layer 111 can be formed using a phthalocyanine-based compound or complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS).

The hole-injection layer 111 may be formed using a substance having an electron-acceptor property. Examples of the substance having an electron-acceptor property include organic compounds having an electron-withdrawing group (a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylen-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3] radialene derivative having an electron-withdrawing group (in particular, a cyano group, a halogen group such as a fluoro group, or the like) has a significantly high electron-acceptor property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an electron-acceptor property, a transition metal oxide such as molybdenum oxide, vanadium oxide, ruthenium oxide, tungsten oxide, or manganese oxide can be used, other than the above-described organic compounds.

The hole-injection layer 111 is preferably formed using a composite material containing any of the aforementioned materials having an electron-acceptor property and an organic compound having a hole-transport property.

As the organic compound having a hole-transport property used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the organic compound having a hole-transport property used in the composite material preferably has a hole mobility higher than or equal to 1×10⁻⁶ cm²/Vs. The organic compound having a hole-transport property used in the composite material preferably has a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

The above-described composite material containing a material having an electron-acceptor property and an organic compound having a hole-transport property efficiently causes interaction between materials. Thus, in a film containing the composite material, the spin density attributed to a signal observed at a g-factor of approximately 2.00 is measured by ESR to be, preferably higher than or equal to 1×10¹⁷ spins/cm³.

Such an organic compound having a hole-transport property further preferably has any of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound having a hole-transport property preferably has an N,N-bis(4-biphenyl)amino group to enable manufacturing a light-emitting device with a long lifetime.

Specific examples of the organic compound having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyl)triphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyl)triphenylamine (abbreviation: BBAPNB), 4-[4-(2-naphthyl)phenyl]-4′,4″-diphenyl)triphenylamine (abbreviation: BBAPNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yl)triphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyl)triphenylamine (abbreviation: TPBiAβNB), 4-(3-biphenylyl)-4′-[4-(2-naphthyl)phenyl]-4″-phenyl)triphenylamine (abbreviation: mTPBiAβNBi), 4-(4-biphenylyl)-4′-[4-(2-naphthyl)phenyl]-4″-phenyl)triphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyl)triphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Examples of the aromatic amine compounds that can be used as the material having a hole-transport property include N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances having an electron-acceptor property, the organic compound having an acceptor property is easy to use because it is easily deposited by vapor deposition.

The hole-transport layer 112 is formed using an organic compound having a hole-transport property. The organic compound having a hole-transport property preferably has a hole mobility of 1×10⁻⁶ cm²/Vs or higher.

Examples of the material having a hole-transport property include compounds having an aromatic amine skeleton, such as 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), andN-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: PNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: PNCCBP), 9,9′-di-2-naphthyl-3,3′-9H,9′H-bicarbazole (abbreviation: BisPNCz), 9-(2-naphthyl)-9′-[1,1′: 4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, and 9-(triphenylen-2-yl)-9′-[1,1′: 3′,1″-terphenyl]-4-yl-3,3′-9H,9′H-bicarbazole; compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the material having a hole-transport property used for the composite material for the hole-injection layer 111 can also be suitably used as the material contained in the hole-transport layer 112.

The light-emitting layer 113 is a layer including a light-emitting substance and preferably includes a light-emitting substance and a host material. The light-emitting layer 113 may additionally include other materials. Alternatively, the light-emitting layer 113 may be a stack of two layers with different compositions.

As the light-emitting substance, fluorescent substances, phosphorescent substances, substances exhibiting thermally activated delayed fluorescence (TADF), or other light-emitting substances may be used.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(NN,N-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″ N″,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-NN,NN-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N-diphenyl-N,N′-(1,6-pyrene-diyl)bis[(6-phenylbenzo[b]naphtho[1,2-d]furan)-8-amine](abbreviation: 1,6BnfAPrn-03), N,N-diphenyl-N,N-bis(9-phenyl-9H-carbazol-2-yl)naphtho[2,3-b;6,7-b′]bisbenzofuran-3,10-diamine (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPm, and 1,6BnfAPrn-03 are particularly preferable because of their high hole-trapping properties, high emission efficiency, or high reliability.

A condensed heteroaromatic compound containing nitrogen and boron, especially a compound having a diaza-boranaphtho-anthracene skeleton, exhibits a narrow emission spectrum, emits blue light with favorable color purity, and can thus be used suitably. Examples of the compound include 5,9-diphenyl-5,9-diaza-13b-boranaphtho[3,2,1-de]anthracene (abbreviation: DABNA1), 9-[(1,1′-diphenyl)-3-yl]-N,N,5,11-tetraphenyl-5,9-dihydro-5,9-diaza-13b-boranaphtho[3,2,1-de]anthracen-3-amine (abbreviation: DABNA2), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′:4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-Y), or the like can be suitably used.

Examples of the material that can be used when a phosphorescent substance is used as the light-emitting substance in the light-emitting layer are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), and tris(5-methyl-3,4-diphenyl-4H-1,2,4-triazolato)iridium(III) (abbreviation: [Ir(Mptz)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptzl-Me)₃]); an organometallic iridium complex having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-{1-[2,6-bis(1-methylethyl)phenyl]-1H-imidazol-2-yl-κN³}-4-cyanophenyl-κC) (abbreviation: CNImIr); an organometallic complex having a benzimizazolidene skeleton, such as tris[(6-tert-butyl-3-phenyl-2H-imidazo[4,5-b]pyrazin-1-yl-KC²)phenyl-κC]iridium(III) (abbreviation: [Ir(cb)₃]); and an organometallic iridium complex in which a phenylpyridine derivative including an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIracac). These compounds emit blue phosphorescent light and have an emission peak in the wavelength range of 450 nm to 520 nm.

Other examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C²)iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C²)iridium(III) acetylacetonate (abbreviation: [Ir(pq)₂(acac)]), [2-d₃-methyl-8-(2-pyridinyl-xN)benzofuro[2,3-b]pyridine-κC]bis[2-(5-d₃-methyl-2-pyridinyl-κN²)phenyl-κC]iridium(III) (abbreviation: [Ir(5mppy-d₃)₂(mbfpypy-d₃)]), [2-d₃-methyl-(2-pyridinyl-xN)benzofuro[2,3-b]pyridine-κC]bis[2-(2-pyridinyl-κN)phenyl-κC]iridium(III) (abbreviation: [Ir(ppy)₂(mbfpypy-d₃)]), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-(2-pyridinyl-KN)benzofuro[2,3-b]pyridine-κC]bis[2-(2-pyridinyl-κN)phenyl-κC]iridium(III) (abbreviation: [Ir(ppy)₂(mbfpypy)]), and [2-(4-methyl-5-phenyl-2-pyridinyl-κN)phenyl-κC]bis[2-(2-pyridinyl-κN)phenyl-κC]iridium(III) (abbreviation: [Ir(ppy)₂(mdppy)]); and a rare earth metal complex such as tris(acetylacetonato) (monophenanthroline)terbium(III) (abbreviation: [Tb(acac)₃(Phen)]). These compounds mainly emit green phosphorescent light and have an emission peak in the wavelength range of 500 nm to 600 nm. Note that organometallic iridium complexes having a pyrimidine skeleton have distinctively high reliability or emission efficiency and thus are particularly preferable.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes having a pyridine skeleton, such as tris(1-phenylisoquinolinato-N,C″)iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-N]phenyl-cC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds emit red phosphorescent light and have an emission peak in the wavelength range of 600 nm to 700 nm. Furthermore, the organometallic iridium complexes having a pyrazine skeleton can provide red light emission with favorable chromaticity.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

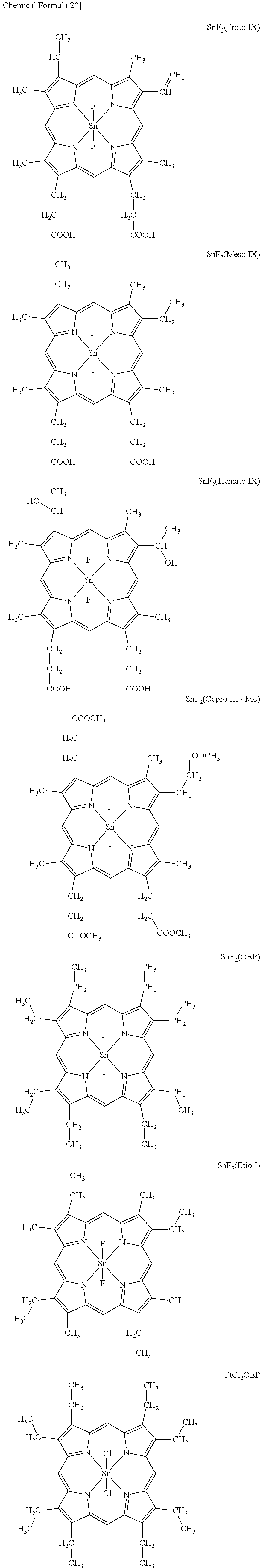

Alternatively, it is possible to use a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high electron-acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-acceptor property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

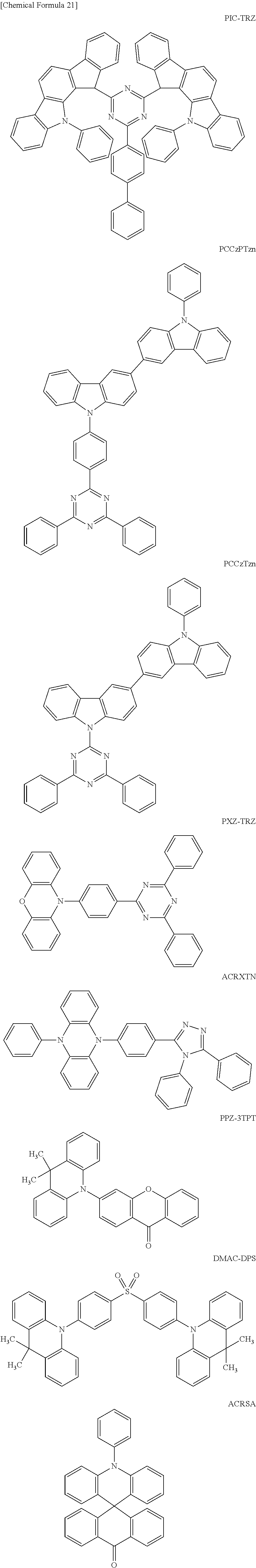

Note that a TADF material is a material having a small difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S₁ level and the T₁ level and functions as a TADF material capable of converting triplet excitation energy into singlet excitation energy.

A phosphorescent spectrum observed at a low temperature (e.g., 77 K to 10 K) is used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between the S₁ level and the T₁ level of the TADF material is preferably smaller than or equal to 0.3 eV, further preferably smaller than or equal to 0.2 eV.

When a TADF material is used as the light-emitting substance, the S₁ level of the host material is preferably higher than that of the TADF material. In addition, the T₁ level of the host material is preferably higher than that of the TADF material.

As the host material in the light-emitting layer, various carrier-transport materials such as materials having an electron-transport property and/or materials having a hole-transport property, and the TADF materials can be used.

The material having a hole-transport property is preferably an organic compound having an amine skeleton or a π-electron rich heteroaromatic ring skeleton, for example. As the π-electron rich heteroaromatic ring, a condensed aromatic ring having at least one of an acridine skeleton, a phenoxazine skeleton, a phenothiazine skeleton, a furan skeleton, a thiophene skeleton, and a pyrrole skeleton is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound having a hole-transport property preferably has an N,N-bis(4-biphenyl)amino group to enable manufacturing a light-emitting device with a long lifetime.

Examples of such an organic compound include compounds having an aromatic amine skeleton, such as 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), and 9,9′-diphenyl-9H,9′H-3,3′-bicarbazole (abbreviation: PCCP); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the material having a hole-transport property that can be used for the hole-transport layer can also be used.

As the material having an electron-transport property, for example, a metal complex such as bis(10-hydroxybenzo[h]quinolinato)beryllium(II) (abbreviation: BeBq2), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferably used. Examples of the organic compound having a π-electron deficient heteroaromatic ring skeleton include an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

Among the above materials, the organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton have high reliability and thus are preferable. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high electron-acceptor property and high reliability.

Examples of the organic compound having a π-electron deficient heteroaromatic ring skeleton include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOS); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-{3-[3-(N-phenyl-9H-carbazol-3-yl)-9H-carbazol-9-yl]phenyl}dibenzo[f,h]quinoxaline (abbreviation: 2mPCCzPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′: 4,5]furo[2,3-b]pyrazine (abbreviation: 9mDBtBPNfpr), 9-[3′-(dibenzothiophen-4-yl)biphenyl-4-yl]naphtho[1′,2′: 4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(biphenyl-3-yl)]naphtho[1′,2′: 4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(PN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)₂Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenyl-indolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′: 4′,1″-terphenyl)-4-yl]-1-dibenzofuranyl}-1,3,5-triazine (abbreviation: mBP-TPDBfTzn), 2-[4-(2-naphthalenyl)phenyl]-4-phenyl-6-spiro[9H-fluorene-9,9′-[9H]xanthen]-4-yl-1,3,5-triazine (abbreviation: βNP-SFx(4)Tzn), or 2-phenyl-4,6-bis[3-(triphenylsilyl)phenyl]-1,3,5-triazine (abbreviation: mSiTrz). The organic compound that has a heteroaromatic ring having a diazine skeleton, the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength on a lowest-energy-side absorption band of the fluorescent substance, in which case excitation energy is transferred smoothly from the TADF material to the fluorescent substance and light emission can be obtained efficiently.

In order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton that brings about light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transportation or carrier recombination. Here, the luminophore refers to an atomic group (skeleton) that brings about light emission in a fluorescent substance. The luminophore is preferably a skeleton having a π bond, further preferably includes an aromatic ring, and still further preferably includes a condensed aromatic ring or a condensed heteroaromatic ring. Examples of the luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. Among the substances having an anthracene skeleton that is used as the host material, a substance having a diphenylanthracene skeleton, in particular, a substance having a 9,10-diphenylanthracene skeleton, is chemically stable and thus is preferably used as the host material. The host material preferably has a carbazole skeleton because the hole-injection and hole-transport properties are improved; further preferably, the host material has a benzocarbazole skeleton in which a benzene ring is further condensed to a carbazole skeleton because the HOMO level thereof is shallower than that of the host material having a carbazole skeleton by approximately 0.1 eV and thus holes enter the host material easily. In particular, the host material preferably has a dibenzocarbazole skeleton because the HOMO level thereof is shallower than that of the host material having a carbazole skeleton by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-QNPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: βN-mQNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

Note that the host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property can be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that exhibits light emission whose wavelength overlaps with the wavelength on a lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the LUMO level of the material having a hole-transport property is preferably higher than or equal to that of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of the mixed film in which the material having a hole-transport property and the material having an electron-transport property are mixed is shifted to the longer wavelength side than the emission spectrum of each of the materials (or has another peak on the longer wavelength side) observed by comparison of the emission spectra of the material having a hole-transport property, the material having an electron-transport property, and the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of transient PL of the material having a hole-transport property, the material having an electron-transport property, and the mixed film of these materials. The transient PL can be rephrased as transient electroluminescence (EL). That is, the formation of an exciplex can also be confirmed by a difference in transient response observed by comparison of the transient EL of the material having a hole-transport property, the material having an electron-transport property, and the mixed film of these materials.

The electron-transport layer 114 contains a material having an electron-transport property. The material having an electron-transport property preferably has an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound including a π-electron deficient heteroaromatic ring is preferable as the above organic compound. The organic compound including a π-electron deficient heteroaromatic ring is preferably one or more of an organic compound including a heteroaromatic ring having an azole skeleton, an organic compound including a heteroaromatic ring having a pyridine skeleton, an organic compound including a heteroaromatic ring having a diazine skeleton, and an organic compound including a heteroaromatic ring having a triazine skeleton.

As the organic compounds having an electron-transport property that can be used in the electron-transport layer 114, the organic compound having an electron-transport property in the light-emitting layer 113 and the organic compound mentioned in Embodiment 1 as the organic compound that can be used as the second organic compound in the electron-injection layer 115 can be similarly used. Among the above-described materials, the organic compound that has a heteroaromatic ring having a diazine skeleton, the organic compound that has a heteroaromatic ring having a pyridine skeleton, and the organic compound that has a heteroaromatic ring having a triazine skeleton are especially preferable because of having high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. An organic compound having a phenanthroline skeleton such as mTpPPhen, PnNPhen, or mPPhen2P is preferable, and an organic compound having a phenanthroline dimer structure such as mPPhen2P is further preferable because of its excellent stability. The organic compound having an electron-transport property and high HOMO level, such as 2mPCCzPDBq and DACT-II, is preferable because a light-emitting device with a low driving voltage can be obtained.

The electron-transport layer preferably contains an organic compound having an electron-transport property with an acid dissociation constant pKₐ of less than 4.

The electron-transport layer 114 may have a stacked-layer structure. In the case where the electron-transport layer 114 has a stacked-layer structure, the layer in contact with the light-emitting layer 113 may function as a hole-blocking layer. In the case where the electron-transport layer in contact with the light-emitting layer functions as a hole-blocking layer, the electron-transport layer is preferably formed using a material having a deeper HOMO level than a material included in the light-emitting layer by more than or equal to 0.5 eV.

The electron-injection layer 115 is formed between the electron-transport layer 114 and the second electrode 102. Since the structure of the electron-injection layer 115 has been described in detail in Embodiment 1, the repetitive description thereof is omitted.

The second electrode 102 is an electrode including a cathode. The second electrode 102 may have a stacked-layer structure, in which case a layer in contact with the organic compound layer 103 functions as a cathode. For the cathode, a metal, an alloy, an electrically conductive compound, or a mixture thereof each having a low work function (specifically, lower than or equal to 3.8 eV) or the like can be used. Specific examples of such a cathode material include elements belonging to Group 1 or 2 of the periodic table, such as alkali metals (e.g., lithium (Li) or cesium (Cs)), magnesium (Mg), calcium (Ca), and strontium (Sr), alloys containing these elements (e.g., MgAg and AlLi), compounds containing these elements (e.g., lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film formed using any of the above materials having a low work function is provided between the second electrode 102 and the electron-transport layer, a variety of conductive materials such as Al, Ag, ITO, or indium oxide-tin oxide containing silicon or silicon oxide can be used for the cathode regardless of the work function.

When the second electrode 102 is formed using a material that transmits visible light, the light-emitting device can emit light from the second electrode 102 side. When the first electrode 101 is formed using a material that transmits visible light, the light-emitting device can emit light from the first electrode 101 side.

Films of these conductive materials can be deposited by a dry process such as a vacuum evaporation method or a sputtering method, an ink-jet method, a spin coating method, or the like. Alternatively, a wet process using a sol-gel method or a wet process using a paste of a metal material may be employed.

Note that in the case of a top-emission light-emitting device, forming a cap layer by evaporation of an organic compound over the second electrode can improve light extraction efficiency. The cap layer may have a single-layer structure or a stacked-layer structure. In the case of a stacked-layer structure, the use of organic compounds with different refractive indexes can further increase the light extraction efficiency.

The organic compound layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different deposition methods may be used to form the electrodes or the layers described above.

Next, an embodiment of a light-emitting device with a structure in which a plurality of light-emitting units are stacked (this type of light-emitting device is also referred to as a stacked or tandem device) is described with reference to FIG. 1B. This light-emitting device includes a plurality of light-emitting units between an anode and a cathode. One light-emitting unit has substantially the same structure as the organic compound layer 103 illustrated in FIG. 1A. In other words, the light-emitting device illustrated in FIG. 1B includes a plurality of light-emitting units, and the light-emitting device illustrated in FIG. 1A includes a single light-emitting unit.

In FIG. 1B, a first light-emitting unit 511 and a second light-emitting unit 512 are stacked between a first electrode 501 and a second electrode 502, and an intermediate layer 513 is provided between the first light-emitting unit 511 and the second light-emitting unit 512. The first electrode 501 and the second electrode 502 correspond, respectively, to the first electrode 101 and the second electrode 102 illustrated in FIG. 1A, and the materials given in the description for FIG. 1A can be used. Furthermore, the first light-emitting unit 511 and the second light-emitting unit 512 may have the same structure or different structures.

The intermediate layer 513 has a function of injecting electrons into one of the light-emitting units and injecting holes into the other of the light-emitting units when voltage is applied between the first electrode 501 and the second electrode 502. That is, in FIG. 1B, the intermediate layer 513 injects electrons into the first light-emitting unit 511 and holes into the second light-emitting unit 512 when voltage is applied such that the potential of the anode becomes higher than the potential of the cathode.

The intermediate layer 513 includes a charge-generation layer. The charge-generation layer includes at least a p-type layer 117. The p-type layer 117 is preferably formed using any of the composite materials given above as examples of materials that can be used for the hole-injection layer 111. The p-type layer 117 maybe formed by stacking a film containing the above-described acceptor material as a material included in the composite material and a film containing a hole-transport material. When a potential is applied to the p-type layer 117, electrons are injected into the electron-transport layer 114 and holes are injected into the cathode; thus, the light-emitting device operates.

Note that the intermediate layer 513 preferably includes one or both of an electron-relay layer 118 and an n-type layer 119 in addition to the p-type layer 117.

The electron-relay layer 118 contains at least the substance having an electron-transport property and has a function of preventing an interaction between the n-type layer 119 and the p-type layer 117 and smoothly transferring electrons. The LUMO level of the substance having an electron-transport property included in the electron-relay layer 118 is preferably between the LUMO level of an acceptor substance in the p-type layer 117 and the LUMO level of a substance included in a layer of the electron-transport layer 114 that is in contact with the intermediate layer 513. As a specific value of the energy level, the LUMO level of the substance having an electron-transport property in the electron-relay layer 118 is preferably higher than or equal to −5.0 eV, further preferably higher than or equal to −5.0 eV and lower than or equal to −3.0 eV. Note that as the substance having an electron-transport property in the electron-relay layer 118, a phthalocyanine-based material or a metal complex having a metal-oxygen bond and an aromatic ligand is preferably used.

The n-type layer 119 can be formed using a substance having a high electron-injection property, e.g., an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)).

In the case where the n-type layer 119 contains a substance having an electron-transport property and a donor substance, the donor substance can be an organic compound such as tetrathianaphthacene (abbreviation: TTN), nickelocene, or decamethylnickelocene, as well as an alkali metal, an alkaline earth metal, a rare earth metal, or a compound thereof (e.g., an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). As the substance having an electron-transport property, a material similar to the above-described material for the electron-transport layer 114 can be used.

Instead of the n-type layer 119, a metal or metal oxide, a first organic compound having a π-electron deficient heteroaromatic ring, and a second organic compound having two or more heteroaromatic rings that are bonded or condensed to each other and include three or more heteroatoms in total, which are described as being used for the electron-injection layer in Embodiment 1, may be formed in the same position as the n-type layer 119. Also in the case of such a structure, a tandem light-emitting device with favorable characteristics can be manufactured.

In the case where the anode-side surface of a light-emitting unit is in contact with the intermediate layer 513, the charge-generation layer of the intermediate layer 513 can also function as a hole-injection layer of the light-emitting unit; therefore, a hole-injection layer is not necessarily provided in the light-emitting unit. In the case where the cathode-side surface of a light-emitting unit is in contact with the intermediate layer 513, the intermediate layer 513 can also function as an electron-injection layer of the light-emitting unit; therefore, an electron-injection layer is not necessarily provided in the light-emitting unit.

The light-emitting device having two light-emitting units is described with reference to FIG. 1B; however, one embodiment of the present invention can also be applied to a light-emitting device in which three or more light-emitting units are stacked. With a plurality of light-emitting units partitioned by the intermediate layer 513 between a pair of electrodes as in the light-emitting device of this embodiment, it is possible to provide a long-life element that can emit light with high luminance at a low current density. A light-emitting apparatus that can be driven at a low voltage and has low power consumption can also be provided.

When the emission colors of the light-emitting units are different, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as the whole.

The organic compound layer 103, the first light-emitting unit 511, the second light-emitting unit 512, the layers such as the intermediate layer 513, and the electrodes that are described above can be formed by a method such as an evaporation method (including a vacuum evaporation method), a droplet discharge method (also referred to as an ink-jet method), a coating method, or a gravure printing method. A low molecular material, a middle molecular material (including an oligomer and a dendrimer), or a high molecular material may be included in the above components.

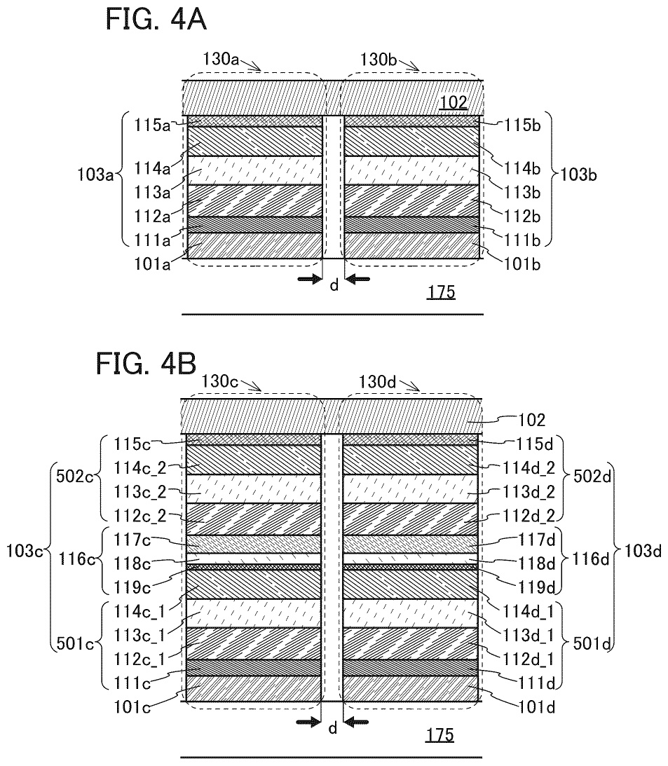

FIG. 4A illustrates two adjacent light-emitting devices (a light-emitting device 130a and a light-emitting device 130b) included in a display device of one embodiment of the present invention.

The light-emitting device 130a includes an organic compound layer 103a between a first electrode 101a over an insulating layer 175 and the second electrode 102 facing the first electrode 101a. The organic compound layer 103a includes a hole-injection layer 111a, a hole-transport layer 112a, a light-emitting layer 113a, an electron-transport layer 114a, and an electron-injection layer 115a, but may have a different stacked-layer structure.

The light-emitting device 130b includes an organic compound layer 103b between a first electrode 101b over the insulating layer 175 and the second electrode 102 facing the first electrode 101b. The organic compound layer 103b includes a hole-injection layer 111b, a hole-transport layer 112b, a light-emitting layer 113b, an electron-transport layer 114b, and an electron-injection layer 115b, but may have a different stacked-layer structure.

The structures of the electron-transport layer 114a and the electron-injection layer 115a in the light-emitting device 130a and the structures of the electron-transport layer 114b and the electron-injection layer 115b in the light-emitting device 130b preferably have the structure as described in Embodiment 1.

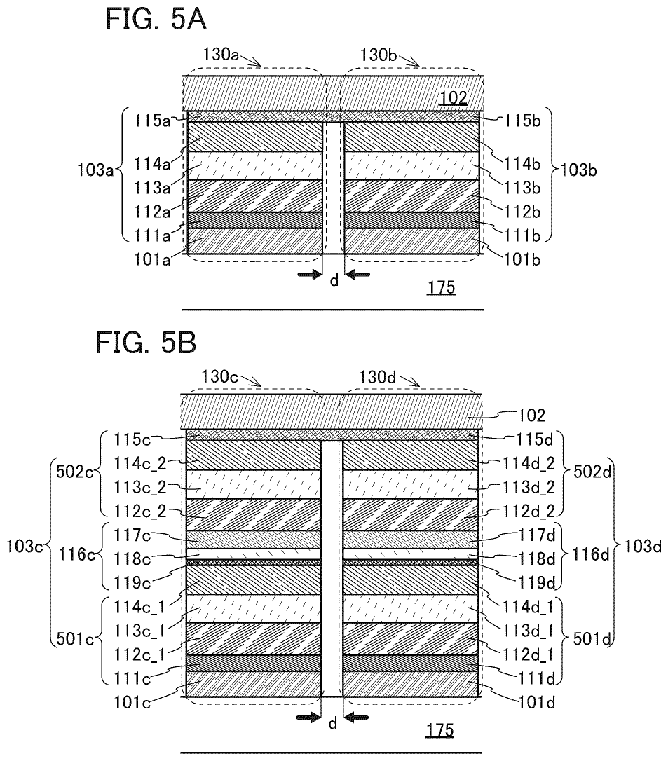

The second electrode 102 is preferably one layer shared by the light-emitting devices 130a and 130b. The organic compound layers 103a and 103b are independent of each other because these layers are processed by a photolithography method after the electron-injection layer 115a is formed and after the electron-injection layer 115b is formed. In the light-emitting device of one embodiment of the present invention, even though processing by a photolithography method is performed after the electron-injection layer 115a is formed and after the electron-injection layer 115b is formed, the light-emitting device can have favorable characteristics. Note that as illustrated in FIG. 5A, the electron-injection layers 115a and 115b may be one layer shared by the light-emitting devices 130a and 130b.

End portions (contours) of the organic compound layer 103a are processed by a photolithography method and thus are substantially aligned with each other in the direction perpendicular to the substrate. Furthermore, end portions (contours) of the organic compound layer 103b are processed by a photolithography method and thus are substantially aligned with each other in the direction perpendicular to the substrate.

A space d is present between the organic compound layer 103a and the organic compound layer 103b because of processing with a photolithography method. Since the organic compound layers are processed by a photolithography method, the distance between the first electrode 101a and the first electrode 101b can be made small, greater than or equal to 0.5 μm and less than or equal to 5 μm, compared with the case where mask vapor deposition is performed.

FIG. 4B illustrates two adjacent tandem light-emitting devices (a light-emitting device 130c and a light-emitting device 130d) manufactured by a photolithography method.

The light-emitting device 130c includes an organic compound layer 103c between a first electrode 101c over the insulating layer 175 and the second electrode 102. The organic compound layer 103c has a structure in which a first light-emitting unit 501c and a second light-emitting unit 502c are stacked with an intermediate layer 116c therebetween. Although FIG. 4B illustrates an example in which the two light-emitting units are stacked, three or more light-emitting units may be stacked. The first light-emitting unit 501c includes a hole-injection layer 111c, a first hole-transport layer 112c_1, a first light-emitting layer 113c_1, and a first electron-transport layer 114c_1. The intermediate layer 116c includes a p-type layer 117c, an electron-relay layer 118c, and an n-type layer 119c. The electron-relay layer 118c is not necessarily provided. The second light-emitting unit 502c includes a second hole-transport layer 112c_2, a second light-emitting layer 113c_2, a second electron-transport layer 114c_2, and an electron-injection layer 115c.

The light-emitting device 130d includes an organic compound layer 103d between a first electrode 101d over the insulating layer 175 and the second electrode 102. The organic compound layer 103d has a structure in which a first light-emitting unit 501d and a second light-emitting unit 502d are stacked with an intermediate layer 116d therebetween. Although FIG. 4B illustrates an example in which the two light-emitting units are stacked, three or more light-emitting units may be stacked. The first light-emitting unit 501d includes a hole-injection layer 111d, a first hole-transport layer 112d_1, a first light-emitting layer 113d_1, and a first electron-transport layer 114d_1. The intermediate layer 116d includes a p-type layer 117d, an electron-relay layer 118d, and an n-type layer 119d. The electron-relay layer 118d is not necessarily provided. The second light-emitting unit 502d includes a second hole-transport layer 112d_2, a second light-emitting layer 113d_2, a second electron-transport layer 114d_2, and an electron-injection layer 115d.

In the light-emitting devices 130c and 130d, the electron-injection layers 115c and 115d preferably have the structure as described in Embodiment 1.

Note that the second electrode 102 is preferably one layer shared by the light-emitting devices 130c and 130d. The organic compound layers 103c and 103d are independent of each other because processing by a photolithography method is performed after the electron-injection layer 115c is formed and after the electron-injection layer 115d is formed. In the light-emitting device of one embodiment of the present invention, even though processing by a photolithography method is performed after the electron-injection layer 115c is formed and after the electron-injection layer 115d is formed, the light-emitting device can have favorable characteristics. Note that as illustrated in FIG. 5B, the electron-injection layers 115c and 115d may be one layer shared by the light-emitting devices 130c and 130d.

End portions (contours) of the organic compound layer 103c are processed by a photolithography method and thus are substantially aligned with each other in the direction perpendicular to the substrate. Furthermore, end portions (contours) of the organic compound layer 103d are processed by a photolithography method and thus are substantially aligned with each other in the direction perpendicular to the substrate.

The space d is present between the organic compound layer 103c and the organic compound layer 103d because of processing with a photolithography method. Since the organic compound layers are processed by a photolithography method, the distance between the first electrode 101c and the first electrode 101d can be made small, greater than or equal to 0.5 μm and less than or equal to 5 μm, compared with the case where mask vapor deposition is performed.

In the light-emitting device of one embodiment of the present invention, since the organic compound layer is processed by a photolithography method, the organic compound layer can be processed with a sufficient accuracy to manufacture a high-resolution display device. Furthermore, since a lithography process can be performed on the electron-injection layer far from the light-emitting layer without contamination by an alkali metal, the light-emitting device can have favorable characteristics. As described above, the light-emitting device of one embodiment of the present invention having the above-described structure enables a high-resolution display device and can have favorable characteristics.

Since the organic compound layer in the light-emitting device of one embodiment of the present invention is processed at once with a photolithography method, all the layers included in the organic compound layer have substantially the same contour. Here, “substantially the same” in this specification means, supposing that the organic compound layer includes a layer A and a layer B, a difference between a contour A of the layer A and a contour B of the layer B is within 5% of the width of the organic compound layer along a line perpendicular to the compared portions of the contours. In the case where an end surface of the organic compound layer has a tapered shape, a continuous change of the contour is allowed.

The structure of this embodiment can be used in combination with any of the other structures as appropriate.

### Embodiment 3

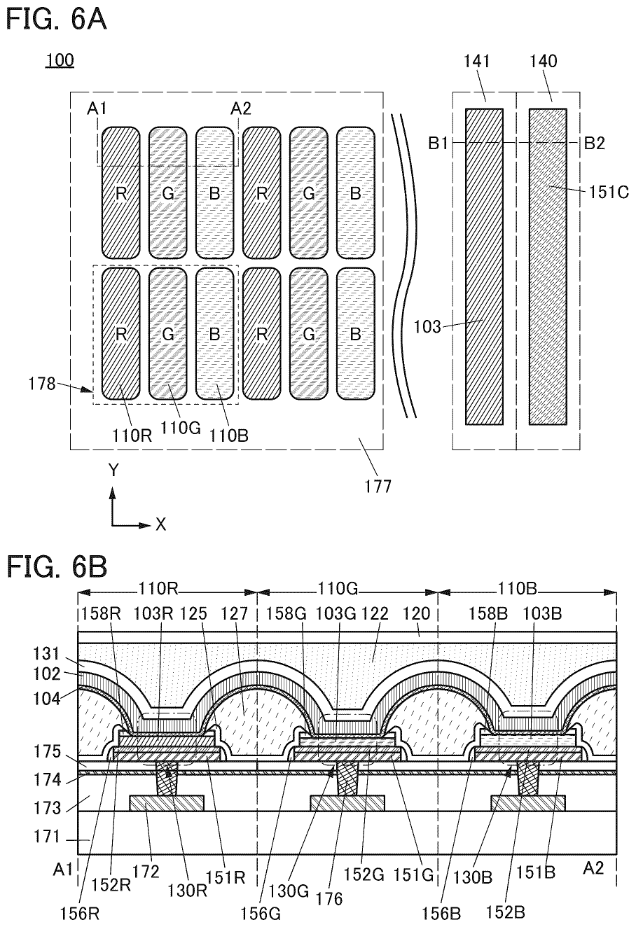

As illustrated in FIGS. 6A and 6B, a plurality of light-emitting devices 130 are formed over the insulating layer 175 to constitute a display device. In this embodiment, the display device of one embodiment of the present invention will be described in detail.

A display device 100 includes a pixel portion 177 in which a plurality of pixels 178 are arranged in matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared (IR) light.

In this specification and the like, the row direction and the column direction are sometimes referred to as the X direction and the Y direction, respectively. The X direction and the Y direction intersect with each other and, for example, intersect with each other at right angles.

FIG. 6A illustrates an example in which subpixels of different colors are arranged in the X direction and subpixels of the same color are arranged in the Y direction. Note that subpixels of different colors may be arranged in the Y direction, and subpixels of the same color may be arranged in the X direction.

A connection portion 140 and a region 141 may be provided outside the pixel portion 177, and the region 141 is provided between the pixel portion 177 and the connection portion 140. The organic compound layer 103 is provided in the region 141. A conductive layer 151C is provided in the connection portion 140.

Although FIG. 6A illustrates an example in which the region 141 and the connection portion 140 are located on the right side of the pixel portion 177, there is no particular limitation on the positions of the region 141 and the connection portion 140. The number of regions 141 and the number of connection portions 140 can each be one or more.

FIG. 6B is a cross-sectional view along the dashed-dotted line A1-A2 in FIG. 6A. As illustrated in FIG. 6B, the display device 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is attached to the protective layer 131 with a resin layer 122. An inorganic insulating layer 125 and an insulating layer 127 over the inorganic insulating layer 125 are preferably provided between the adjacent light-emitting devices 130.

Although a plurality of the inorganic insulating layers 125 and the insulating layers 127 are seen in the cross-sectional view in FIG. 6B, each of the inorganic insulating layer 125 and the insulating layer 127 is preferably one continuous layer when the display device 100 is seen from above. In other words, each of the inorganic insulating layer 125 and the insulating layer 127 preferably includes an opening portion over a first electrode.

In FIG. 6B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, 130G, or 130B may emit visible light of another color or infrared light.

The display device of one embodiment of the present invention can be, for example, a top-emission display device where light is emitted in the direction opposite to a substrate over which light-emitting devices are formed. Note that the display device of one embodiment of the present invention may be of a bottom-emission type.

Examples of a light-emitting substance included in the light-emitting device 130 include organic compounds or organometallic complexes such as a substance emitting fluorescent light (a fluorescent material), a substance emitting phosphorescent light (a phosphorescent material), and a substance exhibiting thermally activated delayed fluorescence (a thermally activated delayed fluorescent (TADF) material). Other examples include inorganic compounds such as a quantum dot material.

The light-emitting device 130R has a structure as described in Embodiment 1. The light-emitting device 130R includes the first electrode (pixel electrode) including a conductive layer 151R and a conductive layer 152R, an organic compound layer 103R over the first electrode, a common layer 104 over the organic compound layer 103R, and a second electrode (common electrode) 102 over the common layer 104. Although the common layer 104 is not necessarily provided, it is preferable to provide the common layer 104 to reduce damage to the organic compound layer 103R during processing. In the case where the common layer 104 is provided, the common layer 104 is preferably an electron-injection layer. Furthermore, in the case where the common layer 104 is provided, the stacked-layer structure of the organic compound layer 103R and the common layer 104 corresponds to the organic compound layer 103 described in Embodiment 2.

The light-emitting device 130G has a structure as described in Embodiment 1. The light-emitting device 130G includes the first electrode (pixel electrode) including a conductive layer 151G and a conductive layer 152G, an organic compound layer 103G over the first electrode, the common layer 104 over the organic compound layer 103G, and the second electrode (common electrode) 102 over the common layer 104. Although the common layer 104 is not necessarily provided, it is preferable to provide the common layer 104 to reduce damage to the organic compound layer 103G during processing. In the case where the common layer 104 is provided, the common layer 104 is preferably an electron-injection layer. Furthermore, in the case where the common layer 104 is provided, the stacked-layer structure of the organic compound layer 103G and the common layer 104 corresponds to the organic compound layer 103 described in Embodiment 2.

The light-emitting device 130B has a structure as described in Embodiment 1. The light-emitting device 130B includes the first electrode (pixel electrode) including a conductive layer 151B and a conductive layer 152B, an organic compound layer 103B over the first electrode, the common layer 104 over the organic compound layer 103B, and the second electrode (common electrode) 102 over the common layer 104. Although the common layer 104 is not necessarily provided, it is preferable to provide the common layer 104 to reduce damage to the organic compound layer 103B during processing. In the case where the common layer 104 is provided, the common layer 104 is preferably an electron-injection layer. Furthermore, in the case where the common layer 104 is provided, the stacked-layer structure of the organic compound layer 103B and the common layer 104 corresponds to the organic compound layer 103 described in Embodiment 2.

In the light-emitting device, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layers 103R, the organic compound layers 103G, and the organic compound layers 103B are island-shaped layers that are independent of each other on a light-emitting device basis or on an emission color basis. Providing the island-shaped organic compound layer 103 in each of the light-emitting devices 130 can inhibit leakage current between the adjacent light-emitting devices 130 even in a high-resolution display device. This can prevent crosstalk, so that a display device with extremely high contrast can be obtained. Specifically, a display device having high current efficiency at low luminance can be obtained.

The island-shaped organic compound layer 103 is formed by forming an EL film and processing the EL film by a lithography method.

In the display device of one embodiment of the present invention, the first electrode (pixel electrode) of the light-emitting device preferably has a stacked-layer structure. For example, in the example illustrated in FIG. 6B, the first electrode of the light-emitting device 130 has a stacked-layer structure of the conductive layer 151 and the conductive layer 152. In the case where the display device 100 is of a top-emission type and the pixel electrode of the light-emitting device 130 functions as the anode, for example, the conductive layer 151 preferably has high visible light reflectance, and the conductive layer 152 preferably has a visible-light-transmitting property and a high work function. In the case where the display device 100 is of a top-emission type, the higher the visible light reflectance of the pixel electrode is, the higher the efficiency of extraction of the light emitted by the organic compound layer 103 is. In the case where the pixel electrode functions as the anode, the higher the work function of the pixel electrode is, the easier hole injection into the organic compound layer 103 is. Accordingly, when the pixel electrode of the light-emitting device 130 has a stacked-layer structure of the conductive layer 151 with high visible light reflectance and the conductive layer 152 with a high work function, the light-emitting device 130 can have high light extraction efficiency and a low driving voltage.

In the case where the conductive layer 151 has high visible light reflectance, the visible light reflectance of the conductive layer 151 is higher than or equal to 40% and lower than or equal to 100%, preferably higher than or equal to 70% and lower than or equal to 100%, for example. When used as an electrode having a visible-light-transmitting property, the conductive layer 152 preferably has a visible light transmittance higher than or equal to 40%, for example.

Here, such a pixel electrode being a stack composed of a plurality of layers sometimes changes in quality as a result of, for example, a reaction between the plurality of layers. For example, when a film formed after the formation of the pixel electrode is removed by a wet etching method, contact of a chemical solution with the pixel electrode might cause galvanic corrosion.

Thus, in the display device 100 of this embodiment, the insulating layer 156 is formed on the side surfaces of the conductive layers 151 and 152. This can inhibit a chemical solution from coming into contact with the conductive layer 151 even when a film that is formed after formation of the pixel electrode including the conductive layer 151 and the conductive layer 152 is removed by a wet etching method, for example. Accordingly, occurrence of galvanic corrosion in the pixel electrode can be inhibited, for example. This allows the display device 100 to be manufactured by a high-yield method and to be accordingly inexpensive. In addition, generation of a defect in the display device 100 can be inhibited, which makes the display device 100 highly reliable.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layers 151 and 152 may each have a stacked-layer structure of a plurality of layers that include different materials. In this case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 has a stacked-layer structure of two or more layers, for example, a layer in contact with the conductive layer 152 can be formed using a material that can be used for the conductive layer 152.

Note that the end portion of the insulating layer 156 may have a tapered shape. Specifically, when the end portion of the insulating layer 156 has a tapered shape with a taper angle less than 90°, a component with higher coverage can be provided along the side surface of the insulating layer 156.

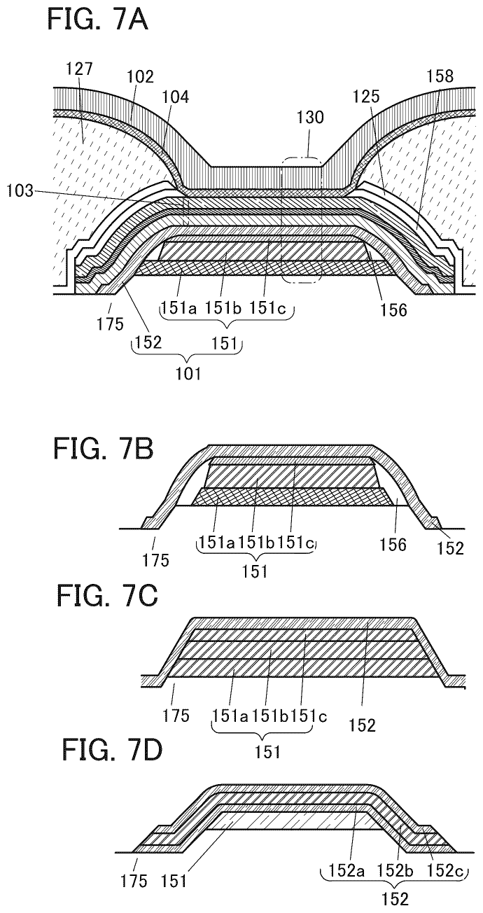

FIG. 7A illustrates the cases where the conductive layer 151 has a stacked-layer structure of a plurality of layers that include different materials. As illustrated in FIG. 7A, the conductive layer 151 includes a conductive layer 151a, a conductive layer 151b over the conductive layer 151a, and a conductive layer 151c over the conductive layer 151b. In other words, the conductive layer 151 illustrated in FIG. 7A has a three-layer-stacked structure. In the case where the conductive layer 151 has a stacked-layer structure of a plurality of layers as described above, the visible light reflectance of at least one of the layers included in the conductive layer 151 is made higher than that of the conductive layer 152.

In the example illustrated in FIG. 7A, the conductive layer 151b is sandwiched between the conductive layers 151a and 151c. A material that is less likely to change in quality than the material for the conductive layer 151b is preferably used for the conductive layers 151a and 151c. The conductive layer 151a can be formed using, for example, a material that is less likely to migrate owing to contact with the insulating layer 175 than the material for the conductive layer 151b. The conductive layer 151c can be formed using a material an oxide of which has lower electrical resistivity than an oxide of the material for the conductive layer 151b and which is less likely to be oxidized than the material for the conductive layer 151b.

In this manner, the structure where the conductive layer 151b is sandwiched between the conductive layers 151a and 151c can expand the range of choices for the material for the conductive layer 151b. The conductive layer 151b, for example, can thus have higher visible light reflectance than at least one of the conductive layers 151a and 151c. For example, aluminum can be used for the conductive layer 151b. The conductive layer 151b may be formed using an alloy containing aluminum. The conductive layer 151a can be formed using titanium; titanium has lower visible light reflectance than aluminum but is less likely to migrate owing to contact with the insulating layer 175 than aluminum. Furthermore, the conductive layer 151c can be formed using titanium; titanium is less likely to be oxidized than aluminum and an oxide of titanium has lower electrical resistivity than aluminum oxide, although titanium has lower visible light reflectance than aluminum.

The conductive layer 151c may be formed using silver or an alloy containing silver. Silver has a feature of higher visible light reflectance than titanium. In addition, silver has a feature of being less likely to be oxidized than aluminum, and silver oxide has a feature of lower electrical resistivity than aluminum oxide. Thus, the conductive layer 151c formed using silver or an alloy containing silver can favorably increase the visible light reflectance of the conductive layer 151 and inhibit an increase in the electrical resistance of the pixel electrode due to oxidation of the conductive layer 151b. Here, as the alloy containing silver, an alloy of silver, palladium, and copper (also referred to as Ag—Pd—Cu or APC) can be used, for example. When the conductive layer 151c is formed using silver or an alloy containing silver and the conductive layer 151b is formed using aluminum, the visible light reflectance of the conductive layer 151c can be higher than that of the conductive layer 151b. Here, the conductive layer 151b may be formed using silver or an alloy containing silver. The conductive layer 151a may be formed using silver or an alloy containing silver.

Meanwhile, a film formed using titanium has better processability in etching than a film formed using silver. Thus, use of titanium for the conductive layer 151c can facilitate formation of the conductive layer 151c. Note that a film formed using aluminum also has better processability in etching than a film formed using silver.

The conductive layer 151 having a stacked-layer structure of a plurality of layers as described above can improve the characteristics of the display device. For example, the display device 100 can have high light extraction efficiency and high reliability.

In the case where the light-emitting device 130 has a microcavity structure, use of silver or an alloy containing silver, i.e., a material with high visible light reflectance, for the conductive layer 151c can favorably increase the light extraction efficiency of the display device 100.

As described above, the conductive layer 151 preferably has a side surface with a tapered shape. Specifically, the side surface of the conductive layer 151 preferably has a tapered shape with a taper angle less than 90°. For example, in the conductive layer 151 illustrated in FIG. 7A, the side surface of at least one of the conductive layers 151a, 151b, and 151c preferably has a tapered shape.

The conductive layer 151 illustrated in FIG. 7A can be formed by a lithography method. Specifically, first, a conductive film to be the conductive layer 151a, a conductive film to be the conductive layer 151b, and a conductive film to be the conductive layer 151c are sequentially formed. Next, a resist mask is formed over the conductive film to be the conductive layer 151c. Then, the conductive film in the region not overlapping with the resist mask is removed by etching, for example. Here, the side surface of the conductive layer 151 can have a tapered shape by processing the conductive film under conditions where the resist mask is easily recessed (reduced in size) as compared to the case where the conductive layer 151 is formed such that the side surface does not have a tapered shape, i.e., the conductive layer 151 is formed to have a perpendicular side surface.

Here, when the conductive film is processed under conditions where the resist mask is easily recessed (reduced in size), the conductive film may be easily processed in the horizontal direction. That is, the etching may become isotropic as compared to the case where the conductive layer 151 is formed to have a perpendicular side surface.

In the case where the conductive layer 151 has a stacked-layer structure of a plurality of layers formed of different materials, the plurality of layers sometimes differ in processability in the horizontal direction. For example, the conductive layers 151a, 151b, and 151c sometimes differ in processability in the horizontal direction.

In that case, after the processing of the conductive film, as illustrated in FIG. 7A, the side surface of the conductive layer 151b may be positioned inward from the side surfaces of the conductive layers 151a and 151c and a protruding portion may be formed. This may impair coverage of the conductive layer 151 with the conductive layer 152 and cause step disconnection of the conductive layer 152.

In view of this, an insulating layer 156 is preferably provided as illustrated in FIG. 7A. FIG. 7A illustrates an example in which the insulating layer 156 is provided over the conductive layer 151a to have a region overlapping with the side surface of the conductive layer 151b. In this structure, occurrence of step disconnection or thinning of the conductive layer 152 due to the protruding portion can be inhibited, so that poor connection or an increase in driving voltage can be inhibited.

Although FIG. 7A illustrates the structure where the side surface of the conductive layer 151b is entirely covered with the insulating layer 156, part of the side surface of the conductive layer 151b is not necessarily covered with the insulating layer 156. Also in a pixel electrode with a later-described structure, part of the side surface of the conductive layer 151b is not necessarily covered with the insulating layer 156.

In the case where the conductive layer 151 has the structure illustrated in FIG. 7A, the conductive layer 152 is provided to cover the conductive layers 151a, 151b, and 151c and the insulating layer 156 and to be electrically connected to the conductive layers 151a, 151b, and 151c. This can prevent a chemical solution from coming into contact with the conductive layers 151a, 151b, and 151c even when a film formed after formation of the conductive layer 152 is removed by a wet etching method, for example. It is thus possible to inhibit occurrence of corrosion in all of the conductive layers 151a, 151b, and 151c. Hence, the display device 100 can be fabricated by a high-yield method. Moreover, the display device 100 can have high reliability since generation of defects is inhibited therein.

Here, the insulating layer 156 preferably has a curved surface as illustrated in FIG. 7A. In that case, step disconnection in the conductive layer 152 covering the insulating layer 156 is less likely to occur than in the case where the insulating layer 156 has a perpendicular side surface (a side surface parallel to the Z direction), for example. In addition, step disconnection in the conductive layer 152 covering the insulating layer 156 is less likely to occur also in the case where the side surface of the insulating layer 156 has a tapered shape, or specifically, a tapered shape with a taper angle less than 90°, than in the case where the insulating layer 156 has a perpendicular side surface, for example. As described above, the display device 100 can be fabricated by a high-yield method. Moreover, the display device 100 can have high reliability since generation of defects is inhibited therein.

FIG. 7A illustrates the structure where the side surface of the conductive layer 151b is located inward from those of the conductive layers 151a and 151c; however, one embodiment of the present invention is not limited to this structure. For example, the side surface of the conductive layer 151b may be located outward from that of the conductive layer 151a. The side surface of the conductive layer 151b may be located outward from that of the conductive layer 151c.

FIGS. 7B to 7D illustrate other structures of the first electrode 101. FIG. 7B illustrates another structure example of the first electrode 101 in FIG. 7A, in which the insulating layer 156 covers not only the side surface of the conductive layer 151b but also the side surfaces of the conductive layers 151a, 151b, and 151c.

FIG. 7C illustrates another structure example of the first electrode 101 in FIG. 7A, in which the insulating layer 156 is not provided.

FIG. 7D illustrates another structure example of the first electrode 101 in FIG. 7A, in which the conductive layer 151 does not have a stacked-layer structure but the conductive layer 152 has a stacked-layer structure.

A conductive layer 152a has higher adhesion to a conductive layer 152b than the insulating layer 175 does, for example. For the conductive layer 152a, an oxide containing one or more selected from indium, tin, zinc, gallium, titanium, aluminum, and silicon, for example, can be used. For example, it is preferable to use a conductive oxide containing one or more of indium oxide, indium tin oxide, indium zinc oxide, zinc oxide, zinc oxide containing gallium, titanium oxide, indium titanium oxide, zinc titanate, aluminum zinc oxide, indium zinc oxide containing gallium, indium zinc oxide containing aluminum, indium tin oxide containing silicon, indium zinc oxide containing silicon, and the like. Accordingly, peeling of the conductive layer 152b can be inhibited. The conductive layer 152b is not in contact with the insulating layer 175.

The conductive layer 152b is a layer whose visible light reflectance (e.g., reflectance with respect to light with a predetermined wavelength longer than or equal to 400 nm and shorter than 750 nm) is higher than those of the conductive layers 151, 152a, and 152c. The visible light reflectance of the conductive layer 152b can be, for example, higher than or equal to 70% and lower than or equal to 100%, and is preferably higher than or equal to 80% and lower than or equal to 100%, further preferably higher than or equal to 90% and lower than or equal to 100%. For the conductive layer 152b, a material having higher visible light reflectance than aluminum can be used, for example. Specifically, for the conductive layer 152b, silver or an alloy containing silver can be used, for example. An example of the alloy containing silver is an alloy of silver, palladium, and copper (APC). In the above manner, the display device 100 can have high light extraction efficiency. Note that a metal other than silver may be used for the conductive layer 152b.

When the conductive layers 151 and 152 serve as the anode, a layer having a high work function is preferably used as the conductive layer 152c. The conductive layer 152c has a higher work function than the conductive layer 152b, for example. For the conductive layer 152c, a material similar to the material usable for the conductive layer 152a can be used, for example. For example, the conductive layers 152a and 152c can be formed using the same kind of material. For example, in the case where indium tin oxide is used for the conductive layer 152a, indium tin oxide can also be used for the conductive layer 152c.

When the conductive layers 151 and 152 serve as the cathode, the conductive layer 152c is preferably a layer having a low work function. For example, the conductive layer 152c has a lower work function than the conductive layer 152b.

The conductive layer 152c is preferably a layer having high visible light transmittance (e.g., transmittance with respect to light with a predetermined wavelength longer than or equal to 400 nm and shorter than 750 nm). For example, the visible light transmittance of the conductive layer 152c is preferably higher than those of the conductive layers 151 and 152b. The visible light transmittance of the conductive layer 152c can be, for example, higher than or equal to 60% and lower than or equal to 100%, and is preferably higher than or equal to 70% and lower than or equal to 100%, further preferably higher than or equal to 80% and lower than or equal to 100%. In that case, the amount of light that is absorbed by the conductive layer 152c after being emitted from the organic compound layer 103 can be reduced. As described above, the conductive layer 152b under the conductive layer 152c can be a layer having high visible light reflectance. Thus, the display device 100 can have high light extraction efficiency.

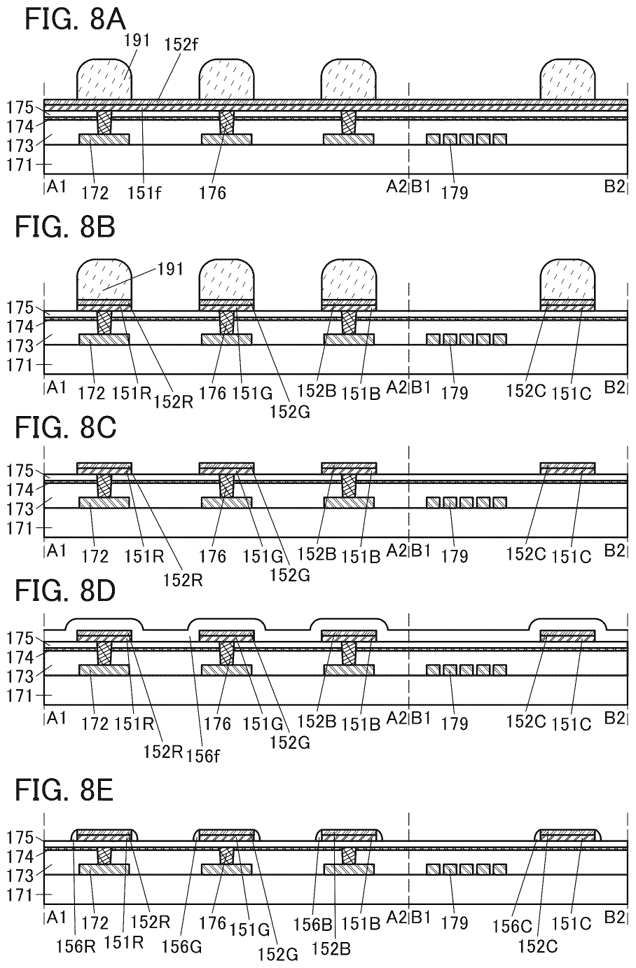

Next, a method for manufacturing the display device 100 having the structure illustrated in FIG. 6A is described with reference to FIGS. 8A to 8E, FIGS. 9A and 9B, FIGS. 10A to 10D, FIGS. 11A to 11C, FIGS. 12A to 12C, and FIGS. 13A to 13C. The organic layer of the light-emitting device included in the display device 100 is formed by a manufacturing process including treatment using water. The use of the organic compound of one embodiment of the present invention for the organic layer of the light-emitting device included in the display device of one embodiment of the present invention prevents problems such as dissolution of a layer including the organic compound and permeation of a chemical solution into a layer including the organic layer even in the process by a manufacturing method including treatment using water; consequently, the light-emitting device can have favorable characteristics.

### Manufacturing Method Example

Thin films included in the display device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a plasma-enhanced CVD (PECVD) method and a thermal CVD method. An example of a thermal CVD method is a metal organic CVD (MOCVD) method.

Thin films included in the display device (e.g., insulating films, semiconductor films, and conductive films) can also be formed by a wet film-formation method such as spin coating, dipping, spray coating, ink-jetting, dispensing, screen printing, offset printing, doctor blade coating, slit coating, roll coating, curtain coating, or knife coating.

Specifically, for fabrication of the light-emitting device, a vacuum process such as an evaporation method and a solution process such as a spin coating method or an ink-jet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, the functional layers (e.g., the hole-injection layer, the hole-transport layer, the hole-blocking layer, the light-emitting layer, the electron-blocking layer, the electron-transport layer, and the electron-injection layer) included in the organic compound layer can be formed by an evaporation method (e.g., a vacuum evaporation method), a coating method (e.g., a dip coating method, a die coating method, a bar coating method, a spin coating method, or a spray coating method), a printing method (e.g., ink-jetting, screen printing (stencil), offset printing (planography), flexography (relief printing), gravure printing, or micro-contact printing), or the like.

Thin films included in the display device can be processed by a lithography method, for example. Alternatively, a nanoimprinting method, a sandblasting method, a lift-off method, or the like maybe used to process thin films. Alternatively, island-shaped thin films maybe directly formed by a film formation method using a shielding mask such as a metal mask.

As a lithography method, for example, a photolithography method can be used. Two typical examples of photolithography methods are given. In one of the methods, a resist mask is formed over a thin film that is to be processed, the thin film is processed by etching, for example, and then the resist mask is removed. In the other method, a photosensitive thin film is formed and then processed into a desired shape by light exposure and development.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used. It is preferable to use EUV light, X-rays, or an electron beam for extremely minute processing. Note that when exposure is performed by scanning of a beam such as an electron beam, a photomask is not needed.

For etching of thin films, a dry etching method, a wet etching method, a sandblasting method, or the like can be used.

First, as illustrated in FIG. 8A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate having heat resistance high enough to withstand at least heat treatment performed later can be used. When an insulating substrate is used, it is possible to use a glass substrate, a quartz substrate, a sapphire substrate, a ceramic substrate, an organic resin substrate, or the like. Alternatively, it is possible to use a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 8A, openings reaching the conductive layer 172 are formed in the insulating layers 175, 174, and 173. Then, the plugs 176 are formed to fill the openings.

Next, as illustrated in FIG. 8A, a conductive film 151f to be the conductive layers 151R, 151G, 151B, and 151C is formed over the plugs 176 and the insulating layer 175. The conductive film 151f can be formed by a sputtering method or a vacuum evaporation method, for example. A metal material can be used for the conductive film 151f, for example.

Next, as illustrated in FIG. 8A, a conductive film 152f to be the conductive layers 152R, 152G, 152B, and 152C is formed over the conductive film 151f. The conductive film 152f can be formed by a sputtering method or a vacuum evaporation method, for example. A conductive oxide can be used for the conductive film 152f, for example. The conductive film 152f can have a stacked-layer structure of a film formed using a metal material and a film formed thereover using a conductive oxide. For example, the conductive film 152f can have a stacked-layer structure of a film formed using titanium, silver, or an alloy containing silver and a film formed thereover using a conductive oxide.

The conductive film 152f can be formed by an ALD method. In this case, for the conductive film 152f, an oxide containing one or more selected from indium, tin, zinc, gallium, titanium, aluminum, and silicon can be used. In this case, the conductive film 152f can be formed by repeating a cycle of introduction of a precursor (generally referred to as a metal precursor or the like in some cases), purge of the precursor, introduction of an oxidizer (generally referred to as a reactant, a non-metal precursor, or the like in some cases), and purge of the oxidizer. Here, in the case where an oxide film including a plurality of kinds of metals (e.g., an indium tin oxide film) is formed as the conductive film 152f, the composition of the metals can be controlled by varying the number of cycles for different kinds of precursors.

For example, in the case where an indium tin oxide film is formed as the conductive film 152f, after a precursor containing indium is introduced, the precursor is purged, and an oxidizer is introduced to form an In—O film, and then a precursor containing tin is introduced, the precursor is purged, and an oxidizer is introduced to form a Sn—O film. Here, when the number of cycles of forming an In—O film is larger than the number of cycles of forming a Sn—O film, the number of In atoms included in the conductive film 152f can be larger than the number of Sn atoms included therein.

For example, to form a zinc oxide film as the conductive film 152f, a Zn—O film is formed in the above procedure. For another example, to form an aluminum zinc oxide film as the conductive film 152f, a Zn—O film and an Al—O film are formed in the above procedure. For another example, to form a titanium oxide film as the conductive film 152f, a Ti—O film is formed in the above procedure. For another example, to form an indium tin oxide film including silicon as the conductive film 152f, an In—O film, a Sn—O film, and a Si—O film are formed in the above procedure. For another example, to form a zinc oxide film including gallium, a Ga—O film and a Zn—O film are formed in the above procedure.

As a precursor containing indium, it is possible to use, for example, triethylindium, trimethylindium, or [1,1,1-trimethyl-N-(trimethylsilyl)amide]-indium. As a precursor containing tin, it is possible to use, for example, tin chloride or tetrakis(dimethylamido)tin. As a precursor containing zinc, it is possible to use, for example, diethylzinc or dimethylzinc. As a precursor containing gallium, it is possible to use, for example, triethylgallium. As a precursor containing titanium, it is possible to use, for example, titanium chloride, tetrakis(dimethylamido)titanium, or tetraisopropyl titanate. As a precursor containing aluminum, it is possible to use, for example, aluminum chloride or trimethylaluminum. As a precursor containing silicon, it is possible to use, for example, trisilylamine, bis(diethylamino)silane, tris(dimethylamino)silane, bis(tert-butylamino)silane, or bis(ethylmethylamino)silane. As the oxidizer, water vapor, oxygen plasma, or an ozone gas can be used.

Subsequently, a resist mask 191 is formed over the conductive films 151f and 152f as illustrated in FIG. 8A. The resist mask 191 can be formed by application of a photosensitive material (photoresist), light exposure, and development.

Subsequently, as illustrated in FIG. 8B, the conductive films 151f and 152f in a region not overlapping with the resist mask 191 are removed by an etching method, specifically, a dry etching method, for example, so that a pixel electrode including the conductive layers 151 and 152 is formed. Note that in the case where the conductive film 151f includes a layer formed using a conductive oxide such as indium tin oxide, for example, the layer may be removed by a wet etching method. In this manner, the conductive layers 151 and 152 are formed. In the case where part of the conductive film 151f is removed by a dry etching method, for example, a recessed portion may be formed in a region of the insulating layer 175 not overlapping with the conductive layer 151.

Note that the conductive film 152f may be processed by a lithography method to form the conductive layers 152R, 152G, 152B, and 152C, and then the conductive film 151f may be processed using the conductive layers 152R, 152G, 152B, and 152C as masks. Specifically, after a resist mask is formed, part of the conductive film 152f is removed by an etching method, for example. The conductive film 152f can be removed by a wet etching method, for example. The conductive film 152f may be removed by a dry etching method. After that, the conductive film 151f is preferably removed by a wet etching method.

Here, hydrophobization treatment is preferably performed on the conductive layer 152. The hydrophobization treatment can change the hydrophilic properties of the subject surface to hydrophobic properties or increase the hydrophobic properties of the subject surface. The hydrophobization treatment for the conductive layer 152 can increase the adhesion between the conductive layer 152 and the organic compound layer 103 formed in a later step and inhibit film peeling. Note that the hydrophobization treatment is not necessarily performed.

Next, the resist mask 191 is removed as illustrated in FIG. 8C. The resist mask 191 can be removed by ashing using oxygen plasma, for example. Alternatively, an oxygen gas and any of CF₄, C₄F₈, SF₆, CHF₃, Cl₂, H₂O, BCl₃, and a Group 18 element such as He may be used. Alternatively, the resist mask 191 may be removed by wet etching.

Then, as illustrated in FIG. 8D, an insulating film 156f to be insulating layers 156R, 156G, 156B, and 156C is formed over the conductive layers 151R and 152R, the conductive layers 151G and 152G, the conductive layers 151B and 152B, the conductive layers 151C and 152C, and the insulating layer 175. The insulating film 156f can be formed by a CVD method, an ALD method, a sputtering method, or a vacuum evaporation method, for example.

For the insulating film 156f, an inorganic material can be used. As the insulating film 156f, an inorganic insulating film such as an oxide insulating film, a nitride insulating film, an oxynitride insulating film, or a nitride oxide insulating film can be used, for example. For example, an oxide insulating film including silicon, a nitride insulating film including silicon, an oxynitride insulating film including silicon, a nitride oxide insulating film including silicon, or the like can be used as the insulating film 156f. For the insulating film 156f, silicon oxynitride can be used, for example.

Subsequently, as illustrated in FIG. 8E, the insulating film 156f is processed to form the insulating layers 156R, 156G, 156B, and 156C. The insulating layer 156 can be formed by performing etching substantially uniformly on the top surface of the insulating film 156f, for example. Such uniform etching for planarization is also referred to as etch back treatment. Note that the insulating layer 156 may be formed by a lithography method.

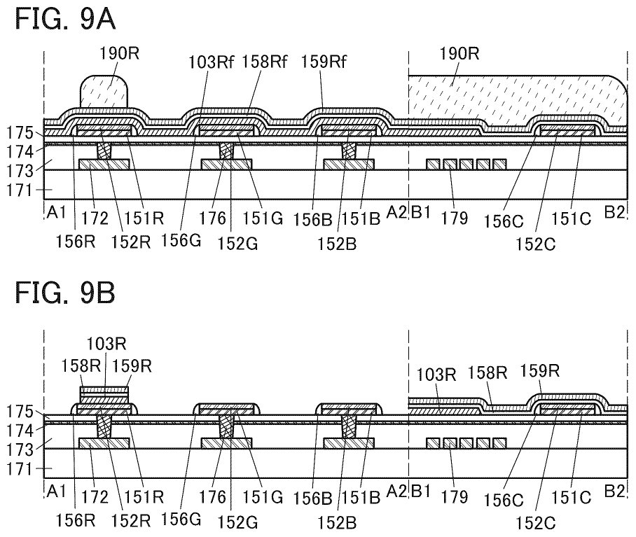

Next, as illustrated in FIG. 9A, an organic compound film 103Rf to be the organic compound layer 103R is formed over the conductive layers 152R, 152G, and 152B, the insulating layers 156R, 156G, and 156B, and the insulating layer 175.

As illustrated in FIG. 9A, the organic compound film 103Rf is not formed over the conductive layer 152C. For example, a mask for defining a film formation area (also referred to as an area mask, a rough metal mask, or the like to be distinguished from a fine metal mask) is used, so that the organic compound film 103Rf can be formed only in a desired region. Employing a film formation step using an area mask and a processing step using a resist mask enables a light-emitting device to be fabricated by a relatively easy process.

The organic compound film 103Rf can be formed by an evaporation method, specifically a vacuum evaporation method, for example. The organic compound film 103Rf may be formed by a transfer method, a printing method, an ink-jet method, a coating method, or the like.

Next, as illustrated in FIG. 9A, a sacrificial film 158Rf to be a sacrificial layer 158R and a mask film 159Rf to be a mask layer 159R are sequentially formed over the organic compound film 103Rf, the conductive layer 152C, and the insulating layer 175.

Although this embodiment shows an example in which a mask film having a two-layer structure of the sacrificial film 158Rf and the mask film 159Rf is formed, the mask film may have a single-layer structure or a stacked-layer structure of three or more layers.

Providing the sacrificial layer over the organic compound film 103Rf can reduce damage to the organic compound film 103Rf in the manufacturing process of the display device, resulting in an increase in reliability of the light-emitting device.

As the sacrificial film 158Rf, a film that is highly resistant to the process conditions for the organic compound film 103Rf, specifically, a film having high etching selectivity with respect to the organic compound film 103Rf is used. For the mask film 159Rf, a film having high etching selectivity with respect to the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each lower than or equal to 200° C., preferably lower than or equal to 150° C., further preferably lower than or equal to 120° C., still further preferably lower than or equal to 100° C., and yet still further preferably lower than or equal to 80° C.

The sacrificial film 158Rf and the mask film 159Rf are preferably films that can be removed by a wet etching method. The use of a wet etching method can reduce damage to the organic compound film 103Rf in processing of the sacrificial film 158Rf and the mask film 159Rf, as compared to the case of using a dry etching method.

The sacrificial film 158Rf and the mask film 159Rf can be formed by a sputtering method, an ALD method (including a thermal ALD method and a PEALD method), a CVD method, or a vacuum evaporation method, for example. Alternatively, the sacrificial film 158Rf and the mask film 159Rf may be formed by the above-described wet film-formation method.

Note that the sacrificial film 158Rf that is formed over and in contact with the organic compound film 103Rf is preferably formed by a formation method that is less likely to damage the organic compound film 103Rf than a formation method of the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, and an inorganic insulating film, for example, can be used.

For each of the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. A metal material that can block ultraviolet rays is preferably used for one or both of the sacrificial film 158Rf and the mask film 159Rf, in which case the organic compound film 103Rf can be inhibited from being irradiated with ultraviolet rays and deteriorating.

The sacrificial film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In place of gallium described above, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

As each of the sacrificial film and the mask film, a film including a material having a light-blocking property, particularly with respect to ultraviolet rays, is preferably used. Although a variety of materials such as a metal, an insulator, a semiconductor, and a metalloid that have a property of blocking ultraviolet rays can be used as a light-blocking material, each of the sacrificial film and the mask film is preferably a film capable of being processed by etching and is particularly preferably a film having good processability because part or the whole of each of the sacrificial film and the mask film is removed in a later step.

The sacrificial film and the mask film are preferably formed using a semiconductor material such as silicon or germanium, for example, for excellent compatibility with a semiconductor manufacturing process. Alternatively, an oxide or a nitride of the semiconductor material can be used. A non-metallic material such as carbon or a compound thereof can be used. A metal such as titanium, tantalum, tungsten, chromium, or aluminum or an alloy containing at least one of these metals can be used. Alternatively, an oxide containing the above-described metal, such as titanium oxide or chromium oxide, or a nitride such as titanium nitride, chromium nitride, or tantalum nitride can be used.

When a film including a material having a property of blocking ultraviolet rays is used as each of the sacrificial film and the mask film, the organic compound layer can be inhibited from being irradiated with ultraviolet rays in a light exposure step, for example. The organic compound layer is inhibited from being damaged by ultraviolet rays, so that the reliability of the light-emitting device can be improved.

Note that the same effect is obtained when a film including a material having a property of blocking ultraviolet rays is used for an after-mentioned inorganic insulating film 125f.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film. For example, an inorganic insulating material such as aluminum oxide, hafnium oxide, or silicon oxide can be used for the sacrificial film 158Rf and the mask film 159Rf. As the sacrificial film 158Rf and the mask film 159Rf, aluminum oxide films can be formed by an ALD method, for example. An ALD method is preferably used, in which case damage to a base (in particular, the organic compound layer) can be reduced.

For example, an inorganic insulating film (e.g., an aluminum oxide film) formed by an ALD method can be used as the sacrificial film 158Rf, and an inorganic film (e.g., an In—Ga—Zn oxide film, an aluminum film, or a tungsten film) formed by a sputtering method can be used as the mask film 159Rf.

Note that the same inorganic insulating film can be used for both the sacrificial film 158Rf and the inorganic insulating layer 125 that is to be formed later. For example, an aluminum oxide film formed by an ALD method can be used for both the sacrificial film 158Rf and the inorganic insulating layer 125. For the sacrificial film 158Rf and the inorganic insulating layer 125, the same film formation conditions may be used or different film formation conditions may be used. For example, when the sacrificial film 158Rf is formed under conditions similar to those of the inorganic insulating layer 125, the sacrificial film 158Rf can be an insulating layer having a high barrier property against at least one of water and oxygen. Meanwhile, since the sacrificial film 158Rf is a layer a large part or the whole of which is to be removed in a later step, it is preferable that the processing of the sacrificial film 158Rf be easy. Therefore, the sacrificial film 158Rf is preferably formed with a substrate temperature lower than that for formation of the inorganic insulating layer 125.

One or both of the sacrificial film 158Rf and the mask film 159Rf may be formed using an organic material. For example, as the organic material, a material that can be dissolved in a solvent chemically stable with respect to at least the uppermost film of the organic compound film 103Rf may be used. Specifically, a material that will be dissolved in water or an alcohol can be suitably used. In forming a film of such a material, it is preferable to apply the material dissolved in a solvent such as water or an alcohol by a wet film-formation method and then perform heat treatment for evaporating the solvent. At this time, the heat treatment is preferably performed in a reduced-pressure atmosphere, in which case the solvent can be removed at a low temperature in a short time and thermal damage to the organic compound film 103Rf can be reduced accordingly.

The sacrificial film 158Rf and the mask film 159Rf may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluorine resin like perfluoropolymer.

For example, an organic film (e.g., a PVA film) formed by an evaporation method or any of the above wet film-formation methods can be used as the sacrificial film 158Rf, and an inorganic film (e.g., a silicon nitride film) formed by a sputtering method can be used as the mask film 159Rf.

Subsequently, a resist mask 190R is formed over the mask film 159Rf as illustrated in FIG. 9A. The resist mask 190R can be formed by application of a photosensitive material (photoresist), light exposure, and development.

The resist mask 190R may be formed using either a positive resist material or a negative resist material.

The resist mask 190R is provided at a position overlapping with the conductive layer 152R. The resist mask 190R is preferably provided also at a position overlapping with the conductive layer 152C. This can inhibit the conductive layer 152C from being damaged during the process of manufacturing the display device. Note that the resist mask 190R is not necessarily provided over the conductive layer 152C. The resist mask 190R is preferably provided to cover the area from an end portion of the organic compound film 103Rf to an end portion of the conductive layer 152C (the end portion closer to the organic compound film 103Rf), as illustrated in the cross-sectional view along the line B1-B2 in FIG. 9A.

Next, as illustrated in FIG. 9B, part of the mask film 159Rf is removed using the resist mask 190R, so that the mask layer 159R is formed. The mask layer 159R remains over the conductive layers 152R and 152C. After that, the resist mask 190R is removed. Then, part of the sacrificial film 158Rf is removed using the mask layer 159R as a mask (also referred to as a hard mask), so that the sacrificial layer 158R is formed.

Each of the sacrificial film 158Rf and the mask film 159Rf can be processed by a wet etching method or a dry etching method. The sacrificial film 158Rf and the mask film 159Rf are preferably processed by isotropic etching.

The use of a wet etching method can reduce damage to the organic compound film 103Rf in processing of the sacrificial film 158Rf and the mask film 159Rf, as compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a chemical solution containing a mixed solution of any of these acids, for example.

Since the organic compound film 103Rf is not exposed in the processing of the mask film 159Rf, the range of choice for a processing method for the mask film 159Rf is wider than that for the sacrificial film 158Rf. Specifically, even in the case where a gas containing oxygen is used as the etching gas in the processing of the mask film 159Rf, deterioration of the organic compound film 103Rf can be inhibited.

In the case of using a dry etching method to process the sacrificial film 158Rf, deterioration of the organic compound film 103Rf can be inhibited by not using a gas containing oxygen as the etching gas. In the case of using a dry etching method, it is preferable to use a gas containing CF₄, C₄F₈, SF₆, CHF₃, Cl₂, H₂O, BCl₃, or a Group 18 element such as He, for example, as the etching gas.

For example, in the case where an aluminum oxide film formed by an ALD method is used as the sacrificial film 158Rf, part of the sacrificial film 158Rf can be removed by a dry etching method using CHF₃ and He or using CHF₃, He, and CH₄. In the case where an In—Ga—Zn oxide film formed by a sputtering method is used as the mask film 159Rf, part of the mask film 159Rf can be removed by a wet etching method using diluted phosphoric acid. Alternatively, part of the mask film 159Rf may be removed by a dry etching method using CH₄ and Ar. Alternatively, part of the mask film 159Rf can be removed by a wet etching method using diluted phosphoric acid. In the case where a tungsten film formed by a sputtering method is used as the mask film 159Rf, part of the mask film 159Rf can be removed by a dry etching method using SF₆, CF₄, and O₂ or using CF₄, Cl₂, and O₂.

The resist mask 190R can be removed by a method similar to that for the resist mask 191. For example, the resist mask 190R can be removed by ashing using oxygen plasma. Alternatively, an oxygen gas and any of CF₄, C₄F₈, SF₆, CHF₃, Cl₂, H₂O, BCl₃, and a Group 18 element such as He may be used. Alternatively, the resist mask 190R may be removed by wet etching. At this time, the sacrificial film 158Rf is located on the outermost surface, and the organic compound film 103Rf is not exposed; thus, the organic compound film 103Rf can be inhibited from being damaged in the step of removing the resist mask 190R. In addition, the range of choice for the method for removing the resist mask 190R can be widened.

Next, as illustrated in FIG. 9B, the organic compound film 103Rf is processed, so that the organic compound layer 103R is formed. For example, part of the organic compound film 103Rf is removed using the mask layer 159R and the sacrificial layer 158R as a hard mask to form the organic compound layer 103R.

Accordingly, as illustrated in FIG. 9B, the stacked-layer structure of the organic compound layer 103R, the sacrificial layer 158R, and the mask layer 159R remains over the conductive layer 152R. The conductive layers 152G and 152B are exposed.

In the example illustrated in FIG. 9B, an end portion of the organic compound layer 103R is located inward from an end portion of the conductive layer 152R. With this structure, a pixel can be miniaturized, so that a high-resolution display can be formed. Although not illustrated in FIG. 9B, by the above etching treatment, a recessed portion may be formed in the insulating layer 175 in a region not overlapping with the organic compound layer 103R.

As described above, the resist mask 190R is preferably provided to cover the area from the end portion of the organic compound layer 103R to the end portion of the conductive layer 152C (the end portion closer to the organic compound layer 103R) in the cross section along the dashed-dotted line B1-B2. In that case, as illustrated in FIG. 9B, the sacrificial layer 158R and the mask layer 159R are provided to cover the area from the end portion of the organic compound layer 103R to the end portion of the conductive layer 152C (the end portion closer to the organic compound layer 103R) in the cross section along the dashed-dotted line B1-B2. Hence, the insulating layer 175 can be inhibited from being exposed in the cross section along the dashed-dotted line B1-B2, for example. This can prevent the insulating layers 175, 174, and 173 from being partly removed by etching or the like and thus prevent the conductive layer 179 from being exposed. Accordingly, the conductive layer 179 can be inhibited from being unintentionally electrically connected to another conductive layer. For example, a short circuit between the conductive layer 179 and a common electrode 155 formed in a later step can be inhibited.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Accordingly, damage to the organic compound film 103Rf can be reduced. Furthermore, a defect such as attachment of a reaction product generated in the etching can be inhibited.

In the case of using a dry etching method, it is preferable to use a gas containing at least one of H₂, CF₄, C₄F₈, SF₆, CHF₃, Cl₂, H₂O, BCl₃, and Group 18 elements such as He and Ar as the etching gas, for example. Alternatively, a gas containing oxygen and at least one of the above is preferably used as the etching gas. Alternatively, an oxygen gas may be used as the etching gas. Specifically, for example, a gas containing H₂ and Ar or a gas containing CF₄ and He can be used as the etching gas. For another example, a gas containing CF₄, He, and oxygen can be used as the etching gas. For another example, a gas containing H₂ and Ar and a gas containing oxygen can be used as the etching gas.

As described above, in one embodiment of the present invention, the mask layer 159R is formed in the following manner: the resist mask 190R is formed over the mask film 159Rf and part of the mask film 159Rf is removed using the resist mask 190R. After that, part of the organic compound film 103Rf is removed using the mask layer 159R as a hard mask, so that the organic compound layer 103R is formed. In other words, the organic compound layer 103R is formed by processing the organic compound film 103Rf by a lithography method. In addition, part of the organic compound film 103Rf may be removed using the resist mask 190R. Then, the resist mask 190R may be removed.

Next, hydrophobization treatment for the conductive layer 152G, for example, is preferably performed. At the time of processing the organic compound film 103Rf, the properties of a surface of the conductive layer 152G change to hydrophilic properties in some cases, for example. The hydrophobization treatment for the conductive layer 152G, for example, can increase the adhesion between the conductive layer 152G and a layer to be formed in a later step (which is the organic compound layer 103G here) and inhibit film peeling. Note that the hydrophobization treatment is not necessarily performed.

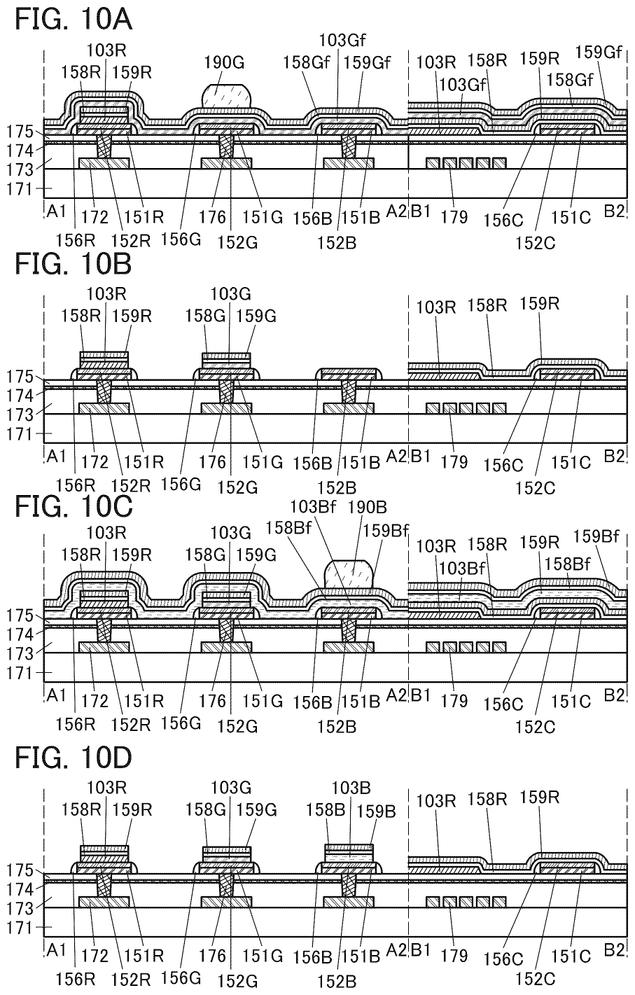

Next, as illustrated in FIG. 10A, an organic compound film 103Gf to be the organic compound layer 103G is formed over the conductive layers 152G and 152B, the insulating layers 156R, 156G, and 156B, the mask layer 159R, and the insulating layer 175.

The organic compound film 103Gf can be formed by a method similar to that for forming the organic compound film 103Rf. The organic compound film 103Gf can have a structure similar to that of the organic compound film 103Rf.

Then, as illustrated in FIG. 10A, a sacrificial film 158Gf to be a sacrificial layer 158G and a mask film 159Gf to be a mask layer 159G are sequentially formed over the organic compound film 103Gf and the mask layer 159R. After that, a resist mask 190G is formed. The materials and the formation methods of the sacrificial film 158Gf and the mask film 159Gf are similar to those of the sacrificial film 158Rf and the mask film 159Rf. The material and the formation method of the resist mask 190G are similar to those of the resist mask 190R.

The resist mask 190G is provided at a position overlapping with the conductive layer 152G.

Subsequently, as illustrated in FIG. 10B, part of the mask film 159Gf is removed using the resist mask 190G, so that the mask layer 159G is formed. The mask layer 159G remains over the conductive layer 152G. After that, the resist mask 190G is removed. Then, part of the sacrificial film 158Gf is removed using the mask layer 159G as a mask, so that the sacrificial layer 158G is formed. Next, the organic compound film 103Gf is processed, so that the organic compound layer 103G is formed. For example, part of the organic compound film 103Gf is removed using the mask layer 159G and the sacrificial layer 158G as a hard mask to form the organic compound layer 103G.

Accordingly, as illustrated in FIG. 10B, the stacked-layer structure of the organic compound layer 103G, the sacrificial layer 158G, and the mask layer 159G remains over the conductive layer 152G. The mask layer 159R and the conductive layer 152B are exposed.

Next, hydrophobization treatment for the conductive layer 152B, for example, is preferably performed. At the time of processing the organic compound film 103Gf, the properties of a surface of the conductive layer 152B change to hydrophilic properties in some cases, for example. The hydrophobization treatment for the conductive layer 152B, for example, can increase the adhesion between the conductive layer 152B and a layer to be formed in a later step (which is the organic compound layer 103B here) and inhibit film peeling. Note that the hydrophobization treatment is not necessarily performed.

Next, as illustrated in FIG. 10C, an organic compound film 103Bf to be the organic compound layer 103B is formed over the conductive layer 152B, the mask layer 159R, the insulating layers 156R, 156G, and 156B, the mask layer 159G, and the insulating layer 175.

The organic compound film 103Bf can be formed by a method similar to that for forming the organic compound film 103Rf. The organic compound film 103Bf can have a structure similar to that of the organic compound film 103Rf.

Then, as illustrated in FIG. 10C, a sacrificial film 158Bf to be a sacrificial layer 158B and a mask film 159Bf to be a mask layer 159B are sequentially formed over the organic compound film 103Bf and the mask layer 159R. After that, a resist mask 190B is formed. The materials and the formation methods of the sacrificial film 158Bf and the mask film 159Bf are similar to those of the sacrificial film 158Rf and the mask film 159Rf. The material and the formation method of the resist mask 190B are similar to those of the resist mask 190R.

The resist mask 190B is provided at a position overlapping with the conductive layer 152B.

Subsequently, as illustrated in FIG. 10D, part of the mask film 159Bf is removed using the resist mask 190B, so that the mask layer 159B is formed. The mask layer 159B remains over the conductive layer 152B. After that, the resist mask 190B is removed. Then, part of the sacrificial film 158Bf is removed using the mask layer 159B as a mask, so that the sacrificial layer 158B is formed. Next, the organic compound film 103Bf is processed, so that the organic compound layer 103B is formed. For example, part of the organic compound film 103Bf is removed using the mask layer 159B and the sacrificial layer 158B as a hard mask to form the organic compound layer 103B.

Accordingly, as illustrated in FIG. 10D, the stacked-layer structure of the organic compound layer 103B, the sacrificial layer 158B, and the mask layer 159B remains over the conductive layer 152B. The mask layers 159R and 159G are exposed.

Note that the side surfaces of the organic compound layers 103R, 103G, and 103B are preferably perpendicular or substantially perpendicular to their formation surfaces. For example, the angles between the formation surfaces and these side surfaces are each preferably greater than or equal to 600 and less than or equal to 90°.

The distance between two adjacent layers among the organic compound layers 103R, 103G, and 103B, which are formed by a lithography method as described above, can be shortened to less than or equal to 8 μm, less than or equal to 5 μm, less than or equal to 3 μm, less than or equal to 2 μm, or less than or equal to 1 μm. Here, the distance can be defined, for example, as the distance between opposite end portions of two adjacent layers among the organic compound layers 103R, 103G, and 103B. Shortening the distance between the island-shaped organic compound layers can provide a display device having high resolution and a high aperture ratio. In addition, the distance between the first electrodes of adjacent light-emitting devices can also be shortened to be, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

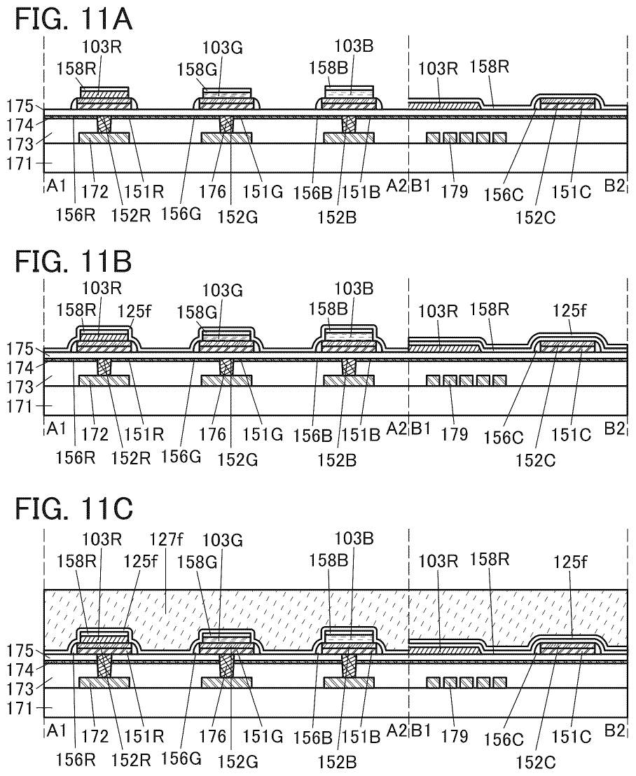

Next, as illustrated in FIG. 11A, the mask layers 159R, 159G, and 159B are preferably removed. The sacrificial layers 158R, 158G, and 158B and the mask layers 159R, 159G, and 159B remain in the display device in some cases depending on the subsequent steps. Removing the mask layers 159R, 159G, and 159B at this stage can inhibit the mask layers 159R, 159G, and 159B from being left in the display device. For example, in the case where a conductive material is used for the mask layers 159R, 159G, and 159B, removing the mask layers 159R, 159G, and 159B in advance can inhibit generation of a leakage current, formation of a capacitor, and the like due to the remaining mask layers 159R, 159G, and 159B.

This embodiment describes an example in which the mask layers 159R, 159G, and 159B are removed; however, the mask layers 159R, 159G, and 159B are not necessarily removed. For example, in the case where the mask layers 159R, 159G, and 159B include the above-described material having a property of blocking ultraviolet rays, the procedure preferably proceeds to the next step without removing the mask layers 159R, 159G, and 159B, in which case the organic compound layers can be protected from ultraviolet rays.

The step of removing the mask layers can be performed by a method similar to that for the step of processing the mask films. Specifically, by using a wet etching method, damage applied to the organic compound layers 103R, 103G, and 103B at the time of removing the mask layers can be reduced as compared to the case of using a dry etching method.

The mask layers may be removed by being dissolved in a solvent such as water or an alcohol. Examples of an alcohol include ethyl alcohol, methyl alcohol, isopropyl alcohol (IPA), and glycerin.

After the mask layers are removed, drying treatment may be performed in order to remove water included in the organic compound layers 103R, 103G, and 103B and water adsorbed onto the surfaces of the organic compound layers 103R, 103G, and 103B. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, as illustrated in FIG. 11B, the inorganic insulating film 125f to be the inorganic insulating layer 125 is formed to cover the organic compound layers 103R, 103G, and 103B and the sacrificial layers 158R, 158G, and 158B.

As described later, an insulating film to be the insulating layer 127 is formed in contact with the top surface of the inorganic insulating film 125f. Therefore, the top surface of the inorganic insulating film 125f preferably has a high affinity for the material used for the insulating film (e.g., a photosensitive resin composition containing an acrylic resin). To improve the affinity, surface treatment is preferably performed so that the top surface of the inorganic insulating film 125f is made hydrophobic (or its hydrophobic property is improved). For example, it is preferable to perform the treatment using a silylation agent such as hexamethyldisilazane (HMDS). By making the top surface of the inorganic insulating film 125f hydrophobic in such a manner, an insulating film 127f can be formed with favorable adhesion. Note that the above-described hydrophobization treatment may be performed as the surface treatment.

Then, as illustrated in FIG. 11C, the insulating film 127f to be the insulating layer 127 is formed over the inorganic insulating film 125f.

The inorganic insulating film 125f and the insulating film 127f are preferably formed by a formation method by which the organic compound layers 103R, 103G, and 103B are less damaged. The inorganic insulating film 125f, which is formed in contact with the side surfaces of the organic compound layers 103R, 103G, and 103B, is particularly preferably formed by a formation method that causes less damage to the organic compound layers 103R, 103G, and 103B than the formation method of the insulating film 127f.

Each of the inorganic insulating film 125f and the insulating film 127f is formed at a temperature lower than the upper temperature limits of the organic compound layers 103R, 103G, and 103B. When the inorganic insulating film 125f is formed at a high substrate temperature, the formed inorganic insulating film 125f, even with a small thickness, can have a low impurity concentration and a high barrier property against at least one of water and oxygen.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed in the above-described range of the substrate temperature.

The inorganic insulating film 125f is preferably formed by an ALD method, for example. An ALD method is preferably used, in which case damage due to film formation is reduced and a film with good coverage can be formed. As the inorganic insulating film 125f, an aluminum oxide film is preferably formed by an ALD method, for example.

Alternatively, the inorganic insulating film 125f may be formed by a sputtering method, a CVD method, or a PECVD method, each of which has a higher deposition rate than an ALD method. In that case, a highly reliable display device can be manufactured with high productivity.

The insulating film 127f is preferably formed by the aforementioned wet film-formation method. For example, the insulating film 127f is preferably formed by spin coating using a photosensitive material, and specifically, preferably formed using a photosensitive resin composition containing an acrylic resin.

The insulating film 127f is preferably formed using a resin composition containing a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

Heat treatment (also referred to as prebaking) is preferably performed after the insulating film 127f is formed. The heat treatment is performed at a temperature lower than the upper temperature limits of the organic compound layers 103R, 103G, and 103B. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, the solvent included in the insulating film 127f can be removed.

Then, part of the insulating film 127f is exposed to visible light or ultraviolet rays. Here, when a positive photosensitive resin composition containing an acrylic resin is used for the insulating film 127f, a region where the insulating layer 127 is not formed in a later step is irradiated with visible light or ultraviolet rays. The insulating layer 127 is formed in regions that are sandwiched between any two of the conductive layers 152R, 152G, and 152B and around the conductive layer 152C. Thus, the top surfaces of the conductive layers 152R, 152G, 152B, and 152C are irradiated with visible light or ultraviolet rays. Note that when a negative photosensitive material is used for the insulating film 127f, the region where the insulating layer 127 is to be formed is irradiated with visible light or ultraviolet rays.

The width of the insulating layer 127 that is to be formed later can be controlled with the exposed region of the insulating film 127f. In this embodiment, processing is performed such that the insulating layer 127 includes a portion overlapping with the top surface of the conductive layer 151.

The light used for the exposure preferably includes the i-line (wavelength: 365 nm). Furthermore, the light used for the exposure may include at least one of the g-line (wavelength: 436 nm) and the h-line (wavelength: 405 nm).

Here, when a barrier insulating layer against oxygen (e.g., an aluminum oxide film) is provided as one or both of the sacrificial layer 158 (the sacrificial layers 158R, 158G, and 158B) and the inorganic insulating film 125f, diffusion of oxygen into the organic compound layers 103R, 103G, and 103B can be inhibited. When the organic compound layer is irradiated with light (visible light or ultraviolet rays), the organic compound included in the organic compound layer is brought into an excited state and a reaction between the organic compound and oxygen in the atmosphere is promoted in some cases. Specifically, when the organic compound layer is irradiated with light (visible light or ultraviolet rays) in an atmosphere containing oxygen, oxygen may be bonded to the organic compound included in the organic compound layer. By providing the sacrificial layer 158 and the inorganic insulating film 125f over the island-shaped organic compound layer, bonding of oxygen in the atmosphere to the organic compound included in the organic compound layer can be inhibited.

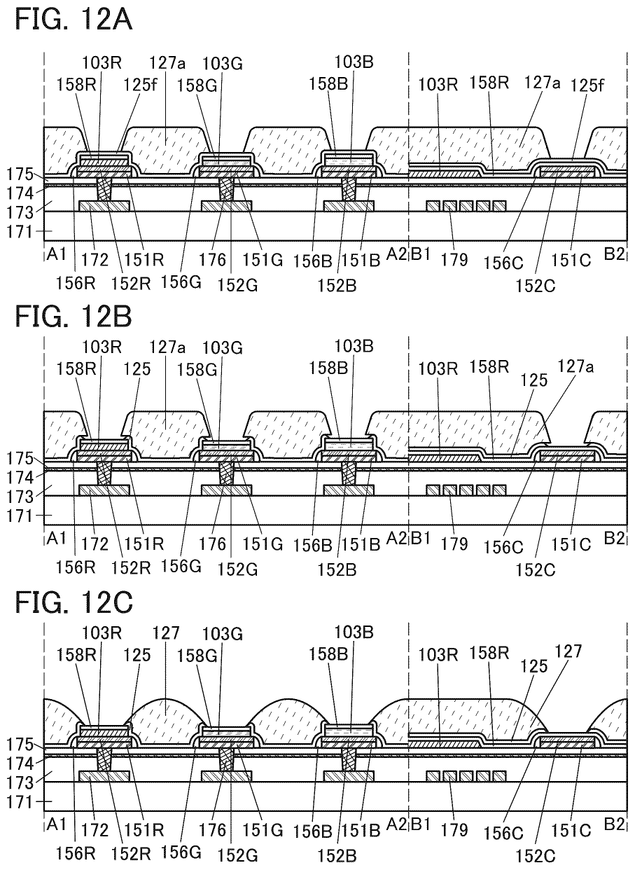

Next, as illustrated in FIG. 12A, development is performed to remove the exposed region of the insulating film 127f, so that an insulating layer 127a is formed. The insulating layer 127a is formed in regions that are sandwiched between any two of the conductive layers 152R, 152G, and 152B and a region surrounding the conductive layer 152C. Here, when an acrylic resin is used for the insulating film 127f, an alkaline solution, such as TMAH, can be used as a developer.

Then, a residue (scum) due to the development may be removed. For example, the residue can be removed by ashing using oxygen plasma.

Etching may be performed to adjust the surface level of the insulating layer 127a. The insulating layer 127a may be processed by ashing using oxygen plasma, for example. In the case where a non-photosensitive material is used for the insulating film 127f, the surface level of the insulating film 127f can be adjusted by the ashing, for example.

Next, as illustrated in FIG. 12B, etching treatment is performed using the insulating layer 127a as a mask to remove part of the inorganic insulating film 125f and reduce the thicknesses of parts of the sacrificial layers 158R, 158G, and 158B. Thus, the inorganic insulating layer 125 is formed under the insulating layer 127a. Moreover, the surfaces of the thin portions of the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layers 158R, 158G, and 158B, in which case the first etching treatment can be performed collectively.

By etching using the insulating layer 127a with a tapered side surface as a mask, the side surface of the inorganic insulating layer 125 and upper end portions of the side surfaces of the sacrificial layers 158R, 158G, and 158B can each be made to have a tapered shape relatively easily.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used. The capacitively coupled plasma etching apparatus including parallel plate electrodes may have a structure where a high-frequency voltage is applied to one of the parallel plate electrodes. Alternatively, the capacitively coupled plasma etching apparatus may have a structure where different high-frequency voltages are applied to one of the parallel-plate electrodes. Alternatively, the capacitively coupled plasma etching apparatus may have a structure where high-frequency voltages with the same frequency are applied to the parallel-plate electrodes. Alternatively, the capacitively coupled plasma etching apparatus may have a structure where high-frequency voltages with different frequencies are applied to the parallel-plate electrodes.

In the case of performing dry etching, a by-product or the like generated by the dry etching is sometimes deposited on the top surface and the side surface of the insulating layer 127a, for example. Accordingly, a component of the etching gas, a component of the inorganic insulating film 125f, a component of the sacrificial layers 158R, 158G, and 158B, and the like are included in the insulating layer 127 in the completed display device in some cases.

The first etching treatment is preferably performed by wet etching. The use of a wet etching method can reduce damage to the organic compound layers 103R, 103G, and 103B, as compared to the case of using a dry etching method. For example, the wet etching can be performed using an alkaline solution. For instance, TMAH, which is an alkaline solution, can be used for the wet etching of an aluminum oxide film. In this case, puddle wet etching can be performed. Note that the inorganic insulating film 125f is preferably formed using a material similar to that of the sacrificial layers 158R, 158G, and 158B, in which case the above etching treatment can be performed collectively.

The sacrificial layers 158R, 158G, and 158B are not removed completely by the first etching treatment, and the etching treatment is stopped when the thicknesses of the sacrificial layers 158R, 158G, and 158B are reduced. The sacrificial layers 158R, 158G, and 158B remain over the corresponding organic compound layers 103R, 103G, and 103B in this manner, whereby the organic compound layers 103R, 103G, and 103B can be prevented from being damaged by treatment in a later step.

Next, the insulating layer 127a is preferably irradiated with visible light or ultraviolet rays by performing light exposure on the entire substrate. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a to a tapered shape.

Here, when a barrier insulating layer against oxygen (e.g., an aluminum oxide film) is provided as each of the sacrificial layers 158R, 158G, and 158B, diffusion of oxygen into the organic compound layers 103R, 103G, and 103B can be inhibited. When the organic compound layer is irradiated with light (visible light or ultraviolet rays), the organic compound included in the organic compound layer is brought into an excited state and a reaction between the organic compound and oxygen in the atmosphere is promoted in some cases. Specifically, when the organic compound layer is irradiated with light (visible light or ultraviolet rays) in an atmosphere containing oxygen, oxygen may be bonded to the organic compound included in the organic compound layer. By providing the sacrificial layers 158R, 158G, and 158B over the island-shaped organic compound layers, bonding of oxygen in the atmosphere to the organic compounds included in the organic compound layers can be inhibited.

Then, heat treatment (also referred to as post-baking) is performed. The heat treatment can change the insulating layer 127a into the insulating layer 127 having a tapered side surface (FIG. 12C). The heat treatment is performed at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. The substrate temperature in the heat treatment of this step is preferably higher than that in the heat treatment (prebaking) after the formation of the insulating film 127f. In that case, the adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the organic compound layers 103R, 103G, and 103B can be prevented from being damaged and deteriorating in the heat treatment. This increases the reliability of the light-emitting devices.

Note that the side surface of the insulating layer 127 may have a concave shape depending on the material of the insulating layer 127 and the temperature, time, and atmosphere of the post-baking. For example, when the temperature of the post-baking is higher or the duration of the post-baking is longer, the insulating layer 127 is more likely to change in shape and thus a concave shape may be more likely to be formed.

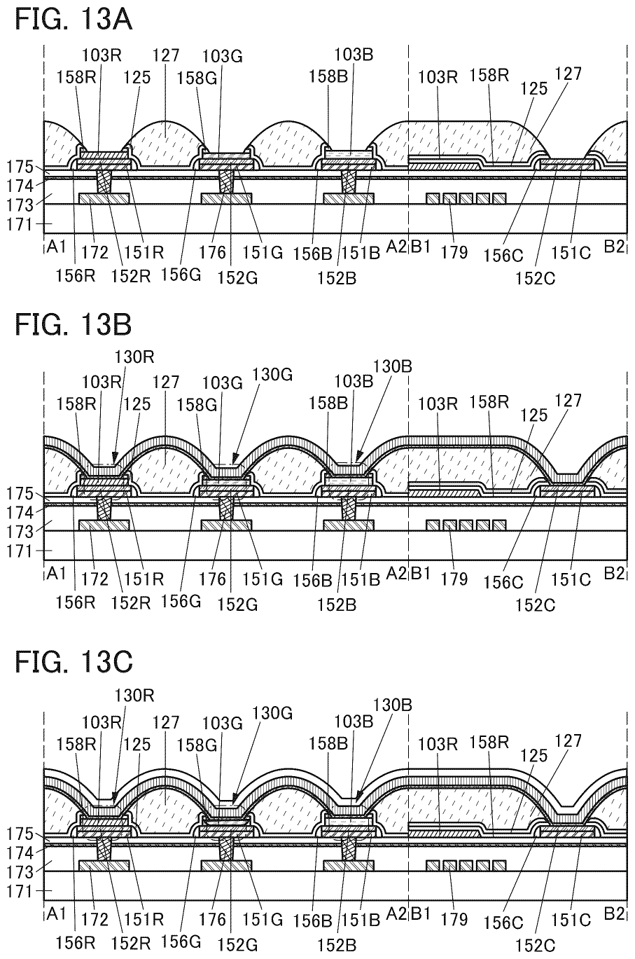

Next, as illustrated in FIG. 13A, etching treatment is performed using the insulating layer 127 as a mask to remove part of the sacrificial layers 158R, 158G, and 158B. Note that part of the inorganic insulating layer 125 is also removed in some cases. Thus, openings are formed in the sacrificial layers 158R, 158G, and 158B, and the top surfaces of the organic compound layers 103R, 103G, and 103B and the conductive layer 152C are exposed. Note that the etching treatment using the insulating layer 127 as a mask may be hereinafter referred to as second etching treatment.

An end portion of the inorganic insulating layer 125 is covered with the insulating layer 127. FIG. 13A illustrates an example in which part of an end portion of the sacrificial layer 158G (specifically a tapered portion formed by the first etching treatment) is covered with the insulating layer 127 and a tapered portion formed by the second etching treatment is exposed.

If the first etching treatment is not performed and the inorganic insulating layer 125 and the mask layer are collectively etched after the post-baking, the inorganic insulating layer 125 and the mask layer under an end portion of the insulating layer 127 may disappear because of side etching and a void may be formed. The void causes unevenness on the formation surface of the common electrode 155, so that step disconnection is more likely to be caused in the common electrode 155. Even when a void is formed owing to side etching of the inorganic insulating layer 125 and the mask layer by the first etching treatment, the post-baking performed subsequently can make the insulating layer 127 fill the void. After that, the thinned mask layer is etched by the second etching treatment; thus, the amount of side etching decreases, a void is less likely to be formed, and even if a void is formed, it can be extremely small. Consequently, the formation surface of the common electrode 155 can be made flatter.

Note that the insulating layer 127 may cover the entire end portion of the sacrificial layer 158G. For example, the end portion of the insulating layer 127 may droop to cover the end portion of the sacrificial layer 158G. For another example, the end portion of the insulating layer 127 may be in contact with the top surface of at least one of the organic compound layers 103R, 103G, and 103B. As described above, when light exposure is not performed on the insulating layer 127a after the development, the shape of the insulating layer 127 may be likely to change.

The second etching treatment is performed by wet etching. The use of a wet etching method can reduce damage to the organic compound layers 103R, 103G, and 103B, as compared to the case of using a dry etching method. The wet etching can be performed using an alkaline solution such as TMAH, for example.

Meanwhile, in the case where the second etching treatment is performed by a wet etching method and there are gaps due to, for example, poor adhesion between the organic compound layer 103 and another layer at the interface between the organic compound layer 103 and the sacrificial layer 158, the interface between the organic compound layer 103 and the inorganic insulating layer 125, and the interface between the organic compound layer 103 and the insulating layer 175, the chemical solution used in the second etching treatment sometimes enters the gaps to come into contact with the pixel electrode. Here, when the chemical solution comes into contact with both the conductive layer 151 and the conductive layer 152, one of the conductive layers 151 and 152 that has a lower spontaneous potential than the other suffers from galvanic corrosion in some cases. For example, when the conductive layer 151 is formed using aluminum and the conductive layer 152 is formed using indium tin oxide, the conductive layer 152 sometimes corrodes. As a result, the yield of the display device decreases in some cases. Moreover, the reliability of the display device decreases in some cases.

When the insulating layer 156 is formed to have a region overlapping with the side surface of the conductive layer 151 and the insulating layer 156 is formed to cover the conductive layers 151 and 152 as described above, step disconnection in the inorganic insulating layer 125 can be prevented, whereby the chemical solution can be prevented from coming into contact with a lower-layer structure such as the conductive layer 151 in the second etching treatment, for example. Thus, corrosion of the pixel electrode can be prevented.

As described above, by providing the insulating layer 127, the inorganic insulating layer 125, and the sacrificial layers 158R, 158G, and 158B, poor connection due to a disconnected portion and an increase in electrical resistance due to a locally thinned portion can be inhibited from occurring in the common electrode 155 between the light-emitting devices. Thus, the display device of one embodiment of the present invention can have improved display quality.

Heat treatment is performed after the organic compound layers 103R, 103G, and 103B are partly exposed. By the heat treatment, water included in the organic compound layers and water adsorbed onto the surfaces of the organic compound layers, for example, can be removed. The shape of the insulating layer 127 may be changed by the heat treatment. Specifically, the insulating layer 127 may be widened to cover at least one of the end portion of the inorganic insulating layer 125, the end portions of the sacrificial layers 158R, 158G, and 158B, and the top surfaces of the organic compound layers 103R, 103G, and 103B.

If the temperature of the heat treatment is too low, water included in the organic compound layers and water adsorbed onto the surfaces of the organic compound layers, for example, cannot be sufficiently removed. If the temperature of the heat treatment is too high, the organic compound layer 103 may deteriorate and the insulating layer 127 may change in shape excessively. Therefore, the temperature of the heat treatment is preferably higher than the temperature at which water is released from the organic compound layer 103 and lower than the glass transition temperature of the organic compound included in the organic compound layer 103, further preferably lower than the glass transition temperature of the organic compound included in the upper surface of the organic compound layer 103. Specifically, the substrate temperature is preferably higher than or equal to 80° C. and lower than or equal to 130° C., further preferably higher than or equal to 90° C. and lower than or equal to 120° C., still further preferably higher than or equal to 100° C. and lower than or equal to 120° C., and yet still further preferably higher than or equal to 100° C. and lower than or equal to 110° C. The heating atmosphere may be an air atmosphere or an inert gas atmosphere. Although the heating atmosphere may be an atmospheric-pressure atmosphere or a reduced-pressure atmosphere, a reduced-pressure atmosphere is preferably employed to prevent re-adsorption of water released from the organic compound layer 103.

By the heat treatment, water included in the organic compound layers and water adsorbed onto the surfaces of the organic compound layers, for example, can be sufficiently removed without deterioration of the organic compound layers 103R, 103G, and 103B and an excessive change in the shape of the insulating layer 127. Thus, degradation of the characteristics of the light-emitting device can be prevented.

Next, as illustrated in FIG. 13B, the common layer 104 and the common electrode 155 are formed over the organic compound layers 103R, 103G, and 103B, the conductive layer 152C, and the insulating layer 127. The common layer 104 and common electrode 155 can be formed by a sputtering method, a vacuum evaporation method, or the like. The common layer 104 may be formed by an evaporation method while the common electrode 155 may be formed by a sputtering method.

Next, as illustrated in FIG. 13C, the protective layer 131 is formed over the common electrode 155. The protective layer 131 can be formed by a vacuum evaporation method, a sputtering method, a CVD method, an ALD method, or the like.

Then, the substrate 120 is attached to the protective layer 131 using the resin layer 122, so that the display device can be manufactured. As described above, in the method for manufacturing the display device of one embodiment of the present invention, the insulating layer 156 is provided on the side surfaces of the conductive layers 151 and 152. This can increase the yield of the display device and inhibit generation of defects.

As described above, in the method for manufacturing the display device of one embodiment of the present invention, the island-shaped organic compound layers 103R, 103G, and 103B are each formed not by using a fine metal mask but by processing a film formed on the entire surface; thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the organic compound layers 103R, 103G, and 103B can be inhibited from being in contact with each other in the adjacent subpixels. As a result, generation of a leakage current between the subpixels can be inhibited. This can prevent crosstalk, so that a display device with extremely high contrast can be obtained. Moreover, even a display device that includes tandem light-emitting devices formed by a lithography method can have favorable characteristics.

The structure described in this embodiment can be used in combination with any of the structures described in other embodiments as appropriate.

### Embodiment 4

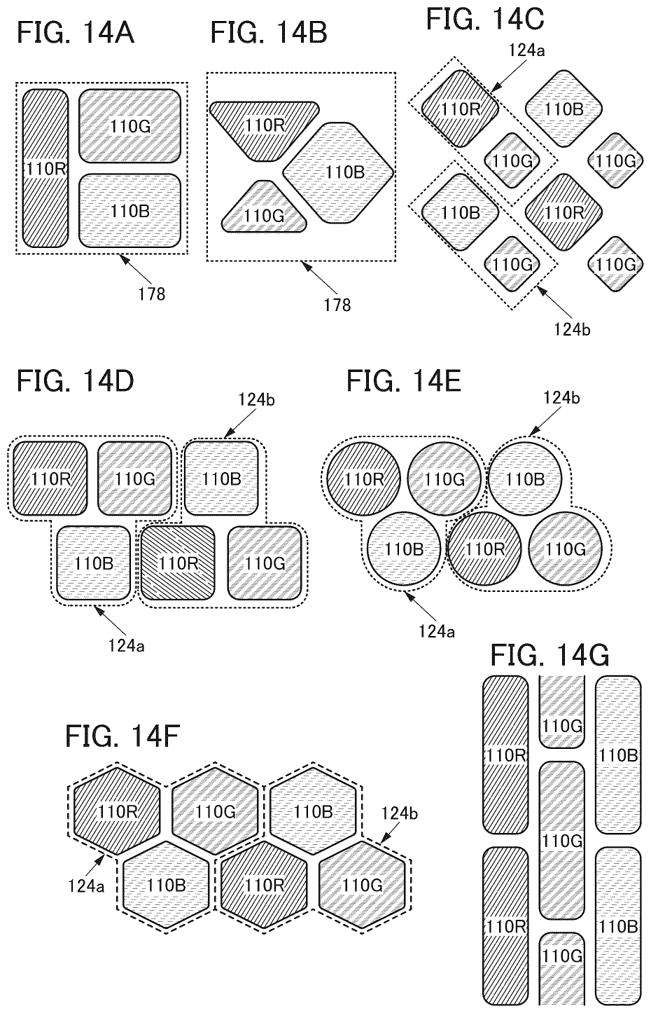

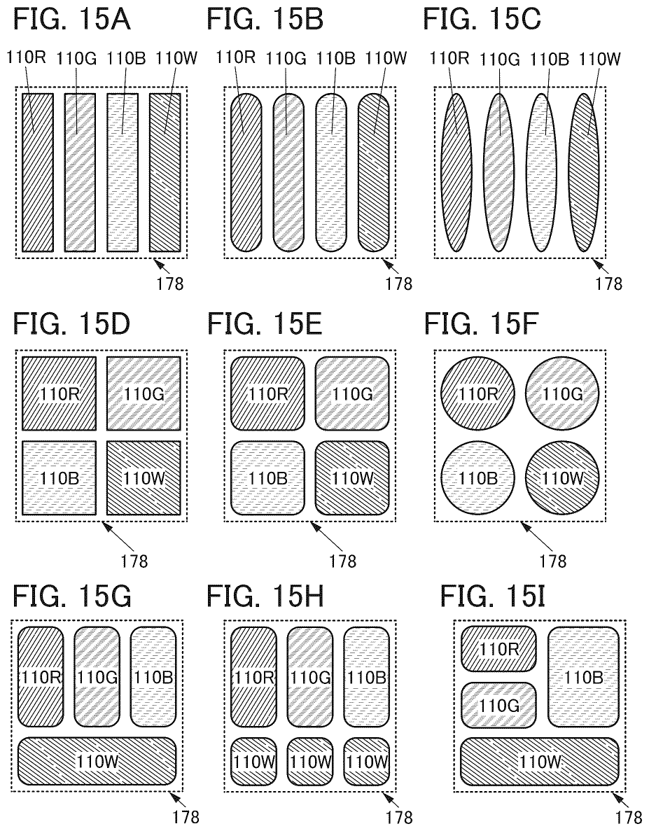

In this embodiment, the light-emitting apparatus of one embodiment of the present invention will be described with reference to FIGS. 14A to 14G and FIGS. 15A to 15I.

### [Pixel Layout]

In this embodiment, pixel layouts different from that in FIG. 6A will be mainly described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

In this embodiment, the top surface shapes of the subpixels shown in the diagrams correspond to top surface shapes of light-emitting regions.

Examples of a top surface shape of the subpixel include polygons such as a triangle, a tetragon (including a rectangle and a square), and a pentagon; polygons with rounded corners; an ellipse; and a circle.

The circuit constituting the subpixel is not necessarily placed within the dimensions of the subpixel illustrated in the diagrams and may be placed outside the subpixel.

The pixel 178 illustrated in FIG. 14A employs S-stripe arrangement. The pixel 178 illustrated in FIG. 14A includes three subpixels, the subpixel 110R, the subpixel 110G, and the subpixel 110B.

The pixel 178 illustrated in FIG. 14B includes the subpixel 110R whose top surface has a roughly trapezoidal or triangular shape with rounded corners, the subpixel 110G whose top surface has a roughly trapezoidal or triangular shape with rounded corners, and the subpixel 110B whose top surface has a roughly tetragonal or hexagonal shape with rounded corners. The subpixel 110R has a larger light-emitting area than the subpixel 110G. In this manner, the shapes and sizes of the subpixels can be determined independently. For example, the size of a subpixel including a light-emitting device with higher reliability can be smaller.

A pixel 124a and a pixel 124b illustrated in FIG. 14C employ PenTile arrangement. FIG. 14C shows an example in which the pixels 124a including the subpixels 110R and 110G and the pixels 124b including the subpixels 110G and 110B are alternately arranged.

The pixels 124a and 124b illustrated in FIGS. 14D to 14F employ delta arrangement. The pixel 124a includes two subpixels (the subpixels 110R and 110G) in the upper row (first row) and one subpixel (the subpixel 110B) in the lower row (second row). The pixel 124b includes one subpixel (the subpixel 110B) in the upper row (first row) and two subpixels (the subpixels 110R and 110G) in the lower row (second row).

FIG. 14D illustrates an example in which each subpixel has a rough tetragonal top surface with rounded corners. FIG. 14E illustrates an example in which each subpixel has a circular top surface. FIG. 14F illustrates an example in which each subpixel has a rough hexagonal top surface with rounded corners.

In FIG. 14F, subpixels are placed inside the respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 110R, the subpixel 110R is surrounded by three subpixels 110G and three subpixels 110B that are alternately arranged.

FIG. 14G shows an example in which subpixels of different colors are arranged in a zigzag manner. Specifically, the positions of the top sides of two subpixels arranged in the row direction (e.g., the subpixels 110R and 110G or the subpixels 110G and 110B) are not aligned in the top view.

In the pixels illustrated in FIGS. 14A to 14G, for example, it is preferable that the subpixel 110R be a subpixel R that emits red light, the subpixel 110G be a subpixel G that emits green light, and the subpixel 110B be a subpixel B that emits blue light. Note that the structures of the subpixels are not limited thereto, and the colors and the order of the subpixels can be determined as appropriate. For example, the subpixel 110G may be the subpixel R that emits red light, and the subpixel 110R may be the subpixel G that emits green light.

In a photolithography method, as a pattern to be formed by processing becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

Furthermore, in the method for fabricating the light-emitting apparatus of one embodiment of the present invention, the organic compound layer is processed into an island shape with the use of a resist mask. A resist film formed over the organic compound layer needs to be cured at a temperature lower than the upper temperature limit of the organic compound layer. Therefore, the resist film is insufficiently cured in some cases depending on the upper temperature limit of the material of the organic compound layer and the curing temperature of the resist material. An insufficiently cured resist film may have a shape different from a desired shape by processing. As a result, the top surface of the organic compound layer may have a polygonal shape with rounded corners, an elliptical shape, a circular shape, or the like. For example, when a resist mask with a square top surface is intended to be formed, a resist mask with a circular top surface may be formed, and the top surface of the organic compound layer may be circular.

To obtain a desired top surface shape of the organic compound layer, a technique of correcting a mask pattern in advance so that a transferred pattern agrees with a design pattern (an optical proximity correction (OPC) technique) may be used. Specifically, with the OPC technique, a pattern for correction is added to a corner portion of a figure on a mask pattern, for example.

As illustrated in FIGS. 15A to 15I, the pixel can include four types of subpixels.

The pixels 178 illustrated in FIGS. 15A to 15C employ stripe arrangement.

FIG. 15A illustrates an example in which each subpixel has a rectangular top surface. FIG. 15B illustrates an example in which each subpixel has a top surface shape formed by combining two half circles and a rectangle. FIG. 15C illustrates an example in which each subpixel has an elliptical top surface.

The pixels 178 illustrated in FIGS. 15D to 15F employ matrix arrangement.

FIG. 15D illustrates an example in which each subpixel has a square top surface. FIG. 15E illustrates an example in which each subpixel has a substantially square top surface with rounded corners. FIG. 15F illustrates an example in which each subpixel has a circular top surface.

FIGS. 15G and 15H each illustrate an example in which one pixel 178 is composed of two rows and three columns.

The pixel 178 illustrated in FIG. 15G includes three subpixels (the subpixels 110R, 110G, and 110B) in the upper row (first row) and one subpixel (a subpixel 110W) in the lower row (second row). In other words, the pixel 178 includes the subpixel 110R in the left column (first column), the subpixel 110G in the middle column (second column), the subpixel 110B in the right column (third column), and the subpixel 110W across these three columns.

The pixel 178 illustrated in FIG. 15H includes three subpixels (the subpixels 110R, 110G, and 110B) in the upper row (first row) and three of the subpixels 110W in the lower row (second row). In other words, the pixel 178 includes the subpixels 110R and 110W in the left column (first column), the subpixels 110G and 110W in the middle column (second column), and the subpixels 110B and 110W in the right column (third column). Matching the positions of the subpixels in the upper row and the lower row as illustrated in FIG. 15H enables dust that would be produced in the fabrication process, for example, to be removed efficiently. Thus, a light-emitting apparatus having high display quality can be provided.

In the pixel 178 illustrated in FIGS. 15G and 15H, the subpixels 110R, 110G, and 110B are arranged in a stripe pattern, whereby the display quality can be improved.

FIG. 15I illustrates an example in which one pixel 178 is composed of three rows and two columns.

The pixel 178 illustrated in FIG. 15I includes the subpixel 110R in the upper row (first row), the subpixel 110G in the middle row (second row), the subpixel 110B across the first row and the second row, and one subpixel (the subpixel 110W) in the lower row (third row). In other words, the pixel 178 includes the subpixels 110R and 110G in the left column (first column), the subpixel 110B in the right column (second column), and the subpixel 110W across these two columns.

In the pixel 178 illustrated in FIG. 15I, the subpixels 110R, 110G, and 110B are arranged in what is called an S-stripe pattern, whereby the display quality can be improved.

The pixel 178 illustrated in each of FIGS. 15A to 15I is composed of four subpixels, which are the subpixels 110R, 110G, 110B, and 110W. For example, the subpixel 110R can be a subpixel that emits red light, the subpixel 110G can be a subpixel that emits green light, the subpixel 110B can be a subpixel that emits blue light, and the subpixel 110W can be a subpixel that emits white light. Note that at least one of the subpixels 110R, 110G, 110B, and 110W may be a subpixel that emits cyan light, magenta light, yellow light, or near-infrared light.

As described above, the pixel composed of the subpixels each including the light-emitting device can employ any of a variety of layouts in the light-emitting apparatus of one embodiment of the present invention.

This embodiment can be combined as appropriate with any of the other embodiments or examples. In this specification, in the case where a plurality of structure examples are shown in one embodiment, the structure examples can be combined as appropriate.

### Embodiment 5

In this embodiment, a display device of one embodiment of the present invention will be described.

The display device in this embodiment can be a high-resolution display device. Thus, the display device in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display device in this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, desktop and notebook personal computers, a monitor of a computer and the like, digital signage, and a large game machine such as a pachinko machine.

[Display Module]

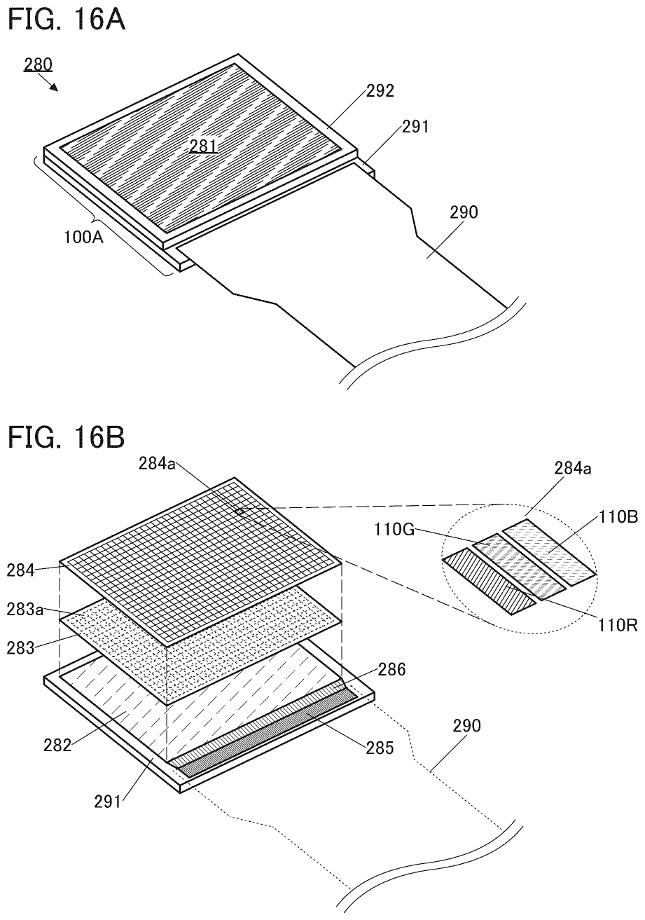

FIG. 16A is a perspective view of a display module 280. The display module 280 includes a display device 100A and an FPC 290. Note that the display device included in the display module 280 is not limited to the display device 100A and may be any of display devices 100B to 100E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 16B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 16B. The pixels 284a can employ any of the structures described in the above embodiments.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both ofa gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic devices including a relatively small display portion.

### [Display Device 100A]

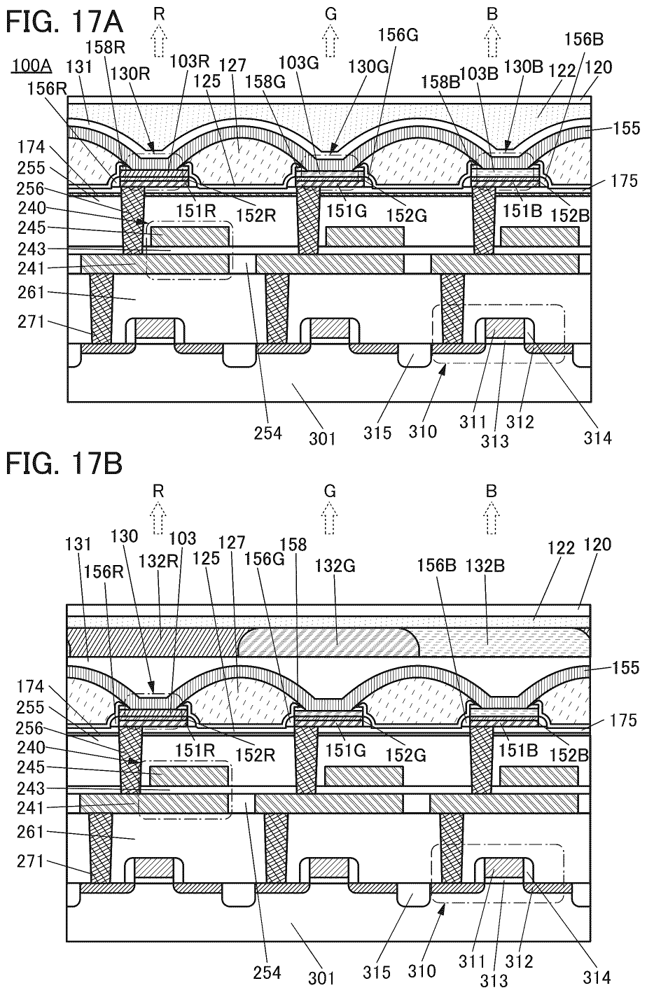

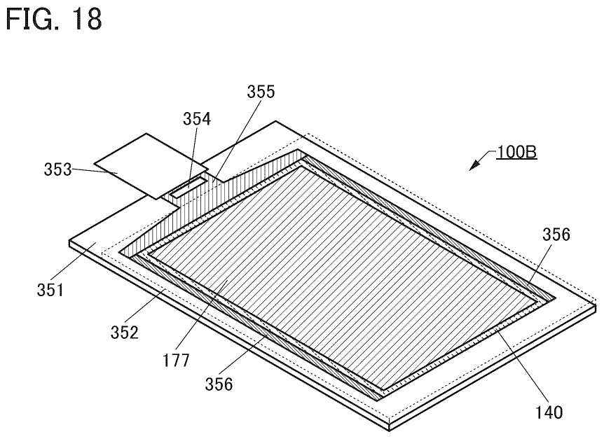

The display device 100A illustrated in FIG. 17A includes a substrate 301, the light-emitting devices 130R, 130G, and 130B, a capacitor 240, and a transistor 310.

The substrate 301 corresponds to the substrate 291 in FIGS. 16A and 16B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

The insulating layer 156R is provided to include a region overlapping with the side surface of the conductive layer 151R. The insulating layer 156G is provided to include a region overlapping with the side surface of the conductive layer 151G. The insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the organic compound layer 103R. The sacrificial layer 158G is positioned over the organic compound layer 103G. The sacrificial layer 158B is positioned over the organic compound layer 103B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 is bonded to the protective layer 131 with the resin layer 122. Embodiment 4 can be referred to for the details of the light-emitting device 130 and the components thereover up to the substrate 120. The substrate 120 corresponds to the substrate 292 in FIG. 16A.

FIG. 17B illustrates a variation example of the display device 100A illustrated in FIG. 17A. The display device illustrated in FIG. 17B includes a coloring layer 132R, a coloring layer 132G, and a coloring layer 132B, and each of the light-emitting devices 130 includes a region overlapping with one of the coloring layers 132R, 132G, and 132B. In the display device illustrated in FIG. 17B, the light-emitting device 130 can emit white light, for example. The coloring layer 132R, the coloring layer 132G, and the coloring layer 132B can transmit red light, green light, and blue light, respectively, for example.

### [Display Device 100B]

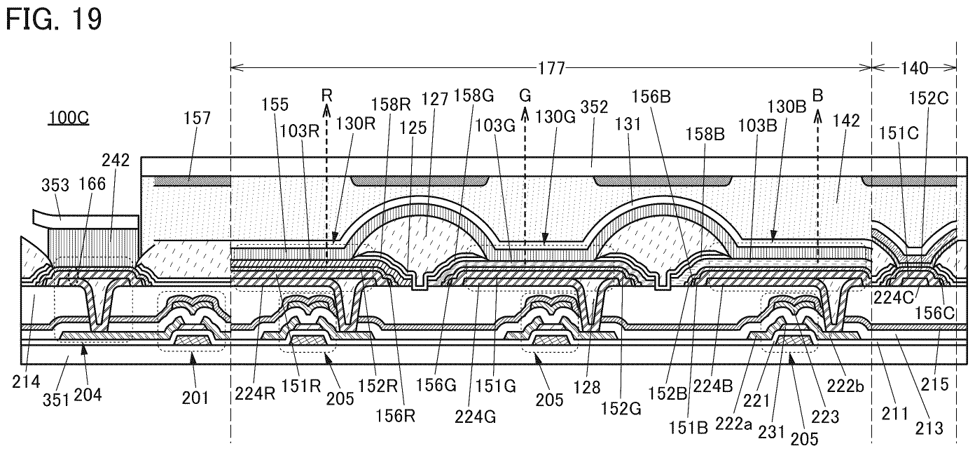

FIG. 18 is a perspective view of the display device 100B, and FIG. 19 is a cross-sectional view of the display device 100C.

In the display device 100B, a substrate 352 and a substrate 351 are bonded to each other. In FIG. 18, the substrate 352 is denoted by a dashed line.

The display device 100B includes the pixel portion 177, the connection portion 140, a circuit 356, a wiring 355, and the like. FIG. 18 illustrates an example in which an IC 354 and an FPC 353 are mounted on the display device 100B. Thus, the structure illustrated in FIG. 18 can be regarded as a display module including the display device 100B, the integrated circuit (IC), and the FPC. Here, a display device in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 18 illustrates an example in which the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display device 100B and the display module are not necessarily provided with an IC. Alternatively, the IC may be mounted on the FPC by a COF method, for example.

FIG. 19 illustrates the display device 100C as an example of cross sections of part of a region including the FPC 353, part of the circuit 356, part of the pixel portion 177, part of the connection portion 140, and part of a region including an end portion of the display device 100B in FIG. 18.

### [Display Device 100C]

The display device 100C illustrated in FIG. 19 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 4 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G, and the insulating layer 156G in the light-emitting device 130G are not described in detail because they are respectively similar to the conductive layers 224R, 151R, and 152R, and the insulating layer 156R in the light-emitting device 130R; the same applies to the conductive layers 224B, 151B, and 152B, and the insulating layer 156B in the light-emitting device 130B.

The conductive layers 224R, 224G, and 224B each have a depressed portion covering the opening provided in the insulating layer 214. A layer 128 is embedded in the depressed portion.

The layer 128 has a function of filling the depressed portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depressed portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 19, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Alternatively, the space may be filled with a resin other than the frame-like adhesive layer 142.

FIG. 19 illustrates an example in which the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 19, the insulating layer 156C is provided to include a region overlapping with the side surface of the conductive layer 151C.

The display device 100C has a top-emission structure. Light from the light-emitting device is emitted toward the substrate 352. For the substrate 352, a material with a high visible-light-transmitting property is preferably used. The pixel electrode contains a material that reflects visible light, and the counter electrode (the common electrode 155) contains a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, one of the source electrode and the drain electrode of the transistor 201 is electrically connected to the FPC 353 through a conductive layer 166 and a connection layer 242. As an example, the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Device 100D]

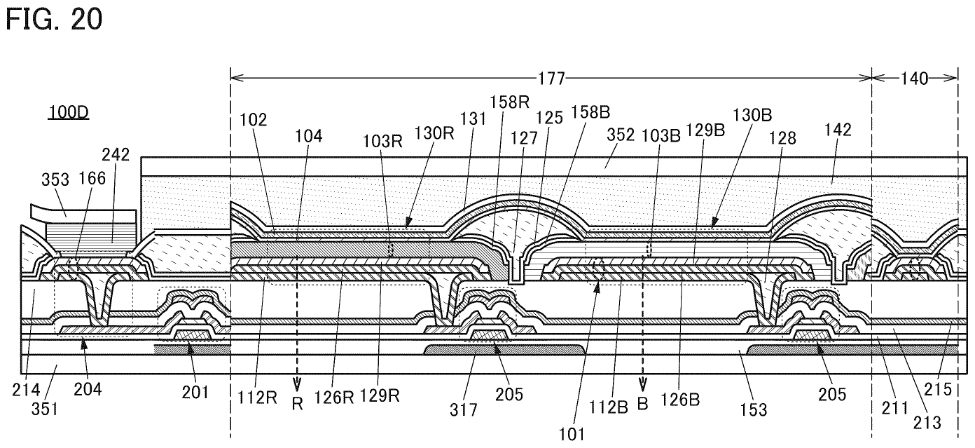

The display device 100D illustrated in FIG. 20 differs from the display device 100C illustrated in FIG. 19 mainly in having a bottom-emission structure.

Light from the light-emitting device is emitted toward the substrate 351. For the substrate 351, a material with a high visible-light-transmitting property is preferably used. By contrast, there is no limitation on the light-transmitting property of a material used for the substrate 352.

A light-blocking layer 317 is preferably formed between the substrate 351 and the transistor 201 and between the substrate 351 and the transistor 205. FIG. 20 illustrates an example in which the light-blocking layer 317 is provided over the substrate 351, an insulating layer 153 is provided over the light-blocking layer 317, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material with a high visible-light-transmitting property is used for each of the conductive layers 112R, 112B, 126R, 126B, 129R, and 129B. A material that reflects visible light is preferably used for the second electrode 102.

Although not illustrated in FIG. 20, the light-emitting device 130G is also provided.

Although FIG. 20 and the like illustrate an example in which the top surface of the layer 128 includes a flat portion, the shape of the layer 128 is not particularly limited.

### [Display Device 100D2]

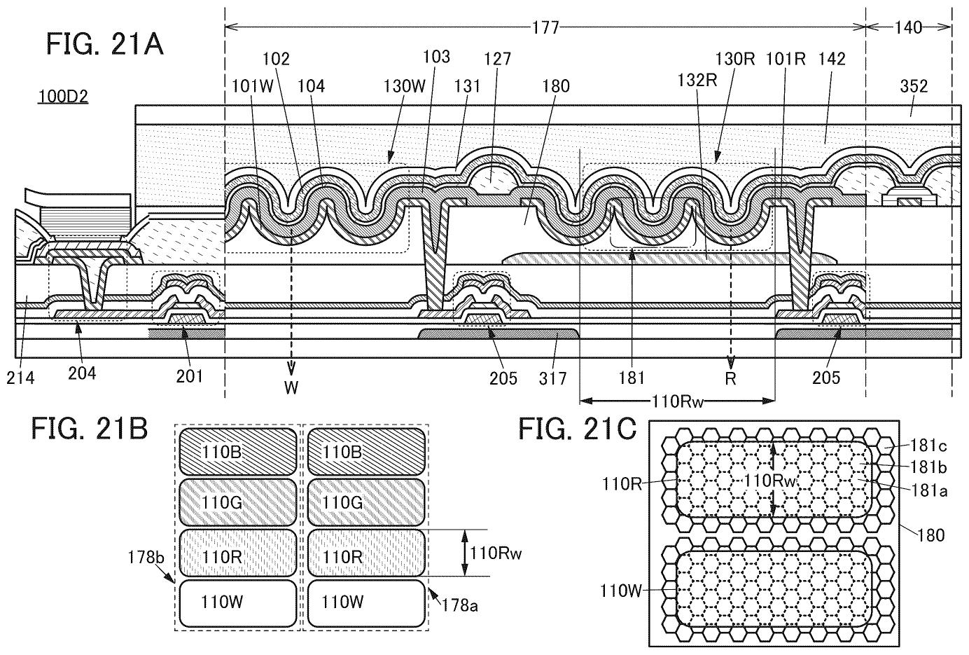

The display device 100D2 illustrated in FIG. 21A is an example of a bottom-emission display device different from the display device 100D illustrated in FIG. 20. The display device 100D2 is different from the display device 100D in including an organic resin layer 180. Note that the reference numerals of the components that are the same as those in FIG. 20 are sometimes omitted and the description for FIG. 20 is referred to for the details of such components.

FIG. 21B is a top-view layout of the pixel 178 (pixels 178a and 178b) including the subpixel 110 (the subpixels 110R, 110G, and 110B and a subpixel 110W), and FIG. 21C is a top view of the organic resin layer 180 in a region where the subpixels 110R and 110G included in the pixel 178 are formed. A region of the subpixel 110R between the light-blocking layers 317 can be represented as a width 110Rw in a light-emitting region.

As illustrated in FIG. 21A, the organic resin layer 180 is provided over the insulating layer 214. As illustrated in FIG. 21C and the region surrounded by the dashed-dotted line in FIG. 21A, the organic resin layer 180 includes a depressed portion 181 (depressed portions 181a and 181b) having a curved surface at least in a region where the subpixel is formed. Note that the depressed portion 181 may be provided outside the light-emitting region, like a depressed portion 181c. With the depressed portion 181c, light emission caused in a region overlapping with the light-blocking layer 317 or light travelled into the region overlapping with the light-blocking layer 317 can be refracted and extracted from the light-emitting region, whereby emission efficiency can be improved.

A plurality of depressed portions 181 may be formed in a matrix. The depressed portions 181a and 181b may be provided in contact with each other or may be provided to have a flat surface therebetween.

In FIGS. 21A to 21C, although the top surface shape and the cross-sectional shape of the depressed portion are hexagonal (FIG. 21C) and semicircular (FIG. 21A), respectively, other shapes may be employed as needed. Examples of the top surface shape of the depressed portion include polygons such as a triangle, a tetragon (including a rectangle and a square), and a pentagon; polygons with rounded corners; an ellipse; and a circle.

An insulating layer containing an organic material can be used as the organic resin layer 180. Examples of materials used for the organic resin layer 180 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. The organic resin layer 180 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

A photosensitive resin can also be used for the organic resin layer 180. A photoresist may be used for the photosensitive resin. As the photosensitive resin, a positive photosensitive material or a negative photosensitive material can be used.

The organic resin layer 180 may contain a material absorbing visible light. For example, the organic resin layer 180 itself may be made of a material absorbing visible light, or the organic resin layer 180 may contain a pigment absorbing visible light. For example, the organic resin layer 180 can be formed using a resin that can be used as a color filter transmitting red, blue, or green light and absorbing light of the other colors; or a resin that contains carbon black as a pigment and functions as a black matrix.

The first electrode 101 (the first electrode 101R and a first electrode 101W) is over the organic resin layer 180 and the organic compound layer 103 is over the first electrode 101. End portions of the first electrode 101 and the organic compound layer 103 may be covered with the insulating layer 127.

The first electrode 101 formed over the organic resin layer 180 also has a depressed portion along the depressed portion of the organic resin layer 180. The organic compound layer 103 formed over the first electrode 101 also has a depressed portion along the depressed portion of the first electrode 101. The common layer 104 formed over the organic compound layer 103 also has a depressed portion along the depressed portion of the organic compound layer 103. The second electrode 102 formed over the common layer 104 also has a depressed portion along the depressed portion of the common layer 104. That is, the depressed portions of the organic resin layer 180, the first electrode 101, the organic compound layer 103, the common layer 104, and the second electrode 102 overlap with each other.

The common layer 104 is provided over the organic compound layer 103 and the insulating layer 127, and the second electrode 102 is provided over the common layer 104. The protective layer 131 is provided over the second electrode 102 and bonded to the substrate 352 with the adhesive layer 142 therebetween.

Although the light-emitting devices 130G and 130B are not illustrated in FIGS. 21A to 21C, the light-emitting devices 130G and 130B are also provided.

The light-emitting apparatus of one embodiment of the present invention including the above-described organic resin layer 180 includes the organic compound represented by General Formula (G1-1) in the organic compound layer 103 as described in Embodiment 1, whereby an organic semiconductor device with high emission efficiency, high reliability, a low driving voltage, and low power consumption can be provided owing to an indivisible effect of the organic resin layer 180 and the organic compound of the present application.

The light-emitting apparatus of one embodiment of the present invention including the above-described organic resin layer 180 includes the organic compound represented by General Formula (G1-2) in the organic compound layer 103 as described in Embodiment 1, whereby an organic semiconductor device with high emission efficiency, high reliability, a low driving voltage, and low power consumption can be provided owing to an indivisible effect of the organic resin layer 180 and the organic compound of the present application.

The light-emitting apparatus of one embodiment of the present invention including the above-described organic resin layer 180 includes the organic compound represented by General Formula (G1-1) and the organic compound represented by General Formula (G1-2) in the organic compound layer 103 as described in Embodiment 1, whereby an organic semiconductor device with high emission efficiency, high reliability, a low driving voltage, and low power consumption can be provided owing to an indivisible effect of the organic resin layer 180 and the organic compound of the present application.

### [Display Device 100E]

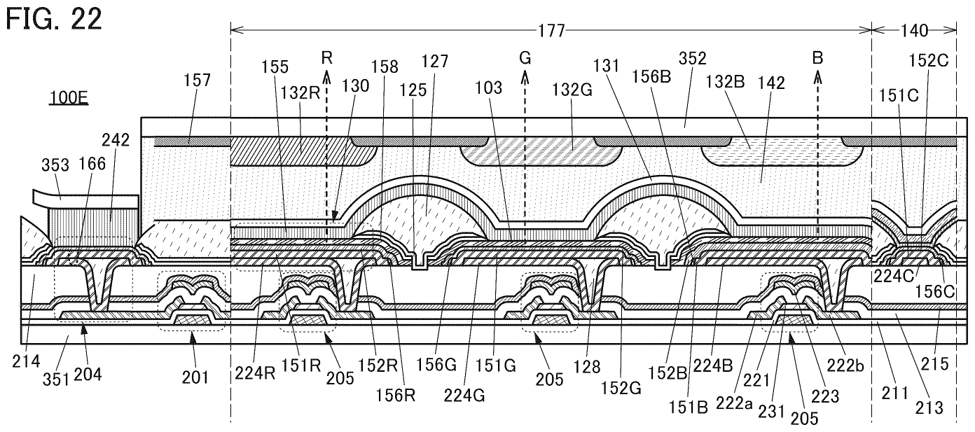

The display device 100E illustrated in FIG. 22 is a variation example of the display device 100C illustrated in FIG. 19 and differs from the display device 100C mainly in including the coloring layers 132R, 132G, and 132B.

In the display device 100E, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-blocking layer 157.

In the display device 100E, the light-emitting device 130 can emit white light, for example. The coloring layer 132R, the coloring layer 132G, and the coloring layer 132B can transmit red light, green light, and blue light, respectively, for example. Note that in the display device 100E, the coloring layers 132R, 132G, and 132B may be provided between the protective layer 131 and the adhesive layer 142.

### [Display Device 100E2]

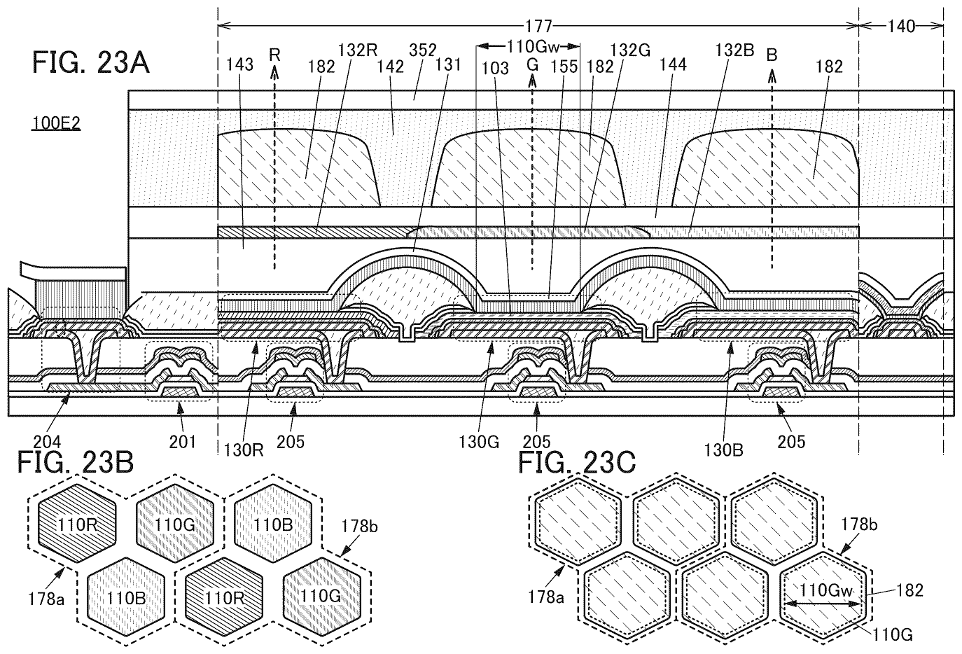

The display device 100E2 illustrated in FIG. 23A is a variation example of the display device 100E illustrated in FIG. 22 and includes microlenses 182 over the coloring layers 132R, 132G, and 132B. Note that the reference numerals of the components that are the same as those in FIG. 22 are sometimes omitted and the description for FIG. 22 is referred to for the details of such components.

FIG. 23B is a top-view layout of the pixel 178 (the pixels 178a and 178b) including the subpixel 110 (the subpixels 110R, 110G, and 110B), and FIG. 23C is a top view of the microlens 182 in a region where the subpixels 110R and 110G included in the pixel 178 are formed. A region of the subpixel 110G where the common electrode 155 and the EL layer 103 are in contact with each other can be represented as a width 110Gw in a light-emitting region.

In the display device 100E2 illustrated in FIG. 23A, a planarization film 143 is provided over the protective layer 131, and the coloring layers 132R, 132G, and 132B are provided over a planarization film 144. The planarization film 144 is provided to cover the coloring layers 132R, 132G, and 132B. The microlenses 182 are provided over the planarization film 144.

Note that as illustrated in FIG. 23C, the microlens 182 is preferably provided for each of the subpixels in a region where the subpixel is formed.

Although the top surface shape of the microlens 182 is illustrated as a hexagon in FIG. 23C, other shapes may be employed as needed. Examples of the top surface shape of the depressed portion include polygons such as a triangle, a tetragon (including a rectangle and a square), and a pentagon; polygons with rounded corners; an ellipse; and a circle.

The microlens 182 can be formed using a material similar to that for the organic resin layer 180.

The light-emitting apparatus of one embodiment of the present invention including the above-described microlens 182 includes the organic compound represented by General Formula (G1-1) in the organic compound layer 103 as described in Embodiment 1, whereby an organic semiconductor device with high emission efficiency, high reliability, a low driving voltage, and low power consumption, which is suitable for a mobile display, can be provided owing to an indivisible effect of the microlens 182 and the organic compound of the present application.

The light-emitting apparatus of one embodiment of the present invention including the above-described microlens 182 includes the organic compound represented by General Formula (G1-2) in the organic compound layer 103 as described in Embodiment 1, whereby an organic semiconductor device with high emission efficiency, high reliability, a low driving voltage, and low power consumption, which is suitable for a mobile display, can be provided owing to an indivisible effect of the microlens 182 and the organic compound of the present application.

The light-emitting apparatus of one embodiment of the present invention including the above-described microlens 182 includes the organic compound represented by General Formula (G1-1) and the organic compound represented by General Formula (G1-2) in the organic compound layer 103 as described in Embodiment 1, whereby an organic semiconductor device with high emission efficiency, high reliability, a low driving voltage, and low power consumption, which is suitable for a mobile display, can be provided owing to an indivisible effect of the microlens 182 and the organic compound of the present application.

This embodiment can be combined as appropriate with the other embodiments or the examples. In this specification, in the case where a plurality of structure examples are shown in one embodiment, the structure examples can be combined as appropriate.

### Embodiment 6

In this embodiment, electronic devices of embodiments of the present invention will be described.

Electronic devices of this embodiment include the light-emitting apparatus of one embodiment of the present invention in their display portions. The light-emitting apparatus of one embodiment of the present invention is highly reliable and can be easily increased in resolution and definition. Thus, the light-emitting apparatus of one embodiment of the present invention can be used for display portions of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook personal computers, a monitor of a computer and the like, digital signage, and a large game machine such as a pachinko machine.

In particular, the light-emitting apparatus of one embodiment of the present invention can have high resolution, and thus can be favorably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and a mixed reality (MR) device.

The definition of the light-emitting apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, definition of 4K, 8K, or higher is preferable. The pixel density (resolution) of the light-emitting apparatus of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, and yet further preferably higher than or equal to 7000 ppi. With such a light-emitting apparatus having one or both of high definition and high resolution, the electronic device can provide higher realistic sensation, sense of depth, and the like. There is no particular limitation on the screen ratio (aspect ratio) of the light-emitting apparatus of one embodiment of the present invention. For example, the light-emitting apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device in this embodiment can have a function of displaying a variety of data (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

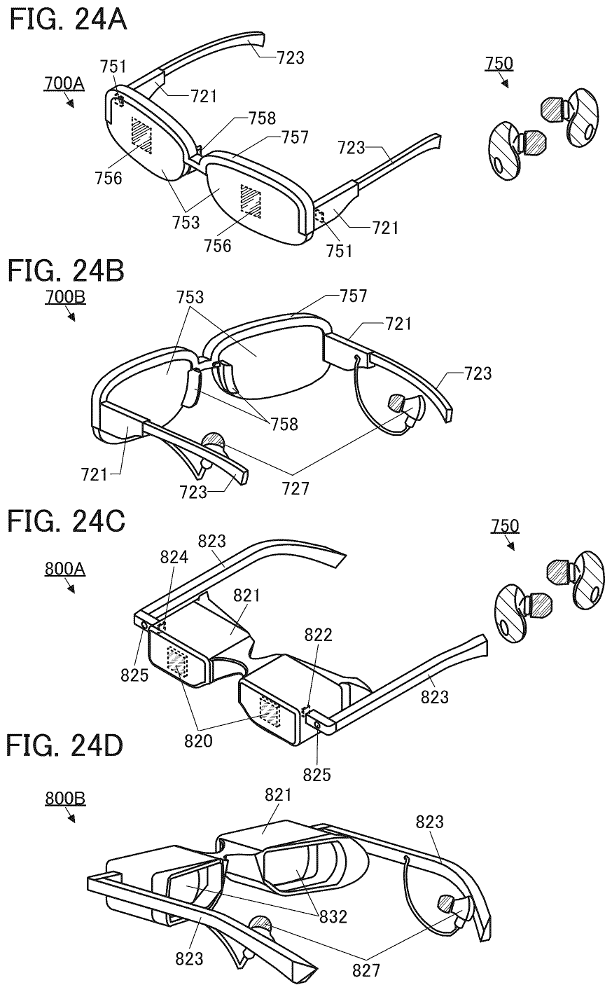

Examples of head-mounted wearable devices are described with reference to FIGS. 24A to 24D. These wearable devices have at least one of a function of displaying AR contents, a function of displaying VR contents, a function of displaying substitutional reality (SR) contents, and a function of displaying MR contents. The electronic device having a function of displaying contents of at least one of AR, VR, SR, MR, and the like enables the user to feel a higher level of immersion.

An electronic device 700A illustrated in FIG. 24A and an electronic device 700B illustrated in FIG. 24B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The light-emitting apparatus of one embodiment of the present invention can be used for the display panels 751. Thus, a highly reliable electronic device is obtained.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic devices 700A and 700B are electronic devices capable of AR display.

In the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic devices 700A and 700B are provided with a battery, so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving element. One or both of an inorganic semiconductor and an organic semiconductor can be used for an active layer of the photoelectric conversion device.

An electronic device 800A illustrated in FIG. 24C and an electronic device 800B illustrated in FIG. 24D each include a pair of display portions 820, a housing 821, a communication portion 822, a pair of wearing portions 823, a control portion 824, a pair of image capturing portions 825, and a pair of lenses 832.

The light-emitting apparatus of one embodiment of the present invention can be used in the display portions 820. Thus, a highly reliable electronic device is obtained.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR. The user who wears the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be mounted on the user's head with the wearing portions 823. FIG. 24C, for instance, shows an example in which the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example in which the image capturing portions 825 are provided is shown here, a range sensor (hereinafter also referred to as a sensing portion) capable of measuring the distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic device 800A.

The electronic devices 800A and 800B may each include an input terminal. To the input terminal, a cable for supplying a video signal from a video output device or the like, power for charging a battery provided in the electronic devices, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 24A has a function of transmitting information to the earphones 750 with the wireless communication function. As another example, the electronic device 800A in FIG. 24C has a function of transmitting information to the earphones 750 with the wireless communication function.

The electronic device may include an earphone portion. The electronic device 700B in FIG. 24B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B in FIG. 24D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferred because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 700A and 700B) and the goggles-type device (e.g., the electronic devices 800A and 800B) are preferable as the electronic device of one embodiment of the present invention.

The electronic device of one embodiment of the present invention can transmit information to earphones by wire or wirelessly.

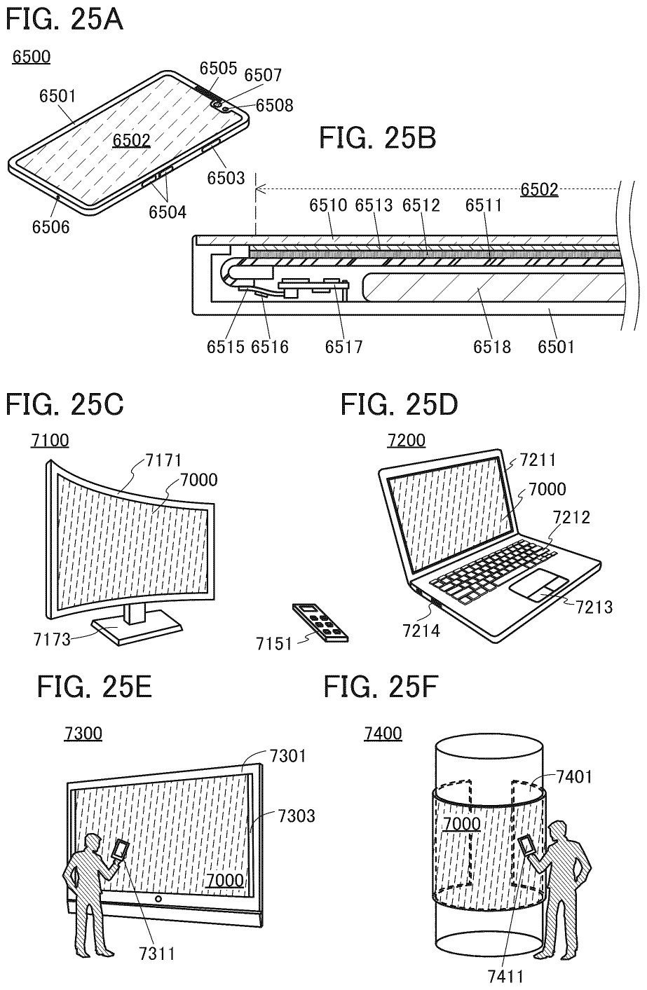

An electronic device 6500 illustrated in FIG. 25A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The light-emitting apparatus of one embodiment of the present invention can be used in the display portion 6502. Thus, a highly reliable electronic device is obtained.

FIG. 25B is a schematic cross-sectional view including an edge portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The light-emitting apparatus of one embodiment of the present invention can be used in the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 25C illustrates an example of a television device. In a television device 7100, a display portion 7000 is incorporated in a housing 7171. Here, the housing 7171 is supported by a stand 7173.

The light-emitting apparatus of one embodiment of the present invention can be used in the display portion 7000. Thus, a highly reliable electronic device is obtained.

Operation of the television device 7100 illustrated in FIG. 25C can be performed with an operation switch provided in the housing 7171 and a separate remote controller 7151. Alternatively, the display portion 7000 may include a touch sensor, and the television device 7100 may be operated by touch on the display portion 7000 with a finger or the like. The remote controller 7151 may be provided with a display portion for displaying information output from the remote controller 7151. With operation keys or a touch panel of the remote controller 7151, channels and volume can be controlled and images displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 25D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The light-emitting apparatus of one embodiment of the present invention can be used in the display portion 7000. Thus, a highly reliable electronic device is obtained.

FIGS. 25E and 25F illustrate examples of digital signage.

Digital signage 7300 illustrated in FIG. 25E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 25F shows digital signage 7400 attached to a cylindrical pillar 7401. The digital signage 7400 includes the display portion 7000 provided along a curved surface of the pillar 7401.

In FIGS. 25E and 25F, the light-emitting apparatus of one embodiment of the present invention can be used in the display portion 7000. Thus, a highly reliable electronic device is obtained.

A larger area of the display portion 7000 can increase the amount of information that can be provided at a time. The display portion 7000 having a larger area attracts more attention, so that the effectiveness of the advertisement can be increased, for example.

The touch panel is preferably used in the display portion 7000, in which case in addition to display of still or moving images on the display portion 7000, intuitive operation by a user is possible. Moreover, in the case of an application for providing information such as route information or traffic information, usability can be enhanced by intuitive operation.

As illustrated in FIGS. 25E and 25F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

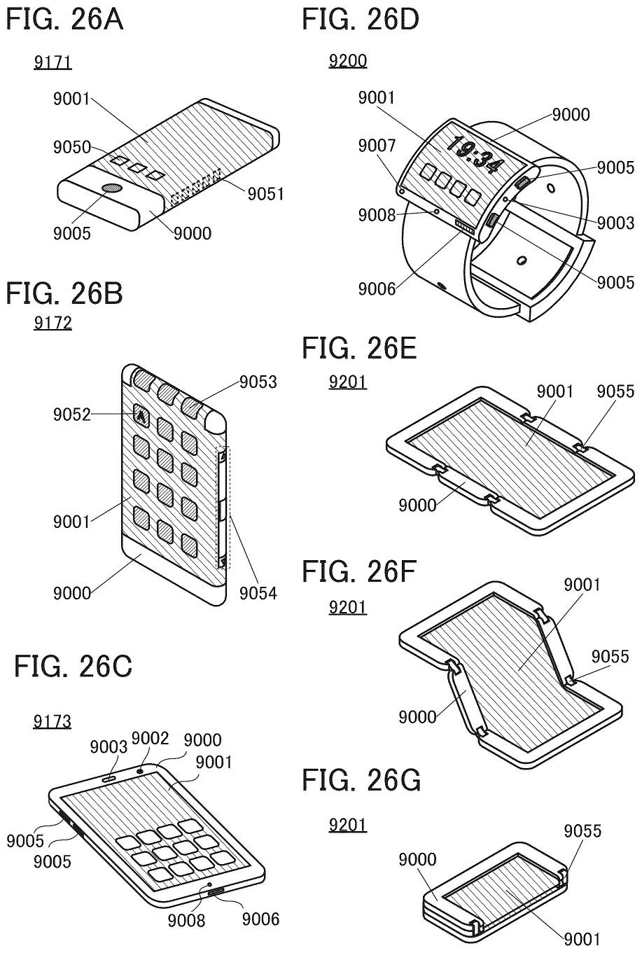

Electronic devices illustrated in FIGS. 26A to 26G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic devices illustrated in FIGS. 26A to 26G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of taking a still image or a moving image, a function of storing the taken image in a storage medium (an external storage medium or a storage medium incorporated in the camera), a function of displaying the taken image on the display portion, and the like.

The electronic devices in FIGS. 26A to 26G are described in detail below.

FIG. 26A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 26A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 26B is a perspective view of a portable information terminal 9172. The portable information terminal 9172 has a function of displaying information on three or more surfaces of the display portion 9001. Here, information 9052, information 9053, and information 9054 are displayed on different surfaces. For example, the user of the portable information terminal 9172 can check the information 9053 displayed such that it can be seen from above the portable information terminal 9172, with the portable information terminal 9172 put in a breast pocket of his/her clothes. Thus, the user can see the display without taking out the portable information terminal 9172 from the pocket and decide whether to answer the call, for example.

FIG. 26C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 26D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 26E to 26G are perspective views of a foldable portable information terminal 9201. FIG. 26E is a perspective view showing the portable information terminal 9201 that is opened. FIG. 26G is a perspective view showing the portable information terminal 9201 that is folded. FIG. 26F is a perspective view showing the portable information terminal 9201 that is shifted from one of the states in FIGS. 26E and 26G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

This embodiment can be combined as appropriate with any of the other embodiments or examples. In this specification, in the case where a plurality of structure examples are shown in one embodiment, the structure examples can be combined as appropriate.

### Example 1

In this example, a light-emitting device 1C, a light-emitting device 1D, a light-emitting device 1E, and a light-emitting device 1F, each of which includes the organic compound of one embodiment of the present invention in an electron-injection layer, a light-emitting device 1A for comparison, which includes no electron-injection layer, and a light-emitting device 1B, which includes an organic compound for comparison in an electron-injection layer, were fabricated and the characteristics thereof were measured. The light-emitting devices were fabricated through a process (MML process) including processing such as exposure to the air and etching.

Structural formulae of organic compounds used for the light-emitting devices 1A to 1F are shown below.

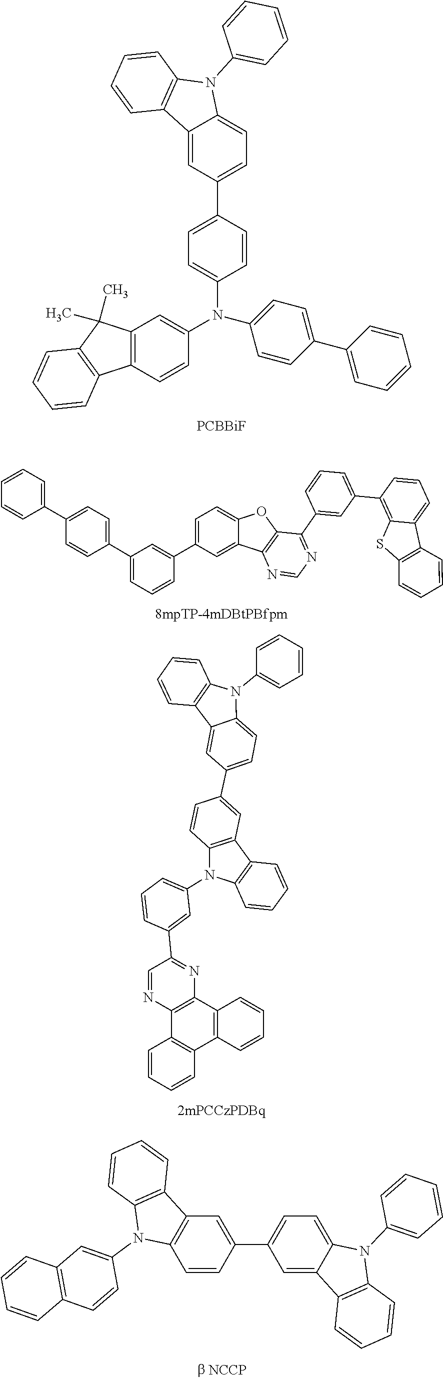

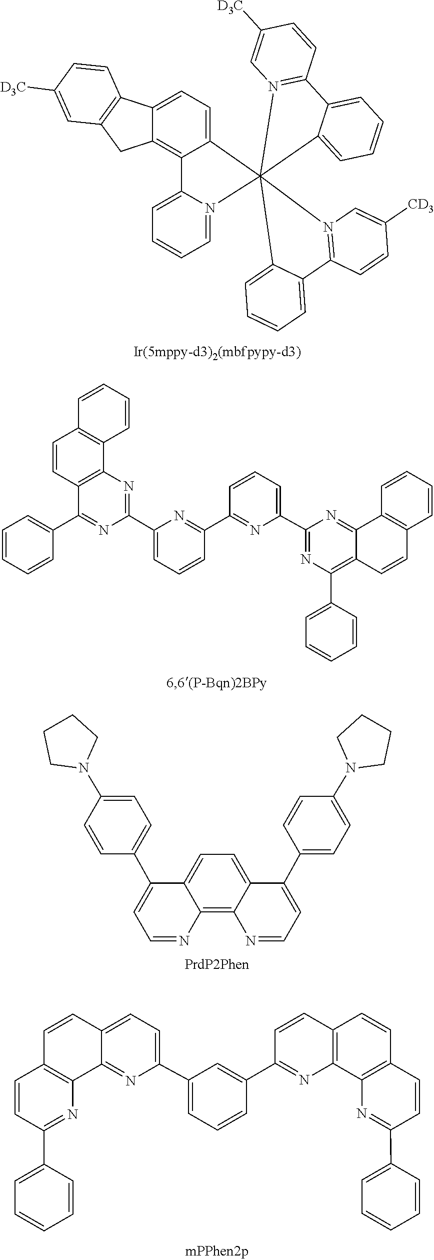

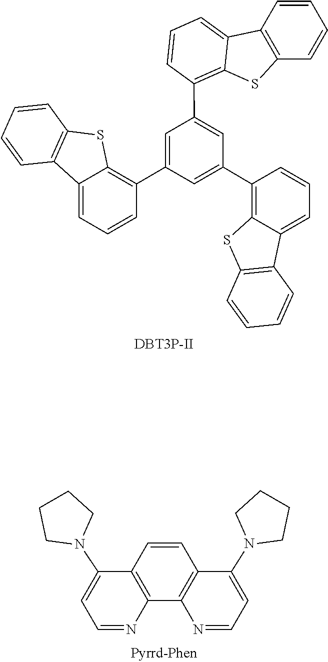 [SMILES: c1ccc2c(c1)sc1c(-c3cc(-c4cccc5c4sc4ccccc45)cc(-c4cccc5c4sc4ccccc45)c3)cccc12 ; "DBT3P-II" ; c1cc(N2CCCC2)c2ccc3c(N4CCCC4)ccnc3c2n1]

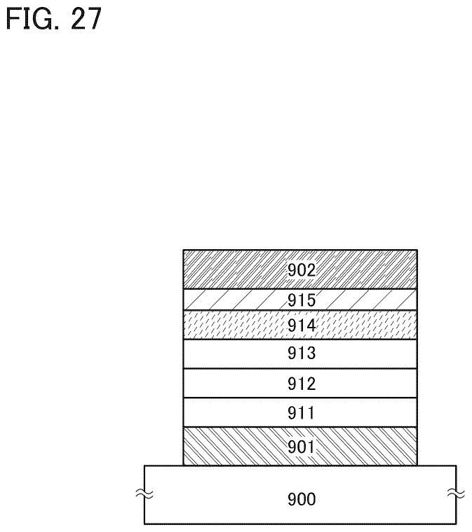

As illustrated in FIG. 27, the light-emitting devices each have a structure in which a hole-injection layer 911, a hole-transport layer 912, a light-emitting layer 913, an electron-transport layer 914, and an electron-injection layer 915 are stacked in this order over a first electrode 901 formed over a substrate 900, which is a glass substrate, and a second electrode 902 is stacked over the electron-injection layer 915.

### <Method for Fabricating Light-Emitting Device 1A>

Over the substrate 900, an alloy of silver, palladium, and copper (also referred to as Ag—Pd—Cu or APC) was formed to a thickness of 100 nm and then ITSO was formed over the APC film to a thickness of 50 nm, whereby the first electrode 901 was formed. The ITSO film is a conductive film having a function of transmitting light, and the APC film is a conductive film having functions of reflecting light and transmitting light. Note that the electrode area was set to 4 mm² (2 mm×2 mm).

Next, in pretreatment for forming the light-emitting device over the substrate, a surface of the substrate was washed with water and baking was performed at 200° C. for 1 hour. Then, the substrate was transferred into a vacuum evaporation apparatus where the internal pressure was reduced to approximately 1×10⁻⁴ Pa, and vacuum baking was performed at 170° C. for 30 minutes in a heating chamber of the vacuum evaporation apparatus. After that, natural cooling was performed to lower than or equal to 30° C.

Then, the substrate provided with the first electrode 901 was fixed to a substrate holder provided in the vacuum evaporation apparatus such that the surface on which the first electrode 901 was formed faced downward. Over the first electrode, N-(biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron acceptor material with a molecular weight of 672 (OCHD-003) were deposited by co-evaporation to a thickness of 10 nm such that the weight ratio of PCBBiF to OCHD-003 was 1:0.03, whereby the hole-injection layer 911 was formed.

Next, over the hole-injection layer 911, PCBBiF was deposited to a thickness of 95 nm by evaporation, whereby the hole-transport layer 912 was formed.

Then, over the hole-transport layer 912, 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm), 9-(2-naphthyl)-9′-phenyl-9H,9′H-3,3′-bicarbazole (abbreviation: PNCCP), and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) were deposited by co-evaporation using a resistance-heating method to a thickness of 40 nm such that the weight ratio of 8mpTP-4mDBtPBfpm, βNCCP, and Ir(5mppy-d₃)₂(mbfpypy-d₃) was 0.5:0.5:0.10, whereby the light-emitting layer 913 was formed.

Next, over the light-emitting layer 913, 2-{3-[3-(N-phenyl-9H-carbazol-3-yl)-9H-carbazol-9-yl]phenyl}dibenzo[f,h]quinoxaline (abbreviation: 2mPCCzPDBq) was deposited to a thickness of 20 nm by evaporation, and then 2,2′-(1,3-phenylene)bis(9-phenyl-1,10-phenanthroline) (abbreviation: mPPhen2P) was deposited to a thickness of 20 nm by evaporation, whereby the electron-transport layer 814 was formed.

Here, the substrate 900 was exposed to the air, then an aluminum oxide (AlOₓ) film was deposited to a thickness of 30 nm by an ALD method, and molybdenum (Mo) was deposited to a thickness of 50 nm by a sputtering method. After that, a resist was formed using a photoresist, and the molybdenum was processed into a predetermined shape by a lithography method. Specifically, a slit with a width of 3 μm was formed at a position 3.5 μm away from the end portion of the first electrode 901.

Next, using the molybdenum as a mask, the stacked-layer structure formed of the aluminum oxide film, the hole-injection layer 911, the hole-transport layer 912, the light-emitting layer 913, and the electron-transport layer 914 was processed into a predetermined shape. After that, the molybdenum was removed by a dry etching method, and then the aluminum oxide film was removed. The aluminum oxide film was removed by wet etching using an acidic chemical solution.

Then, heat treatment was performed at 100° C. for 1 hour in a vacuum where the internal pressure was reduced to approximately 1×10⁻⁴ Pa. The heat treatment can remove moisture or the like attached by the above-described processing, the exposure to the air, or the like.

Then, over the electron-transport layer, silver (Ag) and magnesium (Mg) were deposited by co-evaporation to a thickness of 15 nm such that the volume ratio of Ag to Mg was 1:0.1, whereby the second electrode was formed.

Next, over the second electrode, DBT3P-II was deposited to a thickness of 70 nm by an evaporation method using resistance heating, whereby a cap layer was formed.

### <Method for Fabricating Light-Emitting Device 1B>

Next, a method for fabricating the light-emitting device 1B is described.

The light-emitting device 1B is different from the light-emitting device 1A in the thickness of the electron-transport layer 914, the formation of the electron-injection layer 915 over the electron-transport layer 914, the processing of the electron-injection layer 915 into a predetermined shape after the formation, and the formation of the second electrode over the electron-injection layer 915. That is, in the light-emitting device 1B, over the light-emitting layer 913, 2mPCCzPDBq was deposited by evaporation to a thickness of 20 nm, and then mPPhen2P was deposited by evaporation to a thickness of 15 nm, whereby the electron-transport layer 914 was formed. Next, over the electron-transport layer 914, mPPhen2P and lithium oxide (Li₂O) were deposited by co-evaporation to a thickness of 5 nm such that the volume ratio of mPPhen2P to Li₂O was 1:0.02, whereby the electron-injection layer 915 was formed.

After that, exposure to the air was performed, and a stacked-layer structure including the hole-injection layer 911, the hole-transport layer 912, the light-emitting layer 913, the electron-transport layer 914, and the electron-injection layer 915 was processed into a predetermined shape through a process similar to that for the light-emitting device 1A. Then, after heat treatment was performed at 100° C. for 1 hour in a vacuum where the internal pressure was reduced to approximately 1×10⁻⁴ Pa, silver (Ag) and magnesium (Mg) were deposited by co-evaporation to a thickness of 15 nm such that the volume ratio of Ag to Mg was 1:0.1, whereby the second electrode was formed.

Other components were fabricated in a manner similar to that for the light-emitting device 1A.

### <Method for Fabricating Light-Emitting Device 1C>

Next, a method for fabricating the light-emitting device 1C is described.

The light-emitting device 1C is different from the light-emitting device 1B in the structure of the electron-injection layer 915. That is, the electron-injection layer 915 in the light-emitting device 1C was formed in the following manner: 2,2′-(2,2′-bipyridine-6,6′-diyl)bis(4-phenylbenzo[h]quinazoline) (abbreviation: 6,6′(P-Bqn)2BPy), 4,7-di-1-pyrrolidinyl-1,10-phenanthroline (abbreviation: Pyrrd-Phen), and lithium oxide (Li₂O) were deposited by co-evaporation over the electron-transport layer 914 to a thickness of 5 nm such that the volume ratio of 6,6′(P-Bqn)₂Bpy, Pyrrd-Phen, and Li₂O was 0.5:0.5:0.02.

After that, exposure to the air was performed, and a stacked-layer structure including the hole-injection layer 911, the hole-transport layer 912, the light-emitting layer 913, the electron-transport layer 914, and the electron-injection layer 915 was processed into a predetermined shape through a process similar to that for the light-emitting device 1B.

Other components were fabricated in a manner similar to that for the light-emitting device 1B.

### <Method for Fabricating Light-Emitting Device 1D>

Next, a method for fabricating the light-emitting device 1D is described.

The light-emitting device 1D is different from the light-emitting device 1B in the structure of the electron-injection layer 915. That is, the electron-injection layer 915 in the light-emitting device 1D was formed in the following manner: 6,6′(P-Bqn)2BPy, Pyrrd-Phen, and silver (Ag) were deposited by co-evaporation over the electron-transport layer 914 to a thickness of 5 nm such that the volume ratio of 6,6′(P-Bqn)2Bpy, Pyrrd-Phen, and Ag is 0.5:0.5:0.02.

After that, exposure to the air was performed, and a stacked-layer structure including the hole-injection layer 911, the hole-transport layer 912, the light-emitting layer 913, the electron-transport layer 914, and the electron-injection layer 915 was processed into a predetermined shape through a process similar to that for the light-emitting device 1B.

Other components were fabricated in a manner similar to that for the light-emitting device 1B.

### <Method for Fabricating Light-Emitting Device 1E>

Next, a method for fabricating the light-emitting device 1E is described.

The light-emitting device 1E is different from the light-emitting device 1B in the structure of the electron-injection layer 915. That is, the electron-injection layer 915 in the light-emitting device 1E was formed in the following manner: 6,6′(P-Bqn)2BPy, 4,7-bis(4-(1-pyrrolidinyl)phenyl)-1,10-phenanthroline (abbreviation: PrdP2Phen), and silver (Ag) were deposited by co-evaporation over the electron-transport layer 914 to a thickness of 5 nm such that the volume ratio of 6,6′(P-Bqn)2Bpy, PrdP2Phen, and Ag is 0.5:0.5:0.02.

After that, exposure to the air was performed, and a stacked-layer structure including the hole-injection layer 911, the hole-transport layer 912, the light-emitting layer 913, the electron-transport layer 914, and the electron-injection layer 915 was processed into a predetermined shape through a process similar to that for the light-emitting device 1B.

Other components were fabricated in a manner similar to that for the light-emitting device 1B.

<Method for Fabricating Light-Emitting Device 1F>

Next, a method for fabricating the light-emitting device 1F is described.

The light-emitting device 1F is different from the light-emitting device 1B in the structure of the electron-injection layer 915. That is, the electron-injection layer 915 in the light-emitting device 1F was formed in the following manner: 6,6′(P-Bqn)2BPy, Pyrrd-Phen, and indium oxide (In₂O₃) were deposited by co-evaporation over the electron-transport layer 914 to a thickness of 5 nm such that the volume ratio of 6,6′(P-Bqn)2Bpy, Pyrrd-Phen, and In₂O₃ is 0.5:0.5:0.02.

After that, exposure to the air was performed, and a stacked-layer structure including the hole-injection layer 911, the hole-transport layer 912, the light-emitting layer 913, the electron-transport layer 914, and the electron-injection layer 915 was processed into a predetermined shape through a process similar to that for the light-emitting device 1B.

Other components were fabricated in a manner similar to that for the light-emitting device 1B.

The structures of the light-emitting devices 1A to 1F are listed in the following table. Note that the structure of the electron-injection layer denoted by 1× in the table is separately shown in Table 7.

TABLE 6

| | | | | | | |
|---|---|---|---|---|---|---|
| Film | Light- | Light- | Light- | Light- | Light- | Light- |
| thickness | emitting | emitting | emitting | emitting | emitting | emitting |
| [nm] | device 1A | device 1B | device 1C | device 1D | device 1E | device 1F |

| | | |
|---|---|---|
| Cap layer | 70 | DBT3P-II |
| Second electrode | 15 | Ag:Mg (1:0.1) |

Processing

| Electron-injection | 5 | 1X |
|---|---|---|
| layer | | |

| Electron-transport | — | mPPhen2P | |
|---|---|---|---|
| layer | | 20 nm | 15 nm |

| | | |
|---|---|---|
| | 20 | 2mPCCzPDBq |
| Light-emitting layer | 40 | 8mpTP-4mDBtPBfpm:βNCCP:Ir(5mppy-d₃)₂(mbfpypy-d₃) |
| | | (0.5:0.5:0.1) |
| Hole-transport layer | 95 | PCBBiF |
| Hole-injection layer | 10 | PCBBiF:OCHD-003 (1:0.03) |
| First electrode | 50 | ITSO |
| | 100 | APC |

TABLE 7

| Device | 1X | |
|---|---|---|
| Light-emitting | — | — |
| device 1A | | |
| (comparison) | | |
| Light-emitting | mPPhen2P:Li₂O | (1:0.02) |
| device 1B | | |
| (comparison) | | |
| Light-emitting | 6,6′(P-Bqn)2BPy:Pyrrd-Phen:Li₂O | (0.5:0.5:0.02) |
| device 1C | | |
| Light-emitting | 6,6′(P-Bqn)2BPy:Pyrrd-Phen:Ag | (0.5:0.5:0.02) |
| device 1D | | |
| Light-emitting | 6,6′(P-Bqn)2BPy:PrdP2Phen:Ag | (0.5:0.5:0.02) |
| device 1E | | |
| Light-emitting | 6,6′(P-Bqn)2BPy:Pyrrd-Phen:In₂O₃ | (0.5:0.5:0.02) |
| device 1F | | |

### <Characteristics of Light-Emitting Devices>

The light-emitting devices were each sealed with a glass substrate in a glove box containing a nitrogen atmosphere so as not to be exposed to the air (a sealing material was applied to surround the devices and UV treatment and heat treatment at 80° C. for 1 hour were performed at the time of sealing).

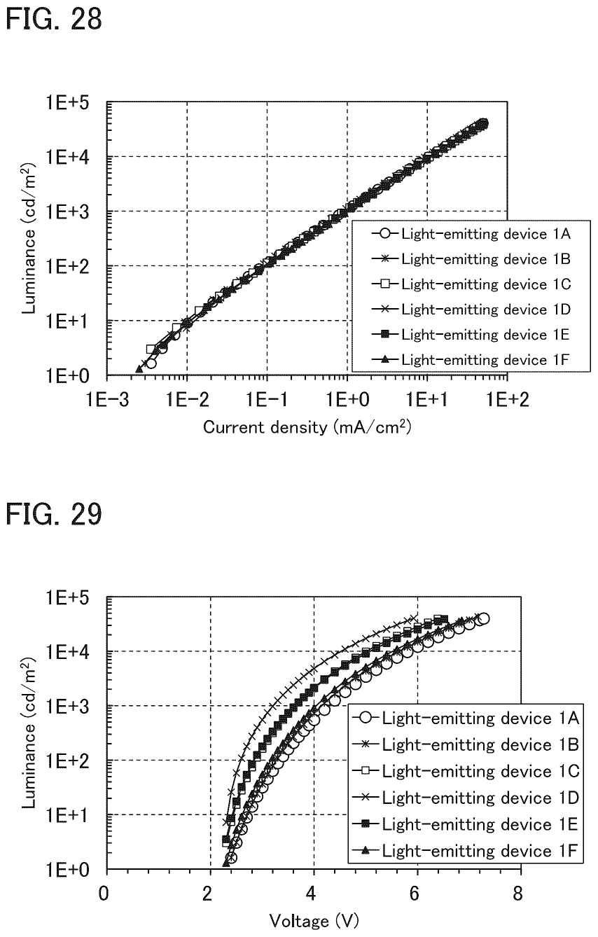

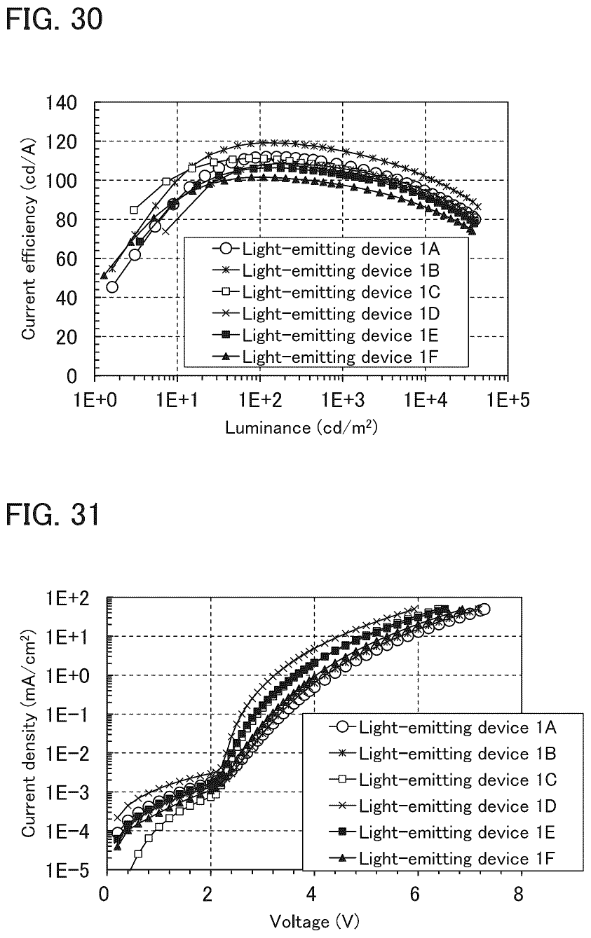

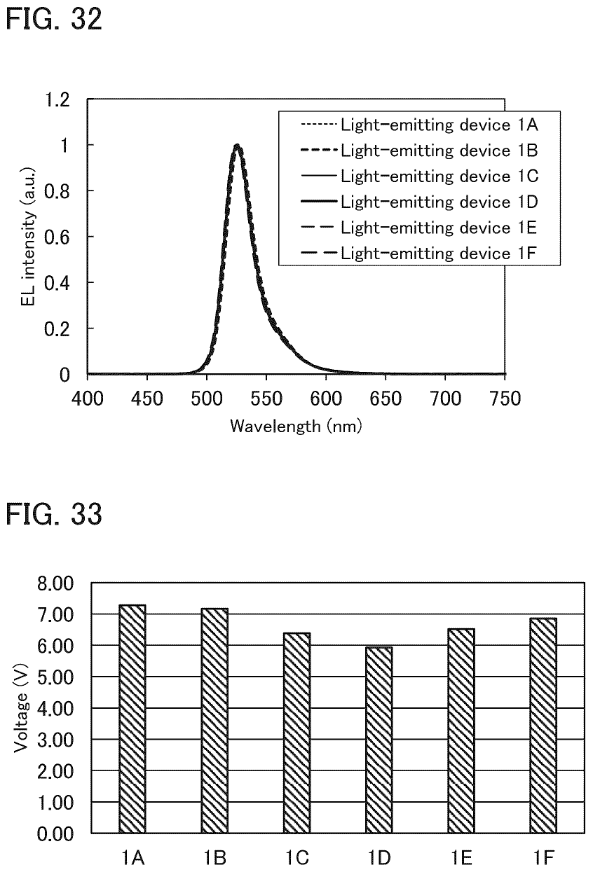

FIG. 28 shows the luminance-current density characteristics of the light-emitting devices, FIG. 29 shows the luminance-voltage characteristics thereof, FIG. 30 shows the current efficiency-luminance characteristics thereof, FIG. 31 shows the current density-voltage characteristics thereof, FIG. 32 shows the electroluminescence spectra thereof, and FIG. 33 shows voltages with respect to a current density of 50 mA/cm².

The following table shows the main characteristics of the light-emitting devices at a luminance of 1000 cd/cm². Note that the luminance, CIE chromaticity, and electroluminescence spectra were measured with a spectroradiometer (SR-UL1R manufactured by TOPCON TECHNOHOUSE CORPORATION).

TABLE 8

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Light-emitting | 4.20 | 0.031 | 0.78 | 0.217 | 0.732 | 843 | 108.4 |
| device 1A | | | | | | | |
| Light-emitting | 4.20 | 0.039 | 0.97 | 0.225 | 0.729 | 1106 | 114.6 |
| device 1B | | | | | | | |
| Light-emitting | 3.60 | 0.034 | 0.86 | 0.215 | 0.732 | 908 | 105.9 |
| device 1C | | | | | | | |
| Light-emitting | 3.20 | 0.037 | 0.91 | 0.219 | 0.731 | 969 | 106.0 |
| device 1D | | | | | | | |
| Light-emitting | 3.60 | 0.036 | 0.90 | 0.218 | 0.731 | 929 | 103.1 |
| device 1E | | | | | | | |
| Light-emitting | 4.00 | 0.037 | 0.94 | 0.211 | 0.733 | 914 | 97.8 |
| device 1F | | | | | | | |

FIGS. 28 to 32 and the above table demonstrate that the light-emitting devices 1C to 1F are each a favorable light-emitting device that is driven at a lower voltage and emits light with higher current efficiency than the light-emitting devices 1A and 1B even through a process exposed to oxygen or water.

According to FIG. 33, in the case where the current density is 50 mA/cm², the light-emitting devices 1C to 1F each including the electron-injection layer of one embodiment of the present invention, which includes a metal, an organic compound having a π-electron deficient heteroaromatic ring, and an organic compound capable of being coordinated to a metal as a multidentate ligand, can be driven at a lower voltage than the light-emitting devices 1A and 1B. In particular, the light-emitting device 1D, which is driven at a voltage lower than or equal to 3.6 V, is found to be a highly efficient device.

Here, thin films containing organic compounds used for the electron-injection layer 915 of the light-emitting device 1C were evaluated by an electron spin resonance (ESR) method.

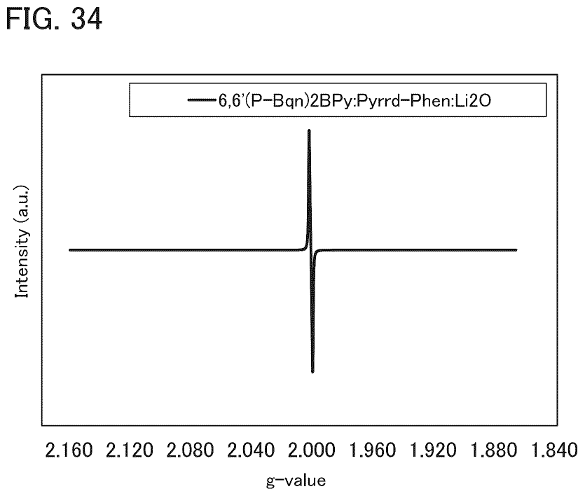

Specifically, a thin film was deposited to a thickness of 100 nm over a quartz substrate by co-evaporation of 6,6′(P-Bqn)2BPy, Pyrrd-Phen, and Li₂O such that the volume ratio of 6,6′(P-Bqn)2Bpy, Pyrrd-Phen, and Li₂O is 0.5:0.5:0.02, and an electron spin resonance spectrum of the thin film was measured at room temperature. Note that the measurement of the electron spin resonance spectrum using an ESR method was performed with an electron spin resonance spectrometer E500 (manufactured by Bruker Corporation). The measurement was performed at room temperature under the conditions where the resonance frequency was 9.56 GHz, the output power was 1 mW, the modulated magnetic field was 50 mT, the modulation width was 0.5 mT, the time constant was 0.04 s, and the sweep time was 1 min. The results are shown in FIG. 34. FIG. 34 shows that a signal was observed at a g-factor of approximately 2.00 and the spin density was 1×10²⁰ spins/cm³. The spin density of 1×10¹⁷ spins/cm³ or higher indicates that efficient interaction is caused between the metal and the organic compound.

### <Reliability Test Result>

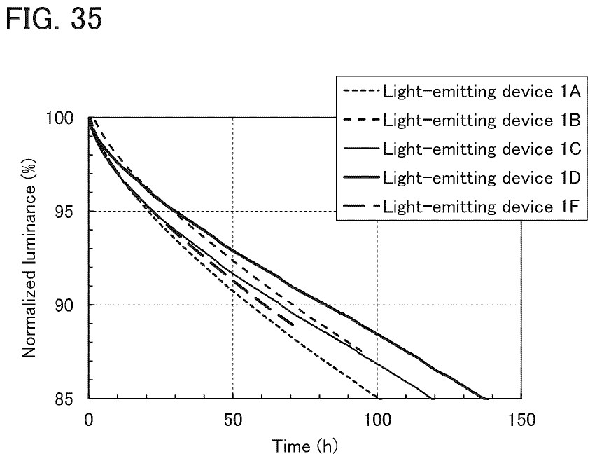

Furthermore, a reliability test was performed on the light-emitting devices 1A to 1D and 1F. FIG. 35 shows a time-dependent change in normalized luminance at the time of constant current density driving (50 mA/cm²). In FIG. 35, the vertical axis represents the luminance (%) normalized with the luminance at the time of the start of emission as 100%, and the horizontal axis represents time (h).

According to FIG. 35, LT90 (h), which is the time that has elapsed until the measured luminance decreases to 90% of the initial luminance, of the light-emitting device 1D is 82 hours, indicating that the light-emitting device 1D has high reliability.

The above shows that a light-emitting device with favorable characteristics can be fabricated by using the structure of the electron-injection layer of one embodiment of the present invention.

### Example 2

In this example, a light-emitting device 2A, which includes the organic compound of one embodiment of the present invention, and a light-emitting device 2B, which includes an organic compound for comparison, were fabricated and the characteristics thereof were measured. The light-emitting devices were fabricated through a process (MML process) including processing such as exposure to the air and etching.

Structural formulae of organic compounds used for the light-emitting devices 2A and 2B are shown below.

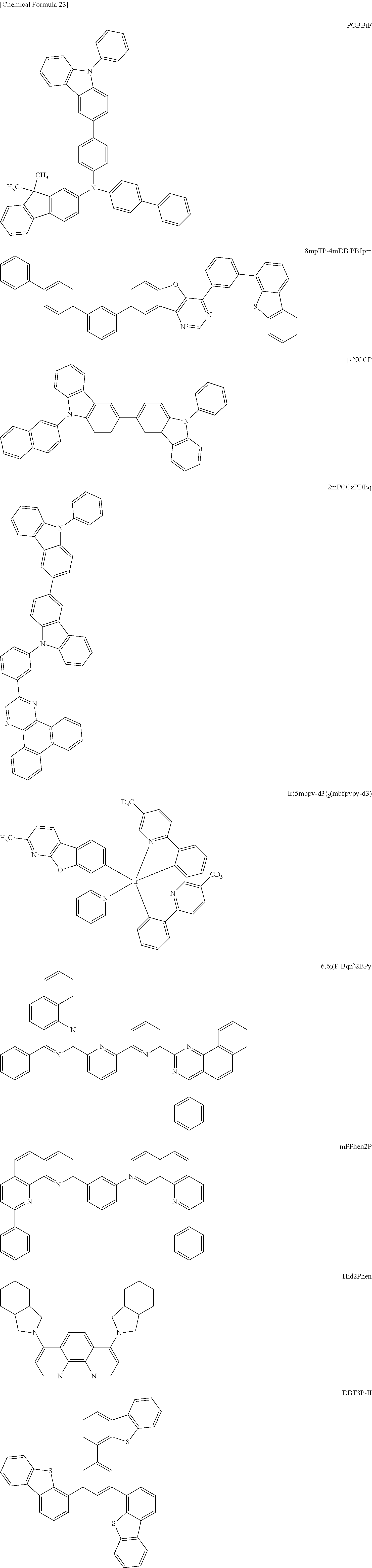

As illustrated in FIG. 27, the light-emitting devices each have a structure in which the hole-injection layer 911, the hole-transport layer 912, the light-emitting layer 913, the electron-transport layer 914, and the electron-injection layer 915 are stacked in this order over the first electrode 901 formed over the substrate 900, which is a glass substrate, and the second electrode 902 is stacked over the electron-injection layer 915.

### <Method for Fabricating Light-Emitting Device 2A>

Over the substrate 900, an alloy of silver, palladium, and copper (also referred to as Ag—Pd—Cu or APC) was formed to a thickness of 100 nm and then ITSO was formed over the APC film to a thickness of 50 nm, whereby the first electrode 901 was formed. The ITSO film is a conductive film having a function of transmitting light, and the APC film is a conductive film having functions of reflecting light and transmitting light. Note that the electrode area was set to 4 mm² (2 mm×2 mm).

Next, in pretreatment for forming the light-emitting device over the substrate, a surface of the substrate was washed with water and baking was performed at 200° C. for 1 hour. Then, the substrate was transferred into a vacuum evaporation apparatus where the internal pressure was reduced to approximately 1×10⁻⁴ Pa, and vacuum baking was performed at 170° C. for 30 minutes in a heating chamber of the vacuum evaporation apparatus. After that, natural cooling was performed to lower than or equal to 30° C.

Then, the substrate provided with the first electrode 901 was fixed to a substrate holder provided in the vacuum evaporation apparatus such that the surface on which the first electrode 901 was formed faced downward. Over the first electrode, N-(biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron acceptor material with a molecular weight of 672 (OCHD-003) were deposited by co-evaporation to a thickness of 10 nm such that the weight ratio of PCBBiF to OCHD-003 was 1:0.03, whereby the hole-injection layer 911 was formed.

Next, over the hole-injection layer 911, PCBBiF was deposited to a thickness of 100 nm by evaporation, whereby the hole-transport layer 912 was formed.

Then, over the hole-transport layer 912, 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm), 9-(2-naphthyl)-9′-phenyl-9H,9′H-3,3′-bicarbazole (abbreviation: PNCCP), and [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)) were deposited by co-evaporation using a resistance-heating method to a thickness of 40 nm such that the weight ratio of 8mpTP-4mDBtPBfpm, PNCCP, and Ir(5mppy-d₃)₂(mbfpypy-d₃) was 0.5:0.5:0.10, whereby the light-emitting layer 913 was formed.

Next, over the light-emitting layer 913, 2-{3-[3-(N-phenyl-9H-carbazol-3-yl)-9H-carbazol-9-yl]phenyl}dibenzo[f,h]quinoxaline (abbreviation: 2mPCCzPDBq) was deposited to a thickness of 20 nm by evaporation, and then 2,2′-(2,2′-bipyridine-6,6′-diyl)bis(4-phenylbenzo[h]quinazoline) (abbreviation: 6,6′(P-Bqn)2BPy) was deposited to a thickness of 15 nm by evaporation, whereby the electron-transport layer 914 was formed.

Here, the substrate 900 was exposed to the air, then an aluminum oxide (AlOₓ) film was deposited to a thickness of 30 nm by an ALD method, and molybdenum (Mo) was deposited to a thickness of 50 nm by a sputtering method. After that, a resist was formed using a photoresist, and the molybdenum was processed into a predetermined shape by a lithography method. Specifically, a slit with a width of 3 μm was formed at a position 3.5 μm away from the end portion of the first electrode 901.

Next, using the molybdenum as a mask, the stacked-layer structure formed of the aluminum oxide film, the hole-injection layer 911, the hole-transport layer 912, the light-emitting layer 913, and the electron-transport layer 914 was processed into a predetermined shape. After that, the molybdenum was removed by a dry etching method, and then the aluminum oxide film was removed. The aluminum oxide film was removed by wet etching using an acidic chemical solution.

Then, heat treatment was performed at 100° C. for 1 hour in a vacuum where the internal pressure was reduced to approximately 1×10⁻⁴ Pa. The heat treatment can remove moisture or the like attached by the above-described processing, the exposure to the air, or the like.

Next, the electron-injection layer 915 was formed over the electron-transport layer 914 in the following manner: 2,2′-(2,2′-bipyridine-6,6′-diyl)bis(4-phenylbenzo[h]quinazoline) (abbreviation: 6,6′(P-Bqn)2BPy), 4,7-di(2,3,3a,4,5,6,7,7a-octahydro-1H-isoindol-2-yl)-1,10-phenanthroline (abbreviation: Hid2Phen), and lithium oxide (Li₂O) were deposited by co-evaporation over the electron-transport layer 914 to a thickness of 5 nm such that the volume ratio of 6,6′(P-Bqn)₂Bpy, Hid2Phen, and LizO is 0.5:0.5:0.02.

Then, over the electron-injection layer 915, silver (Ag) and magnesium (Mg) were deposited by co-evaporation to a thickness of 15 nm such that the volume ratio of Ag to Mg was 1:0.1, whereby the second electrode was formed.

Next, over the second electrode, DBT3P-II was deposited to a thickness of 70 nm by an evaporation method using resistance heating, whereby a cap layer was formed.

### <Method for Fabricating Light-Emitting Device 2B>

Next, a method for fabricating the light-emitting device 2B is described.

The light-emitting device 2B is different from the light-emitting device 2A in the structures of the electron-transport layer 914 and the electron-injection layer 915. That is, the electron-injection layer 915 in the light-emitting device 2B was formed in the following manner: 2,2′-(1,3-phenylene)bis(9-phenyl-1,10-phenanthroline) (abbreviation: mPPhen2P) was deposited by evaporation to a thickness of 15 nm so that the electron-transport layer 914 was formed; and after performing processing, mPPhen2P, 4,7-di(2,3,3a,4,5,6,7,7a-octahydro-1H-isoindol-2-yl)-1,10-phenanthroline (abbreviation: Hid2Phen), and lithium oxide (Li₂O) were deposited by co-evaporation to a thickness of 5 nm such that the volume ratio of mPPhen2P, Hid2Phen, and Li₂O is 0.5:0.5:0.02.

Other components were fabricated in a manner similar to that for the light-emitting device 2A.

The structures of the light-emitting devices 2A and 2B are listed in the following table.

TABLE 9

| | Film | | |
|---|---|---|---|
| | thickness | | |
| | [nm] | Light-emitting device 2A | Light-emitting device 2B |
| Cap layer | 70 | DBT3P-II | |
| Second electrode | 15 | Ag:Mg (1:0.1) | |
| Electron-injection | 5 | 6,6′(P-Bqn)2BPy:Hid2Phen:Li₂O | mPPhen2P:Hid2Phen:Li₂O |
| layer | | (0.5:0.5:0.02) | (0.5:0.5:0.02) |

Processing

| Electron-transport | 15 | 6,6′(P-Bqn)2BPy | mPPhen2P |
|---|---|---|---|
| layer | 20 | 2mPCCzPDBq | |
| Light-emitting | 40 | 8mpTP-4mDBtPBfpm:βNCCP:Ir(5mppy-d₃)₂(mbfpypy-d₃) | |
| layer | | (0.5:0.5:0.1) | |
| Hole-transport | 100 | PCBBiF | |
| layer | | | |
| Hole-injection | 10 | PCBBiF:OCHD-003 (1:0.03) | |
| layer | | | |

| | | |
|---|---|---|
| First electrode | 50 | ITSO |
| | 100 | APC |

### <Characteristics of Light-Emitting Devices>

The light-emitting devices were each sealed with a glass substrate in a glove box containing a nitrogen atmosphere so as not to be exposed to the air (a sealing material was applied to surround the devices and UV treatment and heat treatment at 80° C. for 1 hour were performed at the time of sealing).

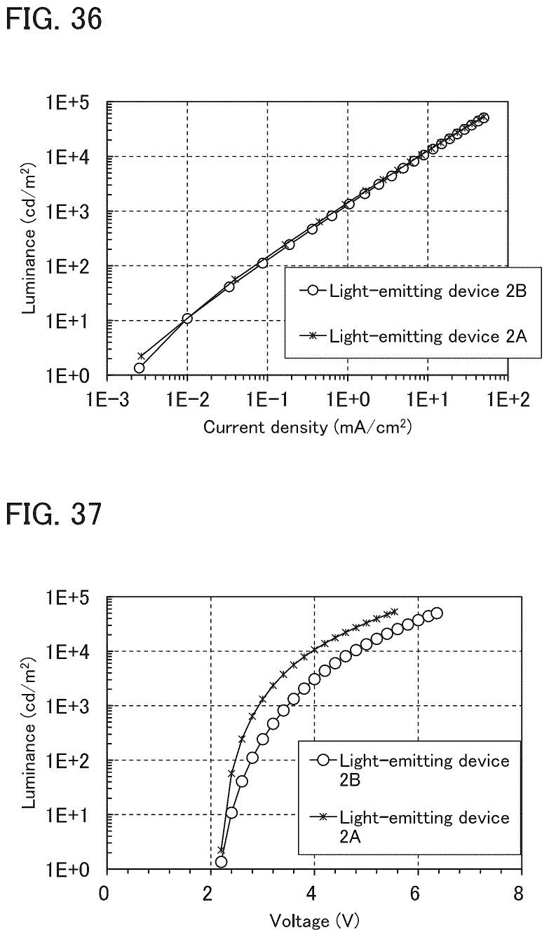

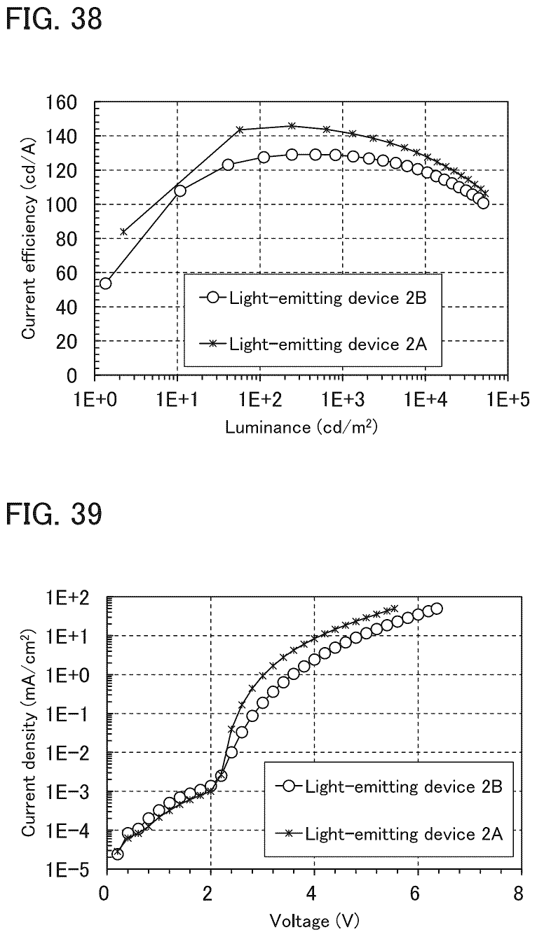

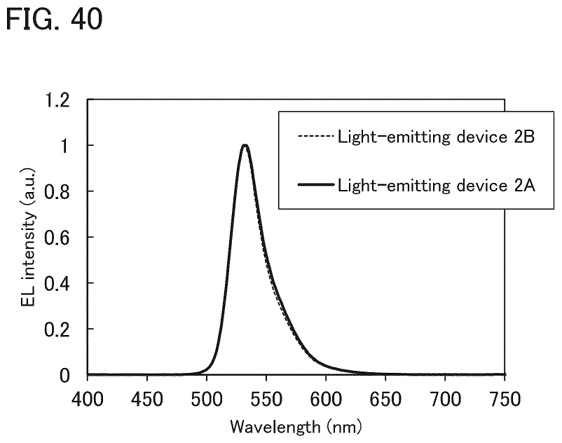

FIG. 36 shows the luminance-current density characteristics of the light-emitting devices, FIG. 37 shows the luminance-voltage characteristics thereof, FIG. 38 shows the current efficiency-luminance characteristics thereof, FIG. 39 shows the current density-voltage characteristics thereof, and FIG. 40 shows the electroluminescence spectra thereof.

The following table shows the main characteristics of the light-emitting devices at a luminance of 1000 cd/cm². Note that the luminance, CIE chromaticity, and electroluminescence spectra were measured with a spectroradiometer (SR-UL1R manufactured by TOPCON TECHNOHOUSE CORPORATION).

TABLE 10

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Light-emitting | 3.00 | 0.037 | 0.93 | 0.271 | 0.700 | 1320 | 141.3 |
| device 2A | | | | | | | |
| Light-emitting | 3.40 | 0.025 | 0.64 | 0.264 | 0.704 | 820 | 128.9 |
| device 2B | | | | | | | |

FIGS. 36 to 40 and the above table demonstrate that the light-emitting device 2A is a favorable light-emitting device that is driven at lower voltages and emits light with higher current efficiency than the light-emitting device 2B even through a process exposed to oxygen or water and a chemical solution and an etching process.

### <Reliability Test Result>

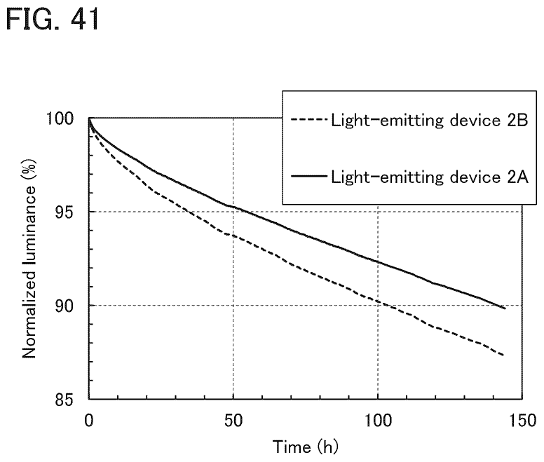

Furthermore, a reliability test was performed on the light-emitting devices 2A and 2B. FIG. 41 shows a time-dependent change in normalized luminance at the time of constant current density driving (50 mA/cm²). In FIG. 41, the vertical axis represents the luminance (%) normalized with the luminance at the time of the start of emission as 100%, and the horizontal axis represents time (h). The luminance at the initial driving stage was 53200 cd/m² for the light-emitting device 2A and 50400 cd/m² for the light-emitting device 2B.

According to FIG. 41, LT90 (h), which is the time that has elapsed until the measured luminance decreases to 90% of the initial luminance, of the light-emitting device 2A is 142 hours, indicating that the light-emitting device 2A has high reliability. The LT90 of the light-emitting device 2B is 104 hours. The light-emitting device 2A, which has higher luminance at the initial driving stage than the light-emitting device 2B, has higher reliability than the light-emitting device 2B.

The above shows that a light-emitting device with favorable characteristics can be fabricated by using the structure of the electron-injection layer of one embodiment of the present invention.

### Reference Example 1

In this reference example, a method for synthesizing 4,7-bis[4-(1-pyrrolidinyl)phenyl]-1,10-phenanthroline (abbreviation: PrdP2Phen) used in Example 1 is described. The structure of PrdP2Phen is shown below.

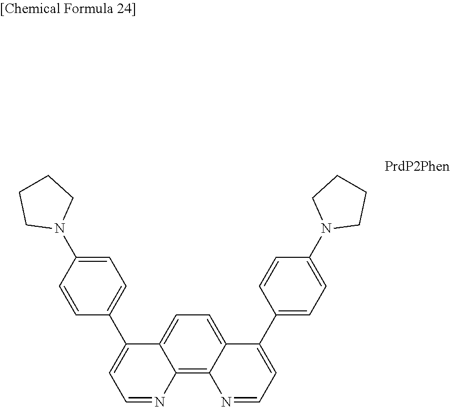 [SMILES: c1cc(-c2ccc(N3CCCC3)cc2)c2ccc3c(-c4ccc(N5CCCC5)cc4)ccnc3c2n1]

### <Synthesis of PrdP2Phen>

To a 100 mL three-neck flask were added 1.4 g (4.2 mmol) of 4,7-dibromo-1,10-phenanthroline, 2.5 g (9.2 mmol) of 2-[4-(1-pyrrolidinyl)phenyl]-4,4,5,5-tetramethyl-1,3,2-dioxaborolane, 0.48 mL (0.29 mmol) of tricyclohexylphosphine (an approximately 18% toluene solution), 3.0 g (14 mmol) of tripotassium phosphate, 25 mL of 1,4-dioxane, and 12 mL of water. The mixture was degassed by being stirred under reduced pressure. To this mixture was added 0.12 g (0.13 mmol) of tris(dibenzylideneacetone)dipalladium(0), and the resulting mixture was stirred under a nitrogen stream at 100° C. for 12 hours. After the stirring, the mixture was cooled down to room temperature. A precipitated solid of the mixture was collected by suction filtration. To this solid was added 1,4-dioxane, followed by irradiation with ultrasonic waves and a solid was collected by suction filtration. Chloroform was added to this solid so that this solid was dissolved. Water was added to this solution and an organic layer was subjected to extraction with chloroform. The extracted solution was concentrated to give a solid. Toluene was added to the obtained solid, and ultrasonic wave irradiation was performed. A solid was collected by suction filtration to give 1.2 g of a target pale yellow solid in a yield of 60%. A synthesis scheme of PrdP2Phen is shown in Formula (a-1) below.

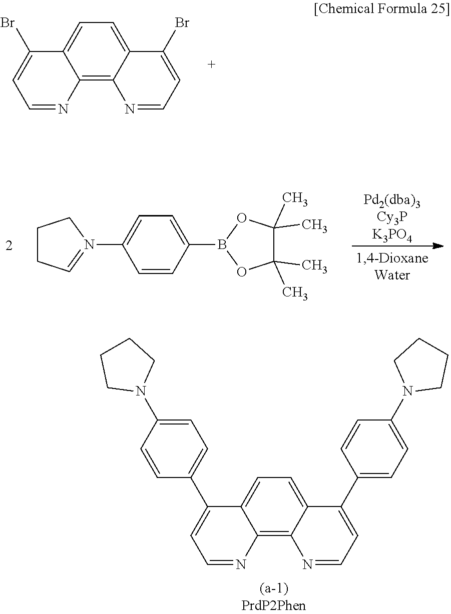

By a train sublimation method, 1.2 g of the obtained pale yellow solid was purified by sublimation. In the purification by sublimation, heating was performed for 20 hours at an argon flow rate of 18 mL/min, a pressure of 3.7 Pa, and a heating temperature of 280° C. As a result, 0.71 g of a target yellow solid was obtained at a collection rate of 59%.

Results of ¹H NMR measurement of PrdP2Phen after the purification by sublimation are shown below. The results reveal that PrdP2Phen was obtained.

¹H NMR (CDCl₃, 300 MHz): δ=9.15 (d, J=4.5 Hz, 2H), 8.00 (s, 2H), 7.54 (d, J=4.5 Hz, 2H), 7.46 (d, J=8.7 Hz, 4H), 6.71 (d, J=8.4 Hz, 4H), 3.41-3.37 (m, 8H), 2.09-2.04 (m, 8H).

### <Measurement of Glass Transition Temperature of PrdP2Phen>

The glass transition temperature (T_{g}) of PrdP2Phen was measured. Note that T_{g} was measured with a differential scanning calorimeter (DSC8500, PerkinElmer Japan Co., Ltd.) in a state where a powder was put on an aluminum cell and the temperature was increased at a rate of 40° C./min. The results show that the T_{g} of PrdP2Phen is 130° C.

Next, a solubility test of PrdP2Phen was performed. Note that the solubility test was conducted at a pressure of one atmosphere at room temperature (RT).

### <Solubility Test of PrdP2Phen by LC-MS Analysis>

In the LC-MS analysis, liquid chromatography (LC) separation was carried out with ACQUITY UPLC (manufactured by Waters Corporation), and MS analysis (mass spectrometry) was carried out with Xevo G2 Tof MS (manufactured by Waters Corporation). Acquity UPLC BEH C8 (2.1×100 mm, 1.7 μm) was used as a column for the LC separation. Acetonitrile was used for Mobile Phase A and a 0.1% aqueous solution of formic acid was used for Mobile Phase B. The injection amount of the sample was 5.0 μL. Note that in the analysis, the wavelength of a photodiode array detector was set to 263 nm±1 nm.

In a 5-mL sample bottle, 1 mg of PrdP2Phen was put and 1 mL of water was added thereto. This mixture was irradiated with ultrasonic waves for 5 minutes. This mixture was filtered through a membrane filter to remove the solid, and the resulting filtrate was diluted by five times with acetonitrile. The obtained solution was subjected to LC-MS analysis.

As a result, the peak area value derived from PrdP2Phen failed to be obtained through the LC-MS analysis. This indicates that PrdP2Phen is an organic compound with extremely low solubility in water.

This application is based on Japanese Patent Application Serial No. 2023-219947 filed with Japan Patent Office on Dec. 26, 2023, the entire contents of which are hereby incorporated by reference.

What is claimed is:

1. A light-emitting device comprising:
a first electrode;
a second electrode; and
an organic compound layer between the first electrode and the second electrode,
wherein the organic compound layer comprises a light-emitting layer and an electron-injection layer,
wherein the electron-injection layer comprises a metal or a metal oxide, a first organic compound, and a second organic compound,
wherein the first organic compound comprises a π-electron deficient heteroaromatic ring,
wherein the second organic compound comprises two or more heteroaromatic rings,
wherein the two or more heteroaromatic rings are bonded or condensed to each other and comprise three or more heteroatoms in total, and
wherein the second organic compound is configured to interact with the metal or the metal oxide by two or more of the three or more heteroatoms as a multidentate ligand.

2. The light-emitting device according to claim 1,
wherein the second organic compound is configured to interact with the metal or the metal oxide as a bidentate or tridentate ligand.

3. The light-emitting device according to claim 1,
wherein the three or more heteroatoms are each a nitrogen atom.

4. A light-emitting device comprising:
a first electrode;
a second electrode; and
an organic compound layer between the first electrode and the second electrode,
wherein the organic compound layer comprises a light-emitting layer and an electron-injection layer,
wherein the electron-injection layer comprises a metal or a metal oxide, a first organic compound, and a second organic compound,
wherein the first organic compound comprises a π-electron deficient heteroaromatic ring,
wherein the second organic compound is represented by General Formula (G1-1), 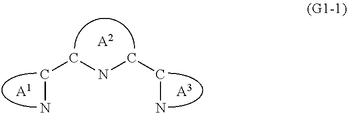
and
wherein A¹, A², and A³ independently represent a substituted or unsubstituted heteroaromatic ring having 1 to 30 carbon atoms.

5. A light-emitting device comprising:
a first electrode;
a second electrode; and
an organic compound layer between the first electrode and the second electrode,
wherein the organic compound layer comprises a light-emitting layer and an electron-injection layer,
wherein the electron-injection layer comprises a metal or a metal oxide, a first organic compound, and a second organic compound,
wherein the first organic compound comprises a π-electron deficient heteroaromatic ring,
wherein the second organic compound is represented by General Formula (G1-2), 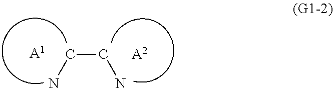
wherein A¹ and A² independently represent a substituted or unsubstituted heteroaromatic ring having 1 to 30 carbon atoms, and
wherein A¹ comprises two or more nitrogen atoms.

6. The light-emitting device according to claim 1,
wherein the two or more heteroaromatic rings are each a π-electron deficient heteroaromatic ring.

7. The light-emitting device according to claim 1,
wherein the two or more heteroaromatic rings each independently comprise at least one of a pyridine ring, a pyrazine ring, a pyrimidine ring, a pyridazine ring, a triazine ring, an imidazole ring, a pyrazole ring, an oxazole ring, a thiazole ring, and a triazole ring.

8. The light-emitting device according to claim 1,
wherein at least one of the two or more heteroaromatic rings comprises a pyrazine ring, a pyrimidine ring, a pyridazine ring or a triazine ring.

9. The light-emitting device according to claim 1,
wherein the two or more heteroaromatic rings comprise three or more pyridine rings in total.

10. The light-emitting device according to claim 1,
wherein the first organic compound comprises an electron-donating group.

11. The light-emitting device according to claim 10,
wherein the electron-donating group comprises at least one of an alkyl group, an alkoxy group, an aryloxy group, an alkylamino group, an arylamino group, and a heterocyclic amino group.

12. The light-emitting device according to claim 1,
wherein the first organic compound has an acid dissociation constant pKₐ of 8 or more.

13. The light-emitting device according to claim 1,
wherein the first organic compound comprises a phenanthroline ring.

14. The light-emitting device according to claim 1,
wherein the second organic compound has a glass transition temperature T_{g} of 100° C. or higher.

15. The light-emitting device according to claim 1,
wherein a LUMO level of the second organic compound is lower than a LUMO level of the first organic compound.

16. The light-emitting device according to claim 1,
wherein the metal belongs to Group 1, 3, 11, or 13 of a periodic table.

17. The light-emitting device according to claim 4,
wherein the first organic compound comprises a phenanthroline ring.

18. The light-emitting device according to claim 4,
wherein a LUMO level of the second organic compound is lower than a LUMO level of the first organic compound.

19. The light-emitting device according to claim 4,
wherein the metal belongs to Group 1, 3, 11, or 13 of a periodic table.

20. The light-emitting device according to claim 5,
wherein the first organic compound comprises a phenanthroline ring.

21. The light-emitting device according to claim 5,
wherein a LUMO level of the second organic compound is lower than a LUMO level of the first organic compound.

22. The light-emitting device according to claim 5,
wherein the metal belongs to Group 1, 3, 11, or 13 of a periodic table.
